(19) United States
(12) Patent Application Publication
(10) Pub. No.: US 2024/0262849 A1
(43) Pub. Date: Aug. 8, 2024

(54) ORGANIC BORON-NITROGEN COMPOUNDS, MIXTURES, COMPOSITIONS, AND ORGANIC ELECTRONIC DEVICES

(71) Applicant: GUANGZHOU CHINARAY OPTOELECTRONIC MATERIALS LTD., Guangzhou, Guangdong (CN)

(72) Inventors: Ruifeng HE, Guangzhou, Guangdong (CN); Canjie WU, Guangzhou, Guangdong (CN); Wenyu HUANG, Guangzhou, Guangdong (CN); Jingyao SONG, Guangzhou, Guangdong (CN)

(73) Assignee: GUANGZHOU CHINARAY OPTOELECTRONIC MATERIALS LTD., Guangzhou, Guangdong (CN)

(21) Appl. No.: 18/682,424

(22) PCT Filed: Apr. 30, 2021
(86) PCT No.: PCT/CN2021/091566

§ 371 Date: Feb. 8, 2024

(30) Foreign Application Priority Data
Dec. 10, 2020 (CN) 202011437282.3

(51) Int. Cl. C07F 5/02; C09K 11/06; H10K 85/60

(52) U.S. Cl. CPC C07F 5/02; C09K 11/06; H10K 85/658

(57) ABSTRACT

The disclosure provides an organic boron-nitrogen compound, a mixture, a composition, and an organic electronic device. The organic boron-nitrogen compound is represented by formula (I) or formula (II), in which Ar¹ to Ar⁷ at each occurrence are independently selected from a substituted or unsubstituted aromatic group having 6 to 40 ring atoms or a substituted or unsubstituted heteroaromatic group having 6 to 40 ring atoms; X is independently selected from CR₁ or N; and Z is selected from NR₂, PR₂, CR₃R₄, SiR₃R₄, O, S, S(═O)₂, or S(═O).

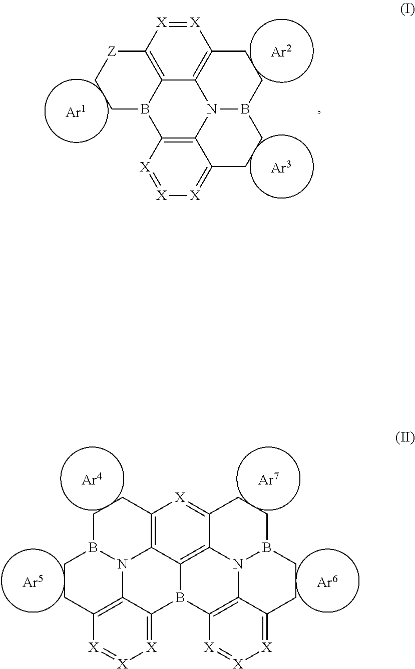

### CROSS-REFERENCE TO RELATED APPLICATIONS

This application claims the priority to and benefit of Chinese Patent Application No. 2020114372823, filed on Dec. 10, 2020, and titled “ORGANIC BORON-NITROGEN COMPOUNDS, MIXTURES, COMPOSITIONS, AND ORGANIC ELECTRONIC DEVICES”, the disclosure of which is incorporated herein by reference in its entirety.

### TECHNICAL FIELD

The present disclosure relates to the field of organic light-emitting materials, and in particular, to organic boron-nitrogen compounds, mixtures, compositions, and organic electronic devices.

### BACKGROUND

Organic semiconductor materials have great potential in manufacturing organic electronic devices, for example, organic light-emitting diodes (OLEDs) or optoelectronic devices, such as flat panel displays and illumination devices, due to their diversity, relatively low manufacturing cost, and excellent optical and electrical properties

The luminescence principle of organic electronic devices is organic electroluminescence, which refers to the phenomenon of using organic substances to convert electrical energy into light energy. An organic electroluminescent device that utilizes organic electroluminescence generally has a positive electrode, a negative electrode, and a functional layer containing organic substances between the positive electrode and the negative electrode. In order to improve efficiency and lifetime of the organic electroluminescent device, the functional layer is designed to be a multi-layer structure that contains different organic substances. Specifically, the functional layer includes a hole injection layer, a hole transport layer, a light-emitting layer, an electron transport layer, an electron injection layer, or the like. When voltages are applied between the positive electrode and the negative electrode, holes in the positive electrode are injected into organic layers, and electrons in the negative electrode are also injected into the organic layers, then the injected holes meet with the injected electrons to form excitons, which emit light when they transition back to a ground state. This organic electroluminescent element has characteristics such as autonomous luminescence, high brightness, high efficiency, low driving voltage, wide viewing angle, high contrast, high responsiveness, and the like.

In order to improve luminous efficiency of the organic electroluminescent device, various light-emitting material systems based on fluorescence and phosphorescence have been developed. At present, organic light-emitting diodes using blue fluorescent materials have higher reliability. However, the development of blue fluorescent materials with excellent optical and electrical properties faces a huge challenge. In traditional technologies, most blue fluorescent materials have wide emission spectrum and poor color purity, which are not conducive to high-end displays. Moreover, OLED devices made from these blue fluorescent materials have poor luminous efficiency and lifetime, thus the blue fluorescent materials need to be further improved.

### SUMMARY

Based on the above, it is necessary to provide an organic boron-nitrogen compound, a mixture, a composition, and an organic electronic device. The organic boron-nitrogen compound can be used as a light-emitting material in the organic electronic device to improve luminous efficiency and lifetime of the device.

Technical solutions of the disclosure are as follows:

The disclosure provides an organic boron-nitrogen compound represented by formula (I) or formula (II):

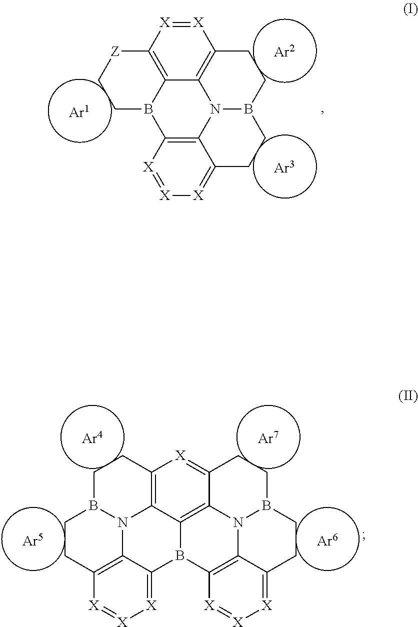

in which Ar¹ to Ar⁷ are independently selected from a substituted or unsubstituted aromatic group having 6 to 40 ring atoms or a substituted or unsubstituted heteroaromatic group having 6 to 40 ring atoms;
X at each occurrence is independently selected from CR₁ or N;
Z is selected from NR₂, PR₂, CR₃R₄, SiR₃R₄, O, S, S(═O)₂, or S(═O);
R₁ to R₄ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF_{3,}—OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₁ groups are connected to form a ring or not form a ring together.

The disclosure further provides a mixture that includes at least one organic boron-nitrogen compound as described above, and at least another organic functional material. The organic functional material is selected from a hole injection material, a hole transport material, an electron transport material, an electron injection material, an electron blocking material, a hole blocking material, a light-emitting material, a host material, or an organic dye.

Further, the disclosure provides a composition that includes at least one organic boron-nitrogen compound or the mixture as described above, and at least one organic solvent.

The disclosure further provides an organic electronic device that includes a first electrode, a second electrode, and one or more functional layers disposed between the first electrode and the second electrode. At least one functional layer in the one or more functional layers includes the organic boron-nitrogen compound or the mixture as described above, or is prepared from the composition as described above.

In the organic boron-nitrogen compound represented by formula (I) or formula (II) of the disclosure, at least one nitrogen atom and two boron atoms are included in the same rigid plane, and the two are not twisted or staggered. The planar arrangement of molecules is conducive to structural stability and light output. At the same time, this type of boron-nitrogen compound can effectively utilize energy of the triplet state to realize anti system transition from the triplet state to the singlet state, thus realizing a theoretical internal quantum efficiency of 100%, which can effectively improve luminous efficiency and lifetime of devices.

### DETAILED DESCRIPTION

For the convenience of understanding the disclosure, a more comprehensive description will be provided below, and preferable embodiments of the disclosure will be provided. This disclosure may, however, be embodied in different forms and should not be construed as limited to the embodiments set forth herein. Rather, these embodiments are provided so that the disclosure will be thorough and complete.

Unless otherwise defined, all terms, including technical and scientific terms, used herein have the same meaning as commonly understood by one of ordinary skill in the art to which the disclosure belongs. The terms used in the specification of the disclosure are only for the purpose of describing specific embodiments and are not intended to limit the disclosure. The term “and/or” used in this context includes any and all combinations of one or more of the associated listed items.

In the disclosure, “substituted” means that a hydrogen atom in one substituted group is substituted by a substituent group.

In the disclosure, the same substituent groups at different substituent sites may be independently selected from different groups. For example, if a formula includes multiple R₁ groups, the R₁ groups may be independently selected from different groups.

In the disclosure, “substituted or unsubstituted” means that a group to be defined, i.e., a defined group, may be substituted or not be substituted. When the defined group is substituted, it can be understood that the defined group is optionally substituted by suitable groups in the art, which include, but not limited to, a C₁-C₃₀ alkyl group, a heterocyclic group having 3 to 20 ring atoms, an aryl group having 5 to 20 ring atoms, a heteroaryl group having 5 to 20 ring atoms, a silyl group, a carbonyl group, an alkoxycarbonyl group, an aryloxycarbonyl group, a carbamoyl group, a haloformyl group, a formyl group, —NRR′, a cyano group, a isocyano group, an isocyanate group, a thiocyanate group, an isothiocyanate group, a hydroxyl group, a trifluoromethyl group, a nitro group, or a halogen atom, and the groups may further be substituted by acceptable substituent groups in the art. Understandably, R and R′ in the —NRR′ are independently substituted by acceptable substituent groups in the art, which include, but not limited to, —H, a C₁₋₆ alkyl group, a cycloalkyl group having 3 to 8 ring atoms, a heterocyclic group having 3 to 8 ring atoms, an aryl group having 5 to 20 ring atoms, or a heteroaryl group having 5 to 10 ring atoms, and the C₁₆ alkyl group, the cycloalkyl group having 3 to 8 ring atoms, the heterocyclic group having 3 to 8 ring atoms, the aryl group having 5 to 20 ring atoms, or the heteroaryl group having 5 to 10 ring atoms is optionally further substituted by one or more of the following groups: a C₁₋₆ alkyl group, a cycloalkyl group having 3 to 8 ring atoms, a heterocyclic group having 3 to 8 ring atoms, a halogen atom, a hydroxyl group, a nitro group, and an amino group.

In the disclosure, “the number of ring atoms” refers to the number of atoms constituting a ring in a structural compound obtained by atomic bonding, for example, a monocyclic compound, a fused ring compound, a cross-linked compound, a carbon ring compound, or a heterocyclic compound. In a ring substituted by a substituent group, the atoms contained in the substituent group are not included in the atoms forming the ring. The same applies to “the number of ring atoms” described below unless otherwise specified. For example, the number of ring atoms in a benzene ring is 6, the number of ring atoms in a naphthalene ring is 10, and the number of ring atoms in thienyl is 5.

In the disclosure, “an alkyl group” refers to a linear alkyl group, a branched alkyl group, and/or a cyclic alkyl group. The number of carbon atoms in the alkyl group may range from 1 to 50, 1 to 30, 1 to 20, 1 to 10, or 1 to 6. The term containing the alkyl group, such as “a C₁₋₉ alkyl group”, refers to an alkyl group having 1 to 9 carbon atoms. The C₁₋₉ alkyl group at each occurrence is independently selected from a C₁ alkyl group, a C₂ alkyl group, a C₃ alkyl group, a C₄ alkyl group, a Cs alkyl group, a C₆ alkyl group, a C₇ alkyl group, a C₈ alkyl group, or a C₉ alkyl group. Examples of the alkyl group include, but not limited to, methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butyhexyl, cyclohexyl, 4-methylcyclohexyl, 4-tert-butylcyclohexyl, n-heptyl, 1-methylheptyl, 2,2-dimethylheptyl, 2-ethylheptyl, 2-butyheptyl, n-octyl, tert-octyl, 2-ethyloctyl, 2-butyloctyl, 2-hexyloctyl, 3,7-dimethyloctyl, cyclooctyl, n-nonyl, n-decyl, and an adamantine group.

An aromatic group refers to a hydrocarbon group having at least one aromatic ring. An hereoaromatic group refers to an aromatic hydrocarbon group having at least one heteroatom. The heteroatom is preferably selected from Si, N, P, O, S, and/or Ge, in particular, preferably selected from Si, N, P, O, and/or S. A fused-ring aromatic group refers to an aromatic group having two or more rings, and two adjacent rings share two carbon atoms, known as the fused ring. A fused heterocyclic aromatic group refers to a fused aromatic hydrocarbon group having at least one heteroatom. For the purpose of the disclosure, the aromatic group or the heteroaromatic group not only includes aromatic ring systems, but also non-aromatic ring systems. Therefore, systems such as pyridine, thiophene, pyrrole, pyrazole, triazole, imidazole, oxazole, oxadiazole, thiazole, tetrazole, pyrazine, pyrimidine, triazine, carbene, and the like, are also considered as the aromatic group or the heterocyclic aromatic group for the purpose of the disclosure. For the purpose of the disclosure, a fused-ring aromatic ring system or a fused heterocyclic aromatic ring system not only includes a system with the aromatic group or the heteroaromatic group, moreover, multiple aromatic groups or heterocyclic aromatic groups may further be disconnected by non-aromatic units (a non-hydrogenium atom contenting less than 10%, preferably less than 5% of non-hydrogenium atoms, such as C, N, or O). Therefore, systems such as 9,9′-spirodifluorene, 9,9-diarylfluorene, triarylamine, diaryl ether, and the like, are also considered as the fused-ring aromatic ring system for the purpose of the disclosure.

In one preferable embodiment, the aromatic group is selected from a group consisting of benzene, naphthalene, anthracene, fluoranthene, phenanthrene, benzophenanthrene, perylene, naphthacene, pyrene, benzopyrene, acenaphthene, fluorine, and derivatives thereof. The hereoaromatic group is selected from a group consisting of triazine, pyridine, pyrimidine, imidazole, furan, thiophene, benzofuran, benzothiophene, indole, carbazole, pyrrolimidazole, diketopyrrolopyrrole, thiophenopyrrole, thienothiophene, furanopyrrole, furanofuran, thienofuran, benzoisoxazole, benzisothiazole, benzimidazole, quinoline, isoquinoline, ortho-diazonaphthalene, quinoxaline, phenanthridine, perimidine, quinazoline, quinazolinone, dibenzothiophene, dibenzofuran, carbazole, and derivatives thereof.

In the disclosure, “*” connected to a single bond indicates a linking site or a fusing site.

In the disclosure, when a linking site in a group is not specified, it means that any of connectable sites in the group may be selected as the linking site.

In the disclosure, when a fusing site in a group is not specified, it means that any of fusible sites in the group may be selected as the fusing site. Preferably, two or more adjacent sites in the group form a fusing site.

A non-aromatic ring system refers to a ring system containing at least one non-aromatic ring. In the disclosure, preferably, the non-aromatic ring system only contains the ring formed by carbon-carbon single bonds.

In the disclosure, a single bond connected to a substituent group and penetrated through a corresponding ring indicates that the substituent group may be connected to any site that can be substituted of the ring. For example,

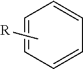

means that R is connected to any substituent site of the benzene ring.

In the disclosure, two single bonds connected to a substituent group and penetrated a corresponding ring indicates that the substituent group may be fused with any site of the ring. For example,

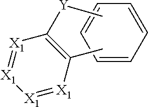

means that

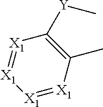

therein is fused with any fusible site(s) of the benzene ring.

In the disclosure, a composition, printing ink, and ink have the same meaning and may be interchanged.

In the disclosure, a host material, a matrix material, and a host have the same meaning and may be interchanged.

The disclosure provides an organic boron-nitrogen compound represented by formula (I) or formula (II):

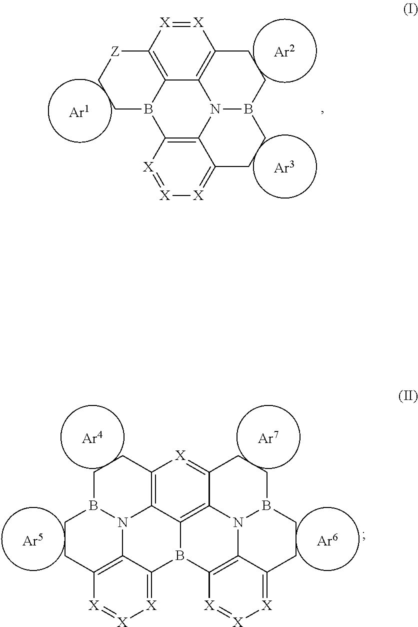

in which Ar¹ to Ar⁷ are independently selected from a substituted or unsubstituted aromatic group having 6 to 40 ring atoms or a substituted or unsubstituted heteroaromatic group having 6 to 40 ring atoms;
X at each occurrence is independently selected from CR₁ or N;
Z is selected from NR₂, PR₂, CR₃R₄, SiR₃R₄, O, S, S(═O)₂, or S(═O);
R₁ to R₄ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF₃, —OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₁ groups are connected to form a ring or not form a ring together.

In one embodiment, R₁ to R₄ at each occurrence are independently selected from —H, -D, a linear alkyl group having 1 to 20 carbon atoms, a branched alkyl group having 3 to 20 carbon atoms, a cycloalkyl group having 3 to 20 carbon atoms, a substituted or unsubstituted aromatic group having 5 to 40 ring atoms, a substituted or unsubstituted heteroaromatic group having 5 to 40 ring atoms, or any combination of these groups.

In one embodiment, R₁ to R₄ at each occurrence are independently selected from —H, -D, a linear alkyl group having 1 to 10 carbon atoms, a branched alkyl group having 3 to 10 carbon atoms, a cycloalkyl group having 3 to 10 carbon atoms, a substituted or unsubstituted aromatic group having 5 to 20 ring atoms, a substituted or unsubstituted heteroaromatic group having 5 to 20 ring atoms, or any combination of these groups.

In one embodiment, R₁ to R₄ at each occurrence are independently selected from —H, -D, methyl, —CD₃, isopropyl, tert-butyl, 2,2-dimethylbutyl, phenyl, pyridinyl, triazinyl, naphthyl, phenanthryl, anthranyl, dibenzofuranyl, dibenzothienyl, carbazolyl, or 9,9-dimethylfluorenyl.

In one embodiment, Ar¹ to Ar⁷ are independently selected from a substituted or unsubstituted aromatic group having 6 to 25 ring atoms or a substituted or unsubstituted heteroaromatic group having 6 to 25 ring atoms.

In one embodiment, Ar¹ to Ar⁷ are independently selected from a substituted or unsubstituted aromatic group having 6 to 13 ring atoms or a substituted or unsubstituted heteroaromatic group having 6 to 13 ring atoms.

In one embodiment, Ar¹ to Ar⁷ are independently selected from a group consisting of formulae (B-1) to (B-9):

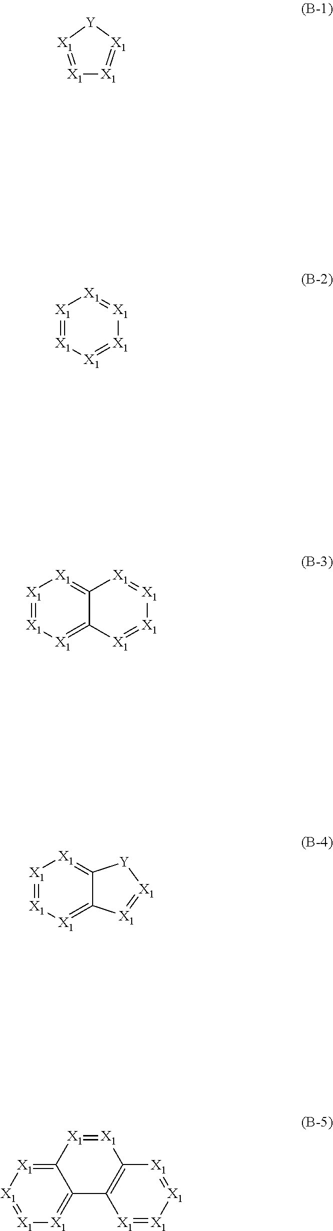

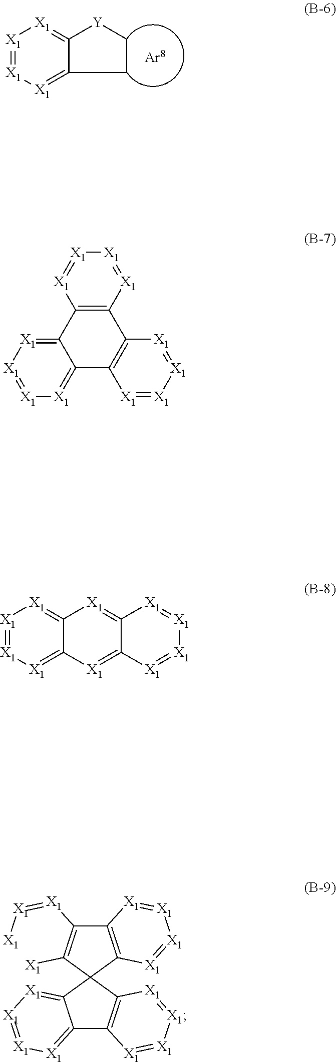

wherein,
X₁ at each occurrence is independently selected from CR₅ or N; and when X₁ is a linking site, X₁ is selected from C;
Y at each occurrence is independently selected from NR₆, PR₆, CR₇R₈, SiR₇R₈, O, S, S(═O)₂, or S(═O);
Ar⁸ is selected from a substituted or unsubstituted aromatic group having 6 to 40 ring atoms or a substituted or unsubstituted heteroaromatic group having 6 to 40 ring atoms;
R₅ to R₈ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF₃, —OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and two adjacent R₅ groups are connected to form a ring or not form a ring together. In some embodiments, Ar⁸ is selected from a substituted or unsubstituted aromatic group having 6 to 10 ring atoms or a substituted or unsubstituted heteroaromatic group having 6 to 10 ring atoms.

Further, the formula (B-6) is selected from a group consisting of following formulae:

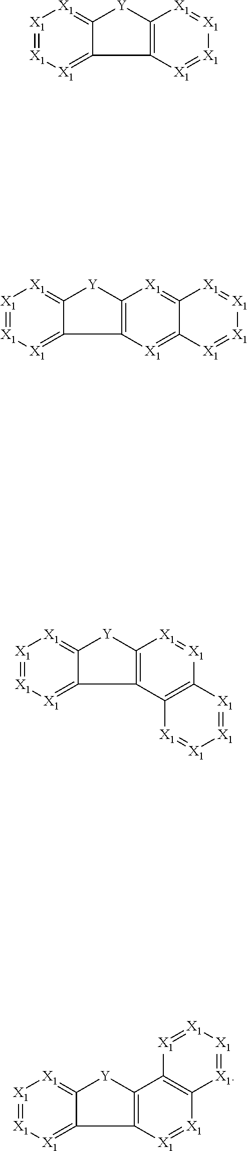

In some embodiments, in the formula (I), Ar¹ to Ar³ are independently selected from the group consisting of the formulae (B-2) to (B-9).

In some embodiments, in the formula (I), at least one of Ar¹ to Ar³ is selected from the formula (B-2). Further, Ar² is selected from the formula (B-2).

In some embodiments, in the formula (I), at least two of Ar¹ to Ar³ are selected from the formula (B-2). Further, Ar² and Ar³ are selected from the formula (B-2).

In some embodiments, in the formula (I), Ar¹ to Ar³ are all selected from the formula (B-2).

In some embodiments, in the formula (I), at least one of Ar¹ to Ar³ is selected from the formula (B-2), and at least one of Ar¹ to Ar³ is selected from the formula (B-6). Further, any two of Ar¹ to Ar³ are selected from the formula (B-2), and the other of Ar¹ to Ar³ is selected from the formula (B-6).

In some embodiments, in the formula (I), at least one of Ar¹ to Ar³ is selected from the formula (B-2), and at least one of Ar¹ to Ar³ is selected from the formula (B-4). Further, any two of Ar¹ to Ar³ are selected from the formula (B-2), and the other of Ar¹ to Ar³ is selected from the formula (B-4).

In some embodiments, in the formula (I), at least one of Ar¹ to Ar³ is selected from the formula (B-2), and at least one of Ar¹ to Ar³ is selected from the formula (B-3). Further, any two of Ar¹ to Ar³ are selected from the formula (B-2), and the other of Ar¹ to Ar³ is selected from the formula (B-3).

In some embodiments, in the formula (I), at least one of Ar¹ to Ar³ is selected from the formula (B-2), and at least one of Ar¹ to Ar³ is selected from the formula (B-7). Further, any two of Ar¹ to Ar³ are selected from the formula (B-2), and the other of Ar¹ to Ar³ is selected from the formula (B-7).

In some embodiments, in the formula (I), at least one of Ar¹ to Ar³ is selected from the formula (B-2), and at least one of Ar¹ to Ar³ is selected from the formula (B-9). Further, any two of Ar¹ to Ar³ are selected from the formula (B-2), and the other of Ar¹ to Ar³ is selected from the formula (B-9).

In one preferable embodiment, Ar¹ is selected from the formula (B-4). Further, Ar² is selected from the formula (B-2). Furthermore, Ar³ is selected from the formula (B-2), the formula (B-3), or the formula (B-6).

The reason for the above selection is that introducing heteroatoms into the structural framework close to the B atom can better regulate photoelectric properties of molecules.

In some embodiments, in the formula (II), Ar⁴ to Ar⁷ are independently selected from the formulae (B-2) to (B-9).

In one embodiment, the compound represented by formula (II) has a symmetrical structure.

In one embodiment, Ar⁴ and Ar⁷ in the formula (II) are selected from the group consisting of the formulae (B-2) to (B-6). Further, Ar⁴ and Ar⁷ are selected from the same group. Furthermore, Ar⁴ and Ar⁷ are the same group selected from

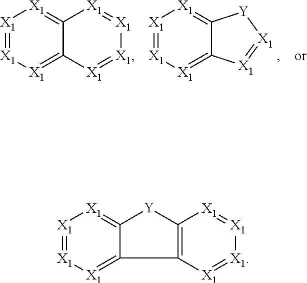

In one embodiment, Ar⁵ and Ar⁶ in the formula (II) are selected from the group consisting of the formulae (B-2) to (B-6). Further, Ar⁵ and Ar⁶ are selected from the same group. Furthermore, Ar⁵ and Ar⁶ are the same group selected from

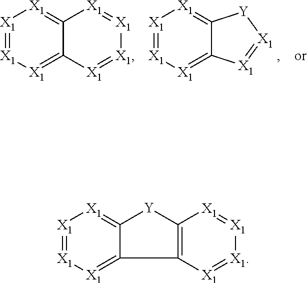

In one embodiment, Ar⁴ and Ar⁷ are the same group selected from

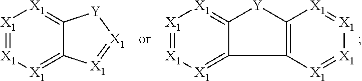

or, Ar⁵ and Ar⁶ are the same group selected from

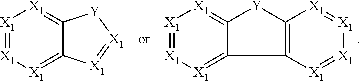

In one embodiment, Ar¹ to Ar⁷ are independently selected from a group consisting of formulae (C-1) to (C-22):

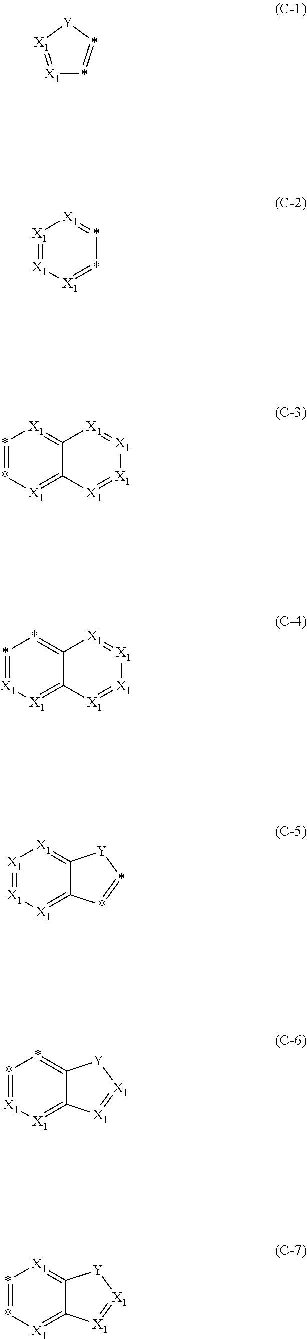

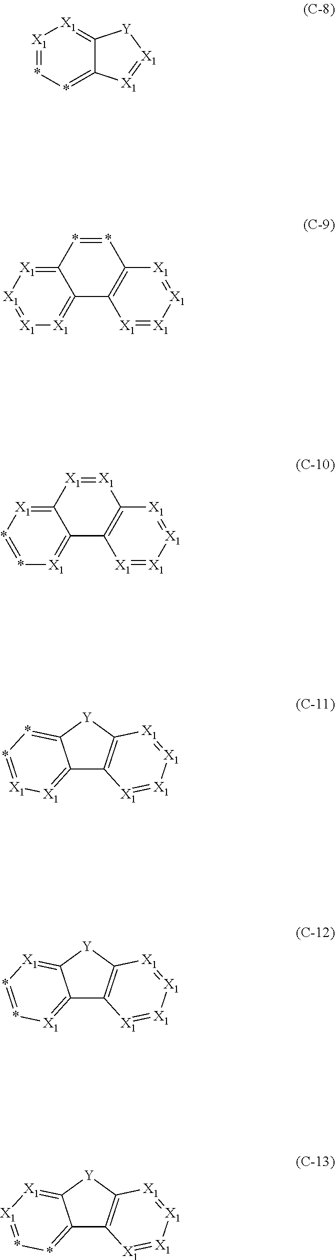

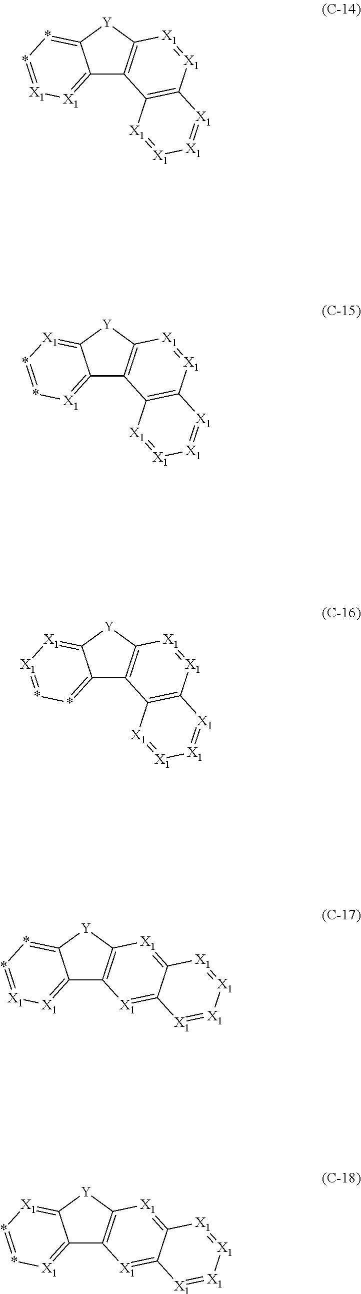

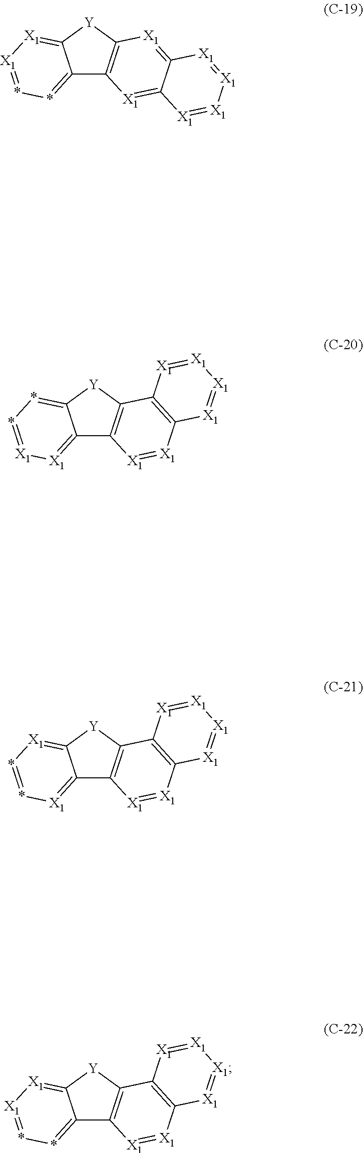

in which * indicates a fusing site.

In one preferable embodiment, Ar¹ is selected from the formula (C-5). Further, Ar² is selected from the formula (C-2).

In some embodiments, X₁ at each occurrence is selected from CR₅. Further, R₅ at each occurrence is independently from —H, -D, a linear alkyl group having 1 to 10 carbon atoms, a branched alkyl group having 3 to 10 carbon atoms, a cyclic alkyl group having 3 to 10 carbon atoms, a substituted or unsubstituted aromatic group having 5 to 20 ring atoms, a substituted or unsubstituted heteroaromatic group having 5 to 20 ring atoms, or any combination of these groups.

Further, R₅ at each occurrence is independently from —H, -D, a linear alkyl group having 1 to 8 carbon atoms, or a branched alkyl group having 3 to 8 carbon atoms.

Furthermore, at least one R₅ is selected from a linear alkyl group having 1 to 8 carbon atoms or a branched alkyl group having 3 to 8 carbon atoms. Furthermore, at least one R₅ is selected from methyl, —CD₃, isopropyl, or the following structure:

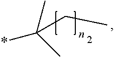

in which n₂ is an integer from 0 to 4.

Understandably, when n2 is 0, R₅ is tert-butyl.

In some embodiments, Y at each occurrence is independently selected from NR₆, CR₇R₈, O, or S.

Further, R₆ to R₈ are independently selected from —H, -D, a linear alkyl group having 1 to 10 carbon atoms, a branched alkyl group having 3 to 10 carbon atoms, a cycloalkyl group having 3 to 10 carbon atoms, an unsubstituted aromatic group having 5 to 20 ring atoms, an unsubstituted heteroaromatic group having 5 to 20 ring atoms, an aromatic group having 5 to 20 ring atoms substituted by a linear alkyl group having 1 to 10 carbon atoms, a branched alkyl group having 3 to 10 carbon atoms, or a cycloalkyl group having 3 to 10 carbon atoms, or a heteroaromatic group having 5 to 20 ring atoms substituted by a branched alkyl group having 3 to 10 carbon atoms or a cycloalkyl group having 3 to 10 carbon atoms.

In one embodiment, R₅ to R₈ at each occurrence are independently selected from —H, -D, methyl, —CD₃, isopropyl, tert-butyl, 2,2-dimethylbutyl, phenyl, pyridinyl, triazinyl, naphthyl, phenanthryl, anthranyl, dibenzofuranyl, dibenzothienyl, carbazolyl, or 9,9-dimethylfluorenyl.

Further, the organic boron-nitrogen compound is represented by any one of formulae (1-1) to (1-15):

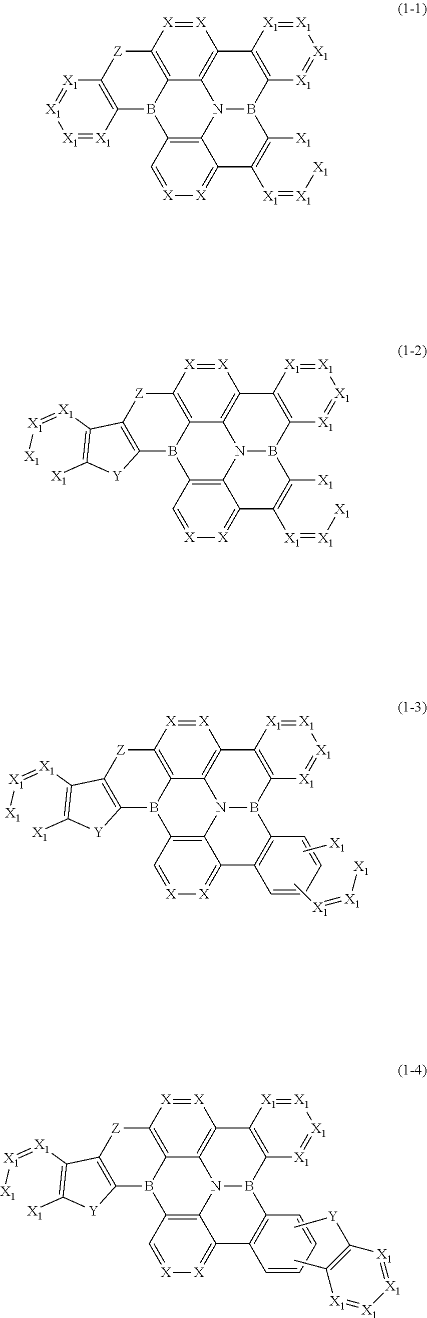

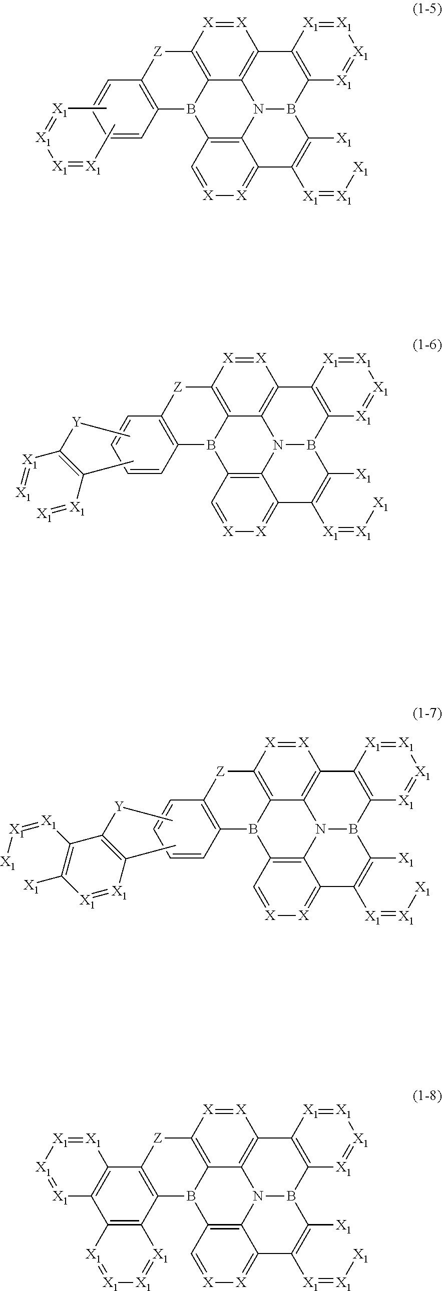

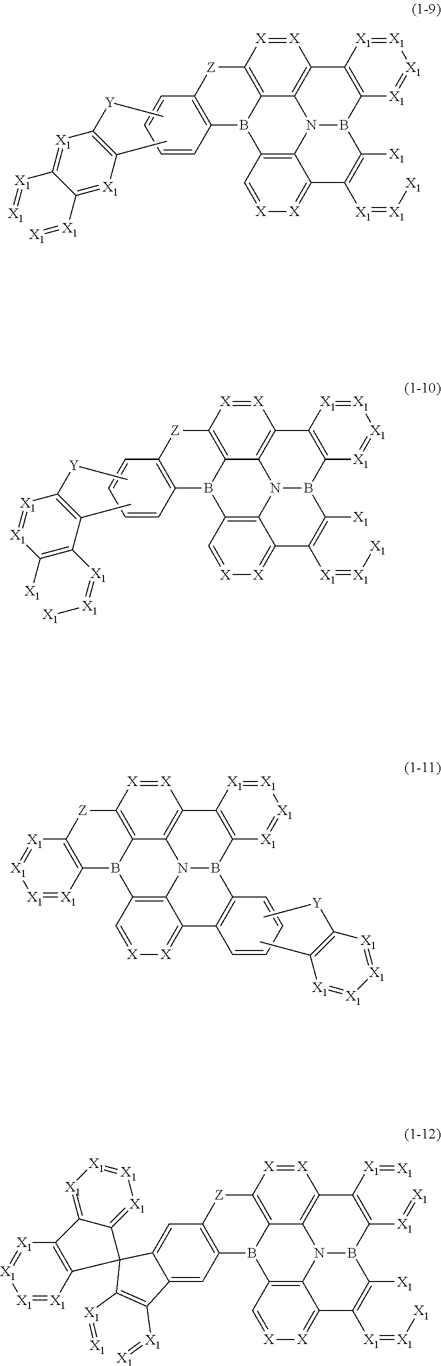

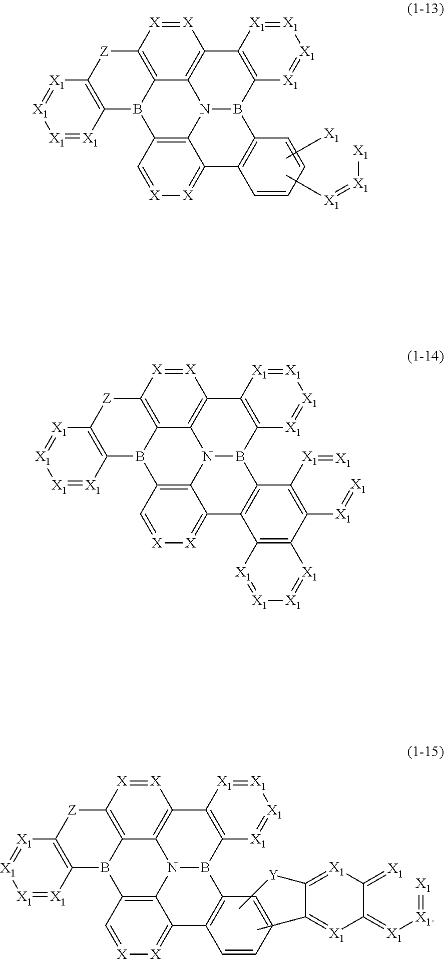

Further, Z is selected from NR₂, CR₃R₄, O, or S. Furthermore, Z is selected from NR_{2.} Further, R₂ is selected from —H, -D, a linear alkyl group having 1 to 10 carbon atoms, a branched alkyl group having 3 to 10 carbon atoms, a cyclic alkyl group having 3 to 10 carbon atoms, an aromatic group having 5 to 20 ring atoms, a heteroaromatic group having 5 to 20 ring atoms, an aromatic group having 5 to 20 ring atoms substituted by a linear alkyl group having 1 to 10 carbon atoms, a branched alkyl group having 3 to 10 carbon atoms, or a cycloalkyl group having 3 to 10 carbon atoms, or a heteroaromatic group having 5 to 20 ring atoms substituted by a branched alkyl group having 3 to 10 carbon atoms or a cyclic alkyl group having 3 to 10 carbon atoms.

In some embodiments, R₂ is selected from —H, -D, a linear alkyl group having 1 to 10 carbon atoms, a branched alkyl group having 3 to 10 carbon atoms, an aromatic group having 5 to 20 ring atoms, a heteroaromatic group having 5 to 20 ring atoms, an aromatic group having 5 to 20 ring atoms substituted by a linear alkyl group having 1 to 10 carbon atoms, a branched alkyl group having 3 to 10 carbon atoms, or a cycloalkyl group having 3 to 10 carbon atoms, or a heteroaromatic group having 5 to 20 ring atoms substituted by a branched alkyl group having 3 to 10 carbon atoms or a cycloalkyl group having 3 to 10 carbon atoms.

Further, R₂ is selected from —H, -D, a linear alkyl group having 1 to 5 carbon atoms, or a branched alkyl group having 3 to 10 carbon atoms, or a group consisting of the following structures:

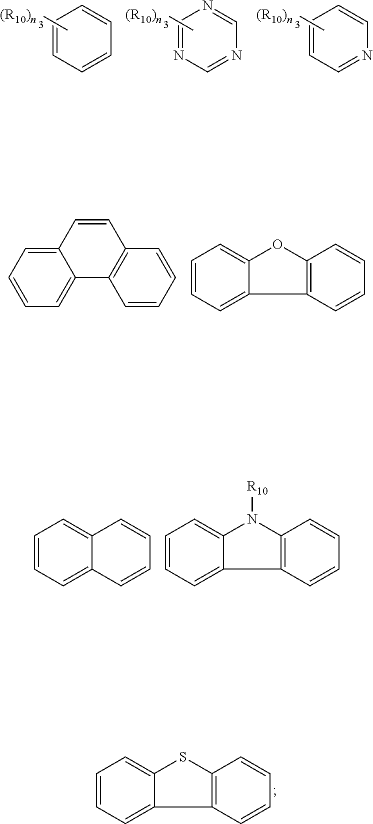

in which R₁₀ at each occurrence is independently selected from —H, -D, a linear alkyl group having 1 to 10 carbon atoms, an aromatic group having 5 to 20 ring atoms, a heteroaromatic group having 5 to 20 ring atoms, an aromatic group having 5 to 20 ring atoms substituted by a linear alkyl group having 1 to 10 carbon atoms, a branched alkyl group having 3 to 10 carbon atoms, or a cycloalkyl group having 3 to 10 carbon atoms, or a heteroaromatic group having 5 to 20 ring atoms substituted by a branched alkyl group having 3 to 10 carbon atoms or a cycloalkyl group having 3 to 10 carbon atoms; and n3 is an integer from 1 to 4. In some embodiments, n3 is an integer from 1 to 3.

In some embodiments, n3 is 1. In other embodiments, n3 is 2.

In one embodiment, R₁₀ is independently selected from —H, -D, a linear alkyl group having 1 to 5 carbon atoms, a branched alkyl group having 3 to 5 carbon atoms, an aromatic group having 5 to 10 ring atoms, or a heteroaromatic group having 5 to 10 ring atoms. Further, R₁₀ is independently selected from —H, -D, methyl, —CD₃, isopropyl, tert-butyl, or phenyl.

In one embodiment, the organic boron-nitrogen compound is represented by any one of formulae (2-1) to (2-12):

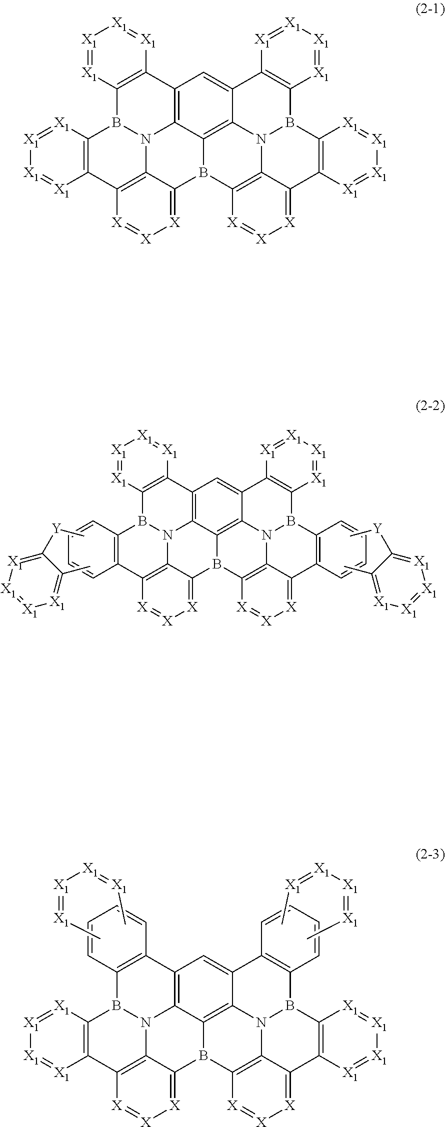

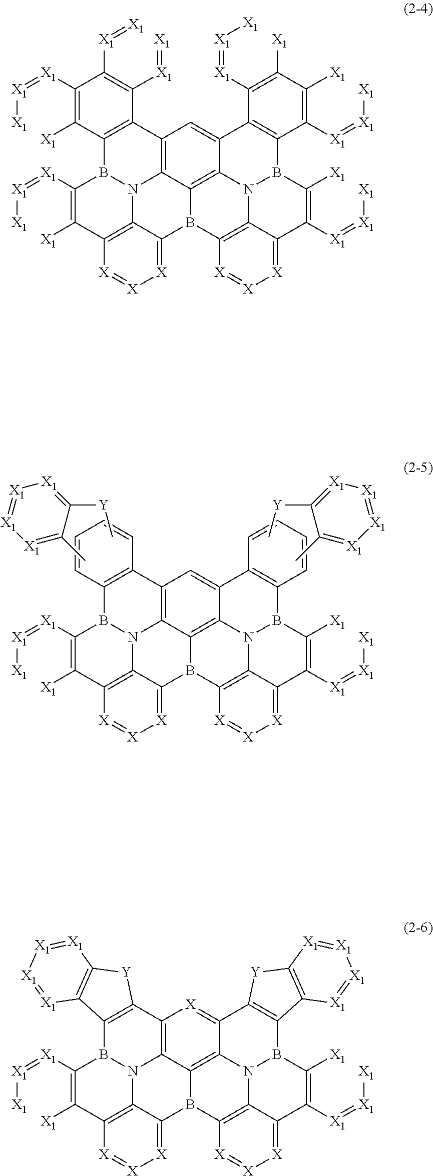

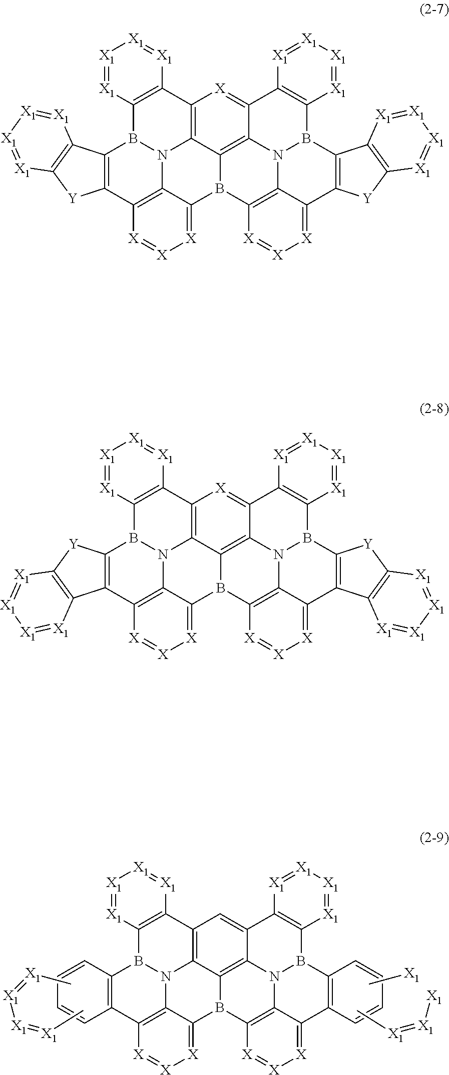

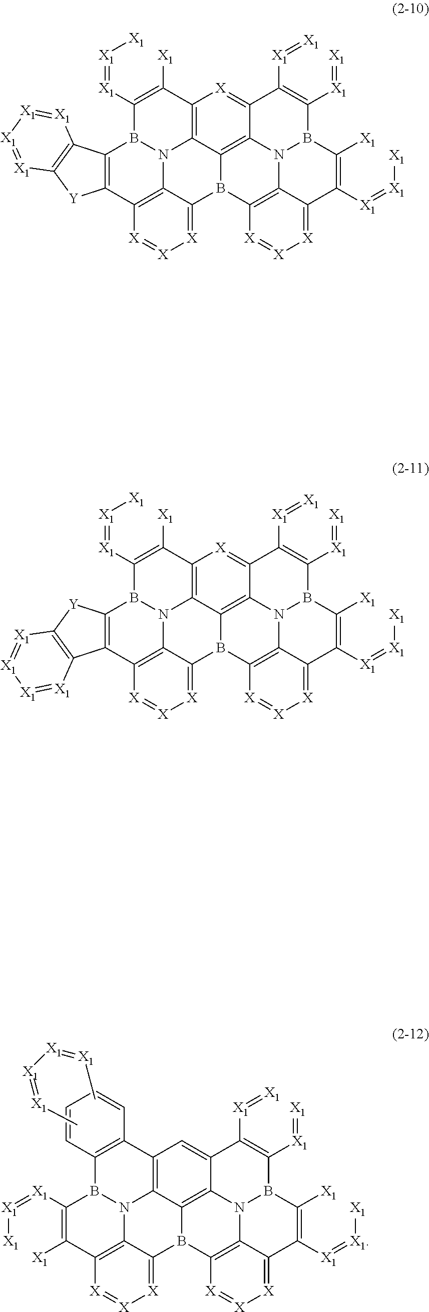

In some embodiments, X at each occurrence is selected from CR₁, and R₁ at each occurrence is independently from —H, -D, a linear alkyl group having 1 to 10 carbon atoms, a branched alkyl group having 3 to 10 carbon atoms, a cycloalkyl group having 3 to 10 carbon atoms, a substituted or unsubstituted aromatic group having 5 to 20 ring atoms, a substituted or unsubstituted heteroaromatic group having 5 to 20 ring atoms, or any combination of these groups.

In one embodiment, X is CH.

Further, R₁ at each occurrence is independently from —H, -D, a linear alkyl group having 1 to 5 carbon atoms, or a branched alkyl group having 3 to 10 carbon atoms. Furthermore, R₁ is independently selected from —H, methyl, —CD₃, isopropyl, or the following structure:

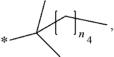

in which n4 is an integer from 0 to 4.

Understandably, when n4 is 0, R₁ is tert-butyl.

Further, n4 is selected from 0 or 1.

In one embodiment, when Ar¹ to Ar⁷ are selected from the formula (C-2). The formula (C-2) is represented by the following formula:

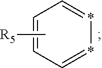

in which R₅ has the same meaning as described above. Further, the formula (C-2) has a structure selected from a group consisting of the following structures:

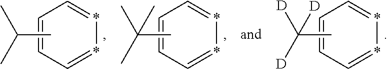

In some embodiments, the organic boron-nitrogen compound is represented by formula (I-1) or formula (II-1):

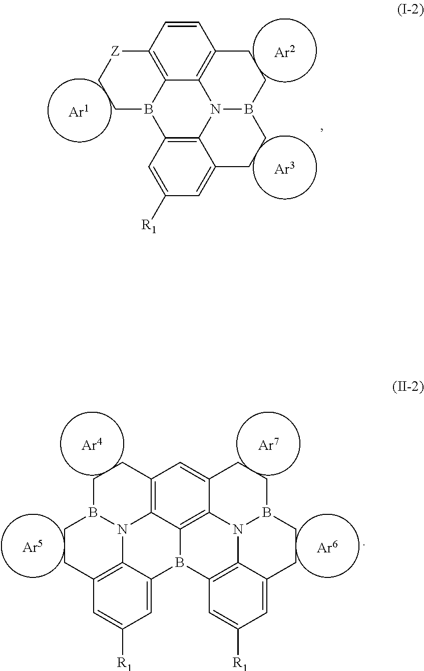

Preferably, R₁ is independently selected from methyl, isopropyl, —CD₃, or the following structure:

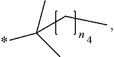

in which n₄ is an integer from 0 to 4.

Further, examples of the organic boron-nitrogen compound of the disclosure include, but not limited to, the structures represented by formulae (1) to (236):

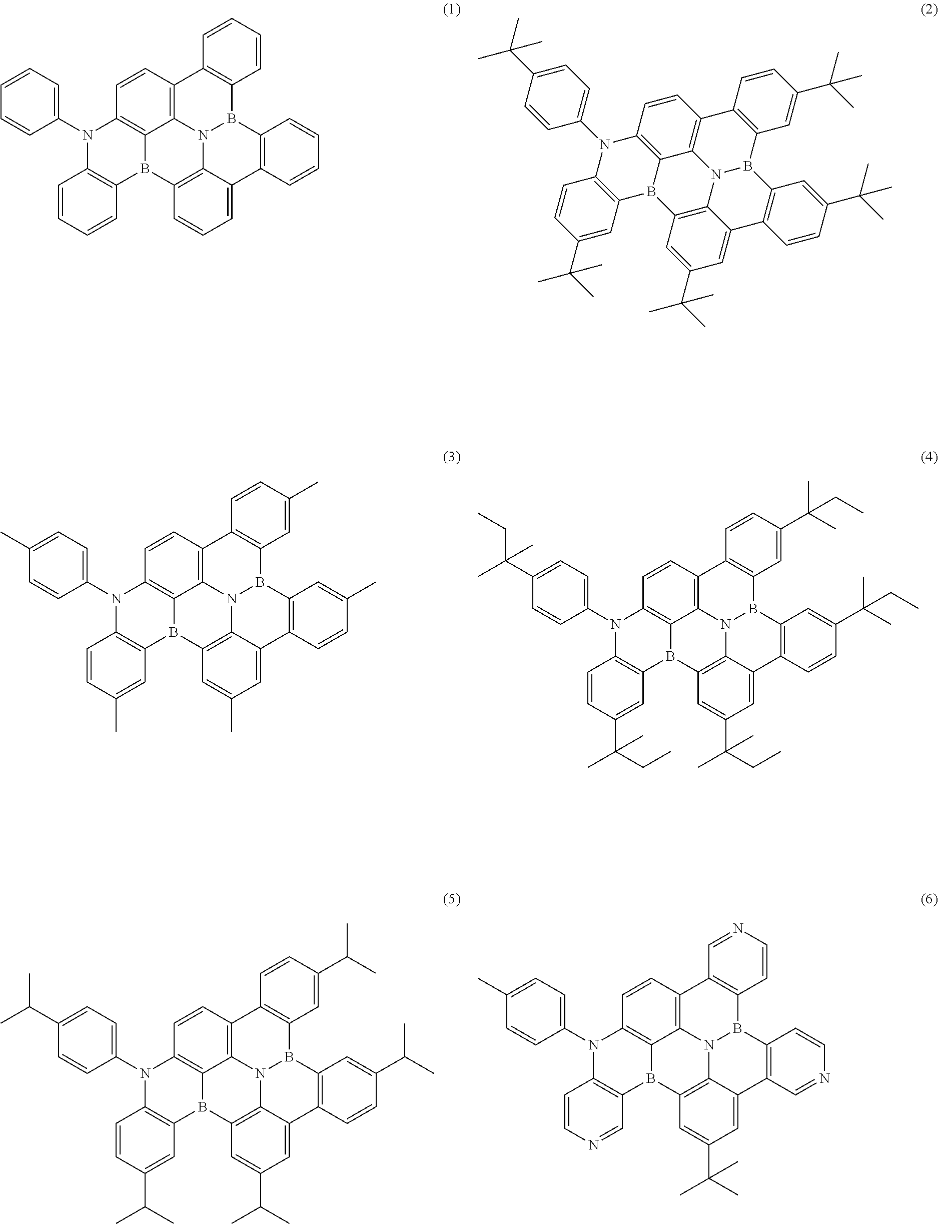

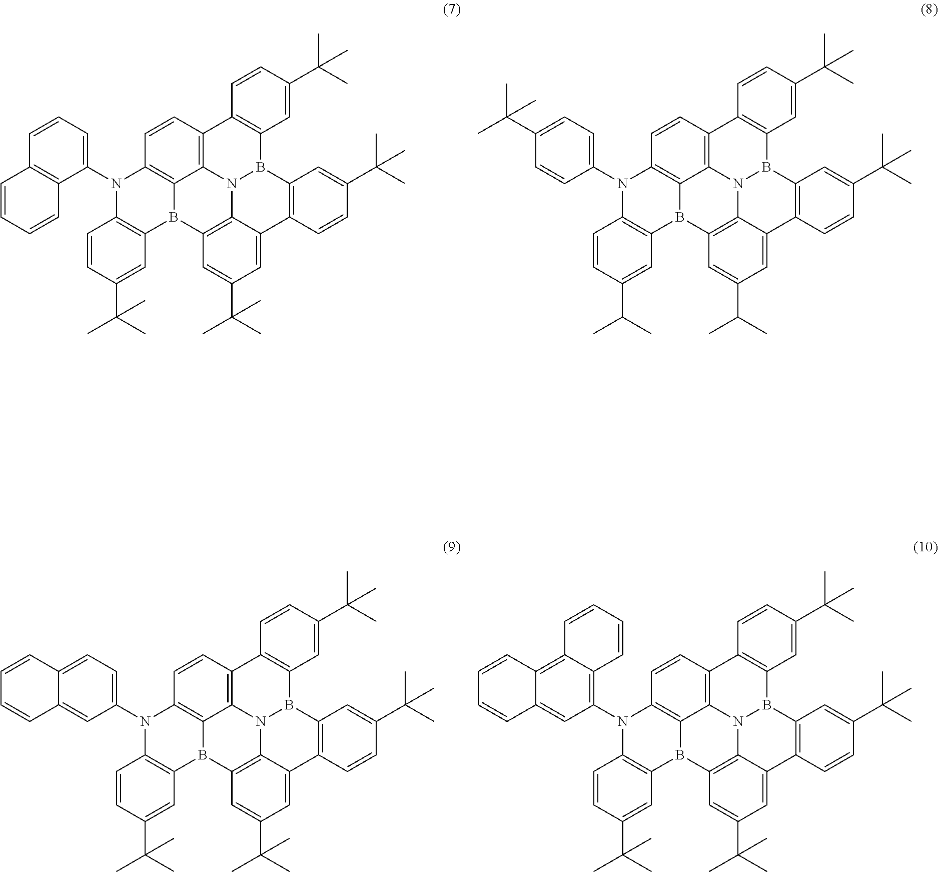 [SMILES: CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1cccc2ccccc12 ; CC(C)c1ccc2c(c1)B1c3cc(C(C)C)cc4c3N3B(c5cc(C(C)(C)C)ccc5-4)c4cc(C(C)(C)C)ccc4-c4ccc(c1c43)N2c1ccc(C(C)(C)C)cc1 ; CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1ccc2ccccc2c1 ; CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1cc2ccccc2c2ccccc12]

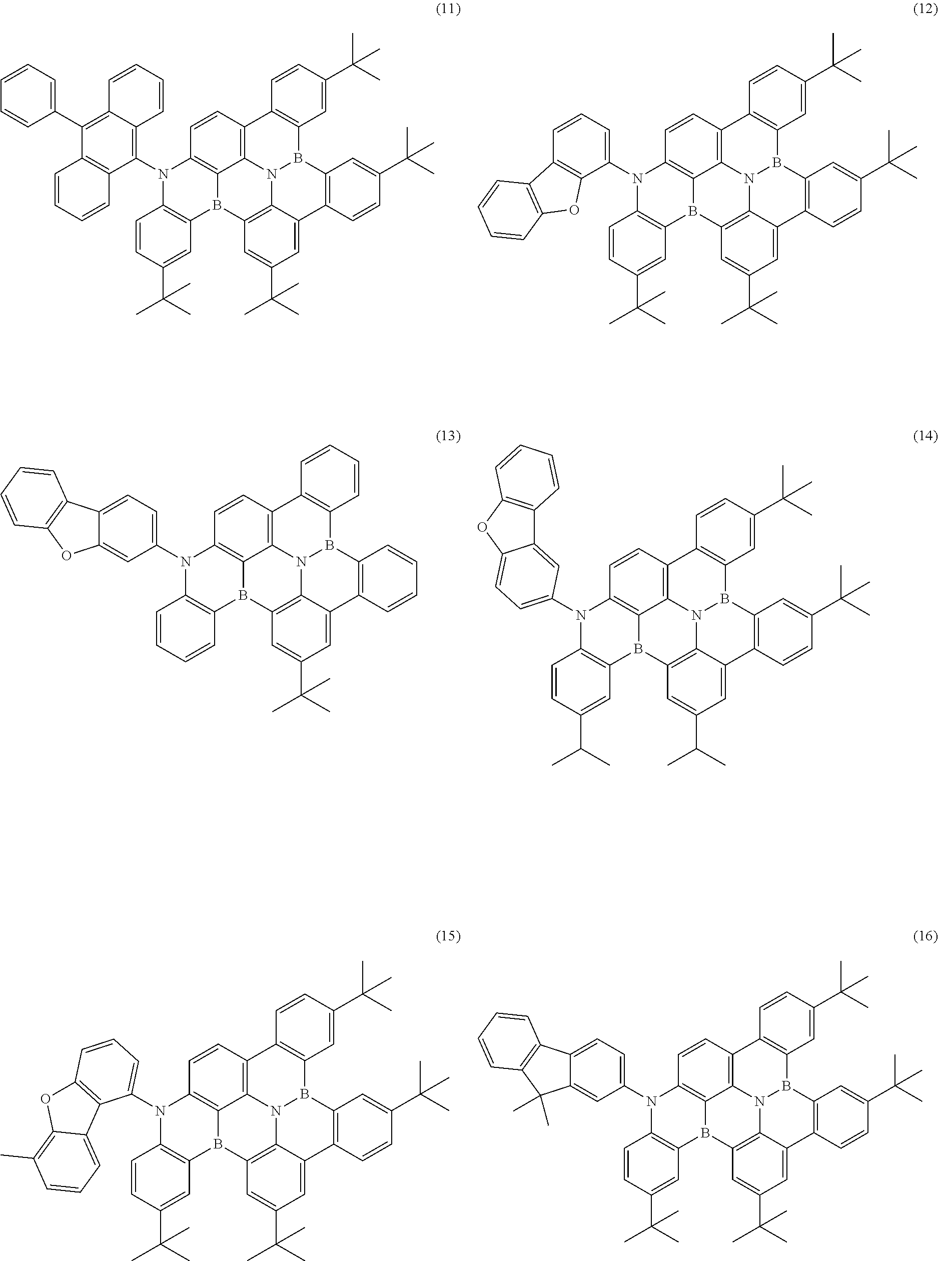

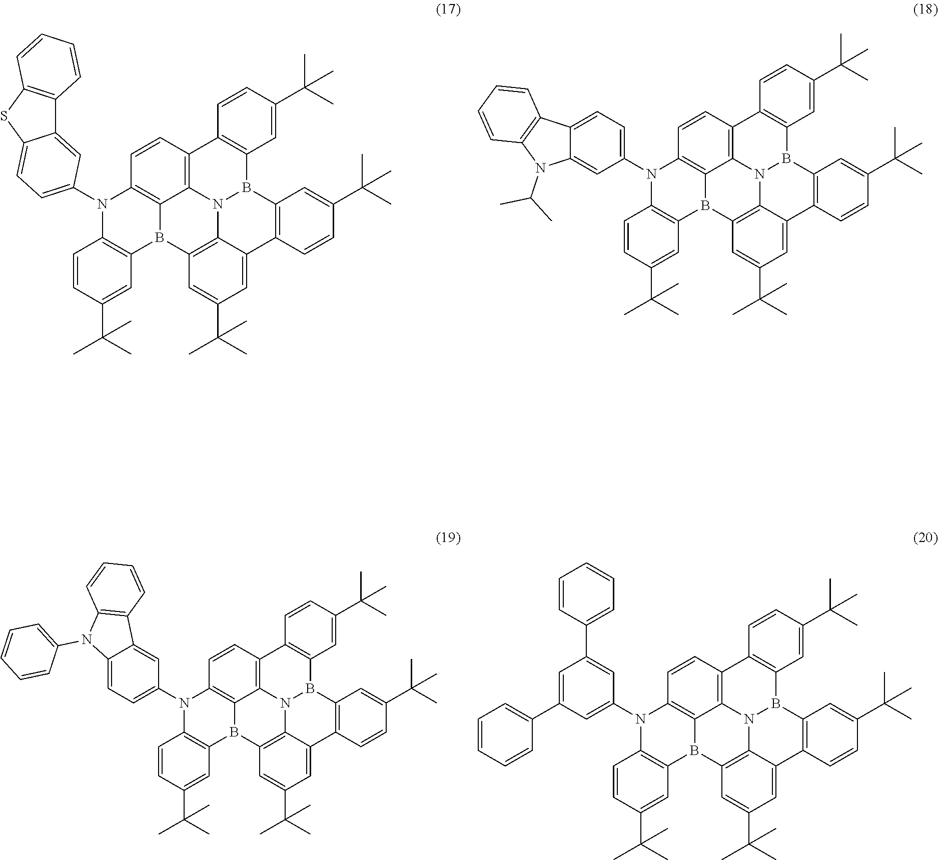 [SMILES: CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1ccc2sc3ccccc3c2c1 ; CC(C)n1c2ccccc2c2ccc(N3c4ccc(C(C)(C)C)cc4B4c5cc(C(C)(C)C)cc6c5N5B(c7cc(C(C)(C)C)ccc7-6)c6cc(C(C)(C)C)ccc6-c6ccc3c4c65)cc21 ; CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1ccc2c(c1)c1ccccc1n2-c1ccccc1 ; CC(C)(C)c1ccc2c(c1)B1c3cc(C(C)(C)C)ccc3-c3ccc4c5c3N1c1c(cc(C(C)(C)C)cc1-2)B5c1cc(C(C)(C)C)ccc1N4c1cc(-c2ccccc2)cc(-c2ccccc2)c1]

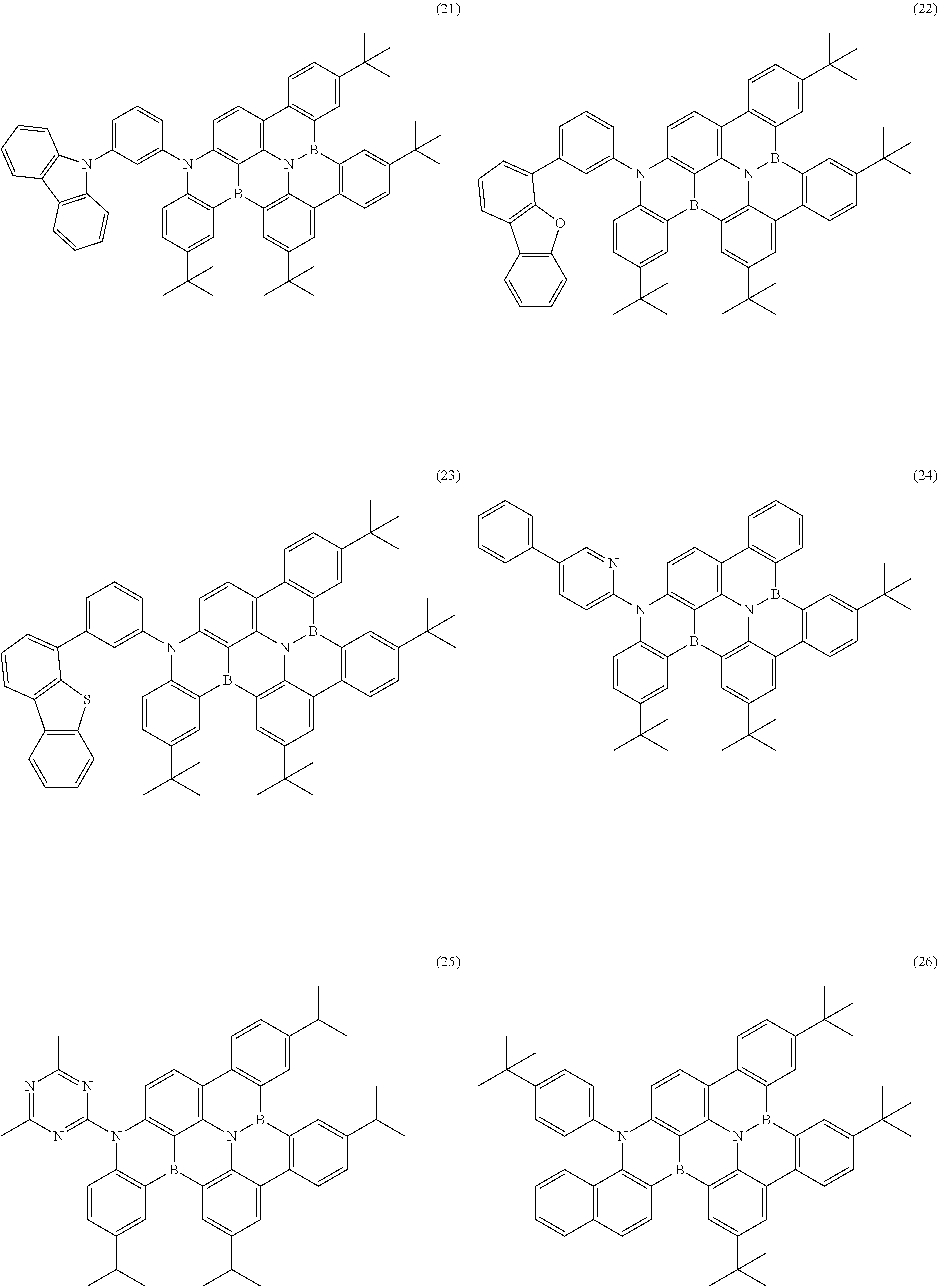

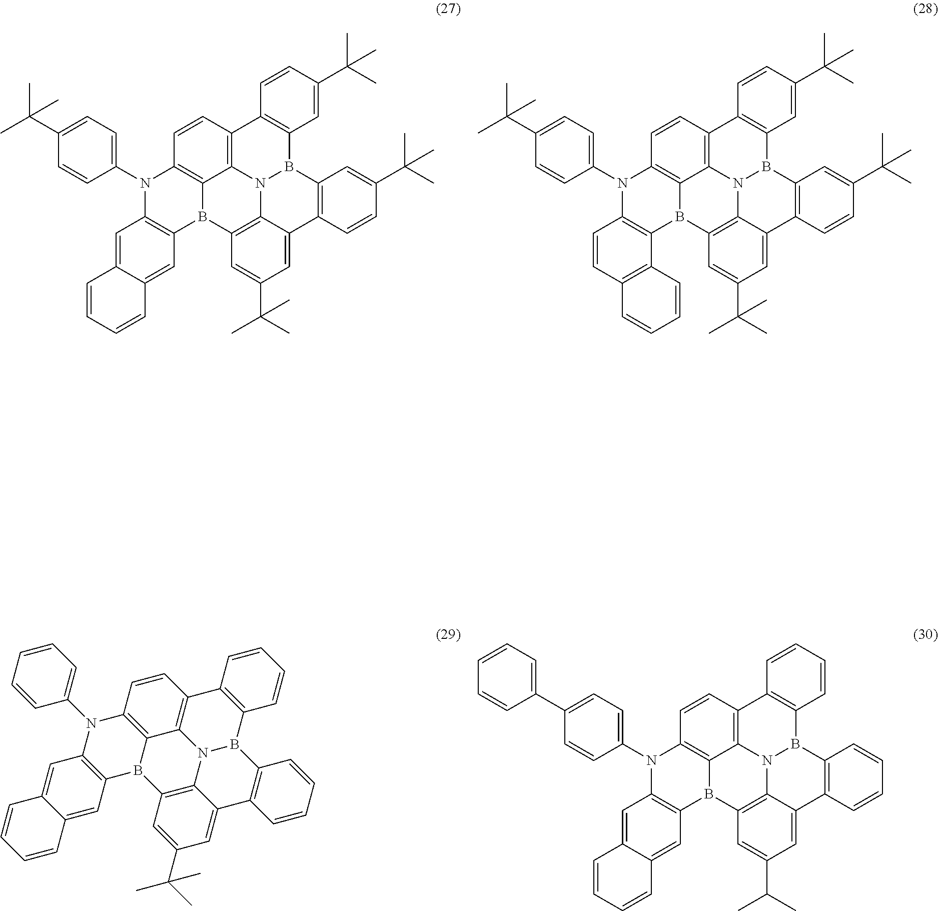 [SMILES: CC(C)(C)c1ccc(N2c3cc4ccccc4cc3B3c4cc(C(C)(C)C)cc5c4N4B(c6cc(C(C)(C)C)ccc6-5)c5cc(C(C)(C)C)ccc5-c5ccc2c3c54)cc1 ; CC(C)(C)c1ccc(N2c3ccc4c5c3B(c3cc(C(C)(C)C)cc6c3N5B(c3cc(C(C)(C)C)ccc3-6)c3cc(C(C)(C)C)ccc3-4)c3c2ccc2ccccc32)cc1 ; CC(C)(C)c1cc2c3c(c1)-c1ccccc1B1c4ccccc4-c4ccc5c(c4N13)B2c1cc2ccccc2cc1N5c1ccccc1 ; CC(C)c1cc2c3c(c1)-c1ccccc1B1c4ccccc4-c4ccc5c(c4N13)B2c1cc2ccccc2cc1N5c1ccc(-c2ccccc2)cc1]

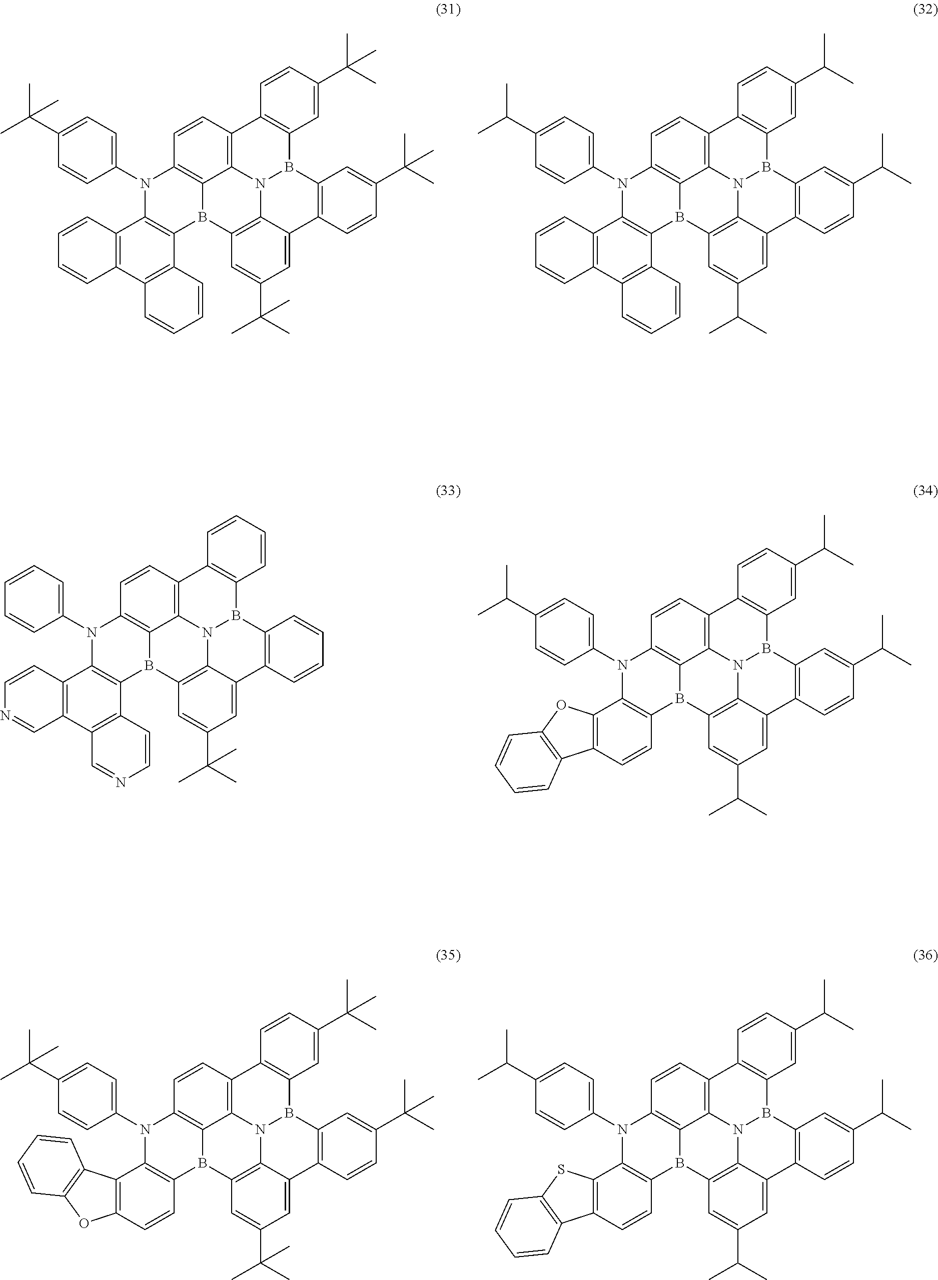

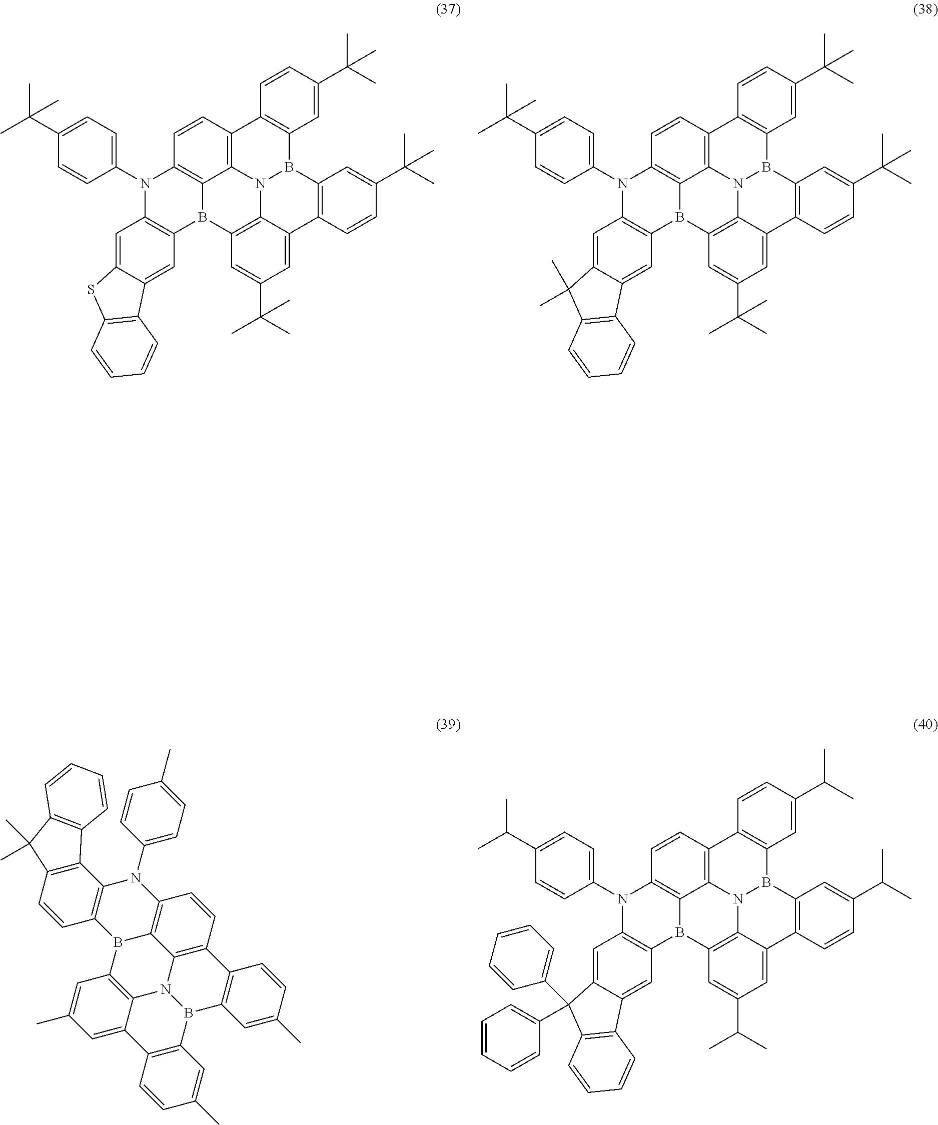

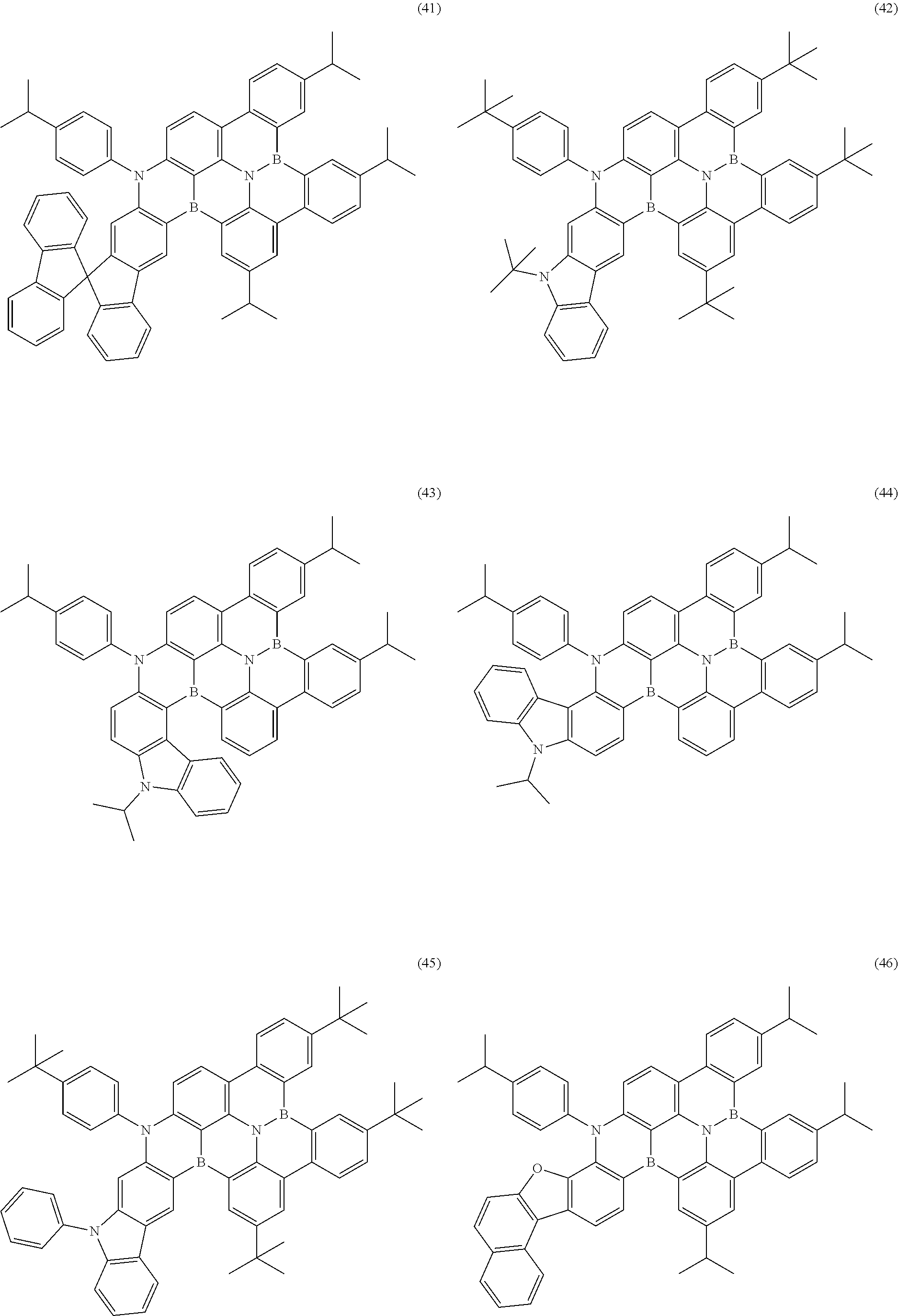

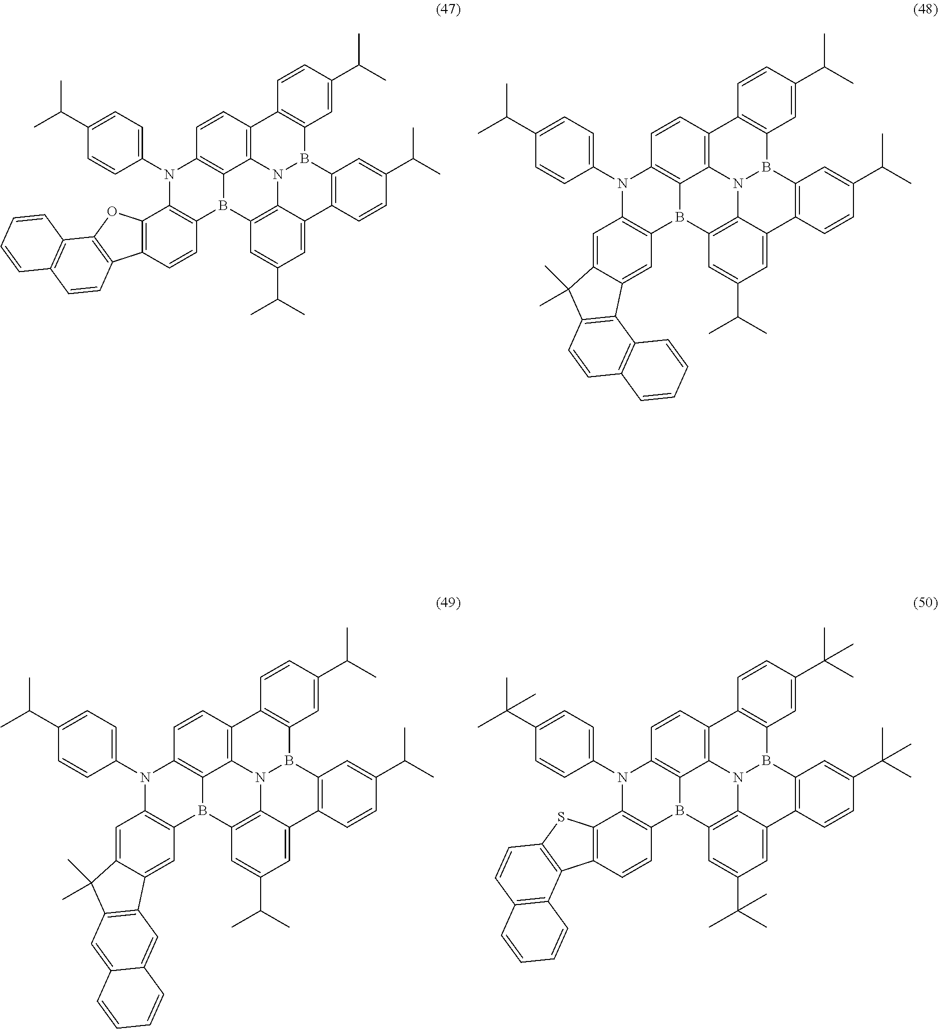 [SMILES: CC(C)c1ccc(N2c3ccc4c5c3B(c3cc(C(C)C)cc6c3N5B(c3cc(C(C)C)ccc3-6)c3cc(C(C)C)ccc3-4)c3ccc4c(oc5c6ccccc6ccc45)c32)cc1 ; CC(C)c1ccc(N2c3cc4c(cc3B3c5cc(C(C)C)cc6c5N5B(c7cc(C(C)C)ccc7-6)c6cc(C(C)C)ccc6-c6ccc2c3c65)-c2c(ccc3ccccc23)C4(C)C)cc1 ; CC(C)c1ccc(N2c3cc4c(cc3B3c5cc(C(C)C)cc6c5N5B(c7cc(C(C)C)ccc7-6)c6cc(C(C)C)ccc6-c6ccc2c3c65)-c2cc3ccccc3cc2C4(C)C)cc1 ; CC(C)(C)c1ccc(N2c3ccc4c5c3B(c3cc(C(C)(C)C)cc6c3N5B(c3cc(C(C)(C)C)ccc3-6)c3cc(C(C)(C)C)ccc3-4)c3ccc4c(sc5ccc6ccccc6c54)c32)cc1]

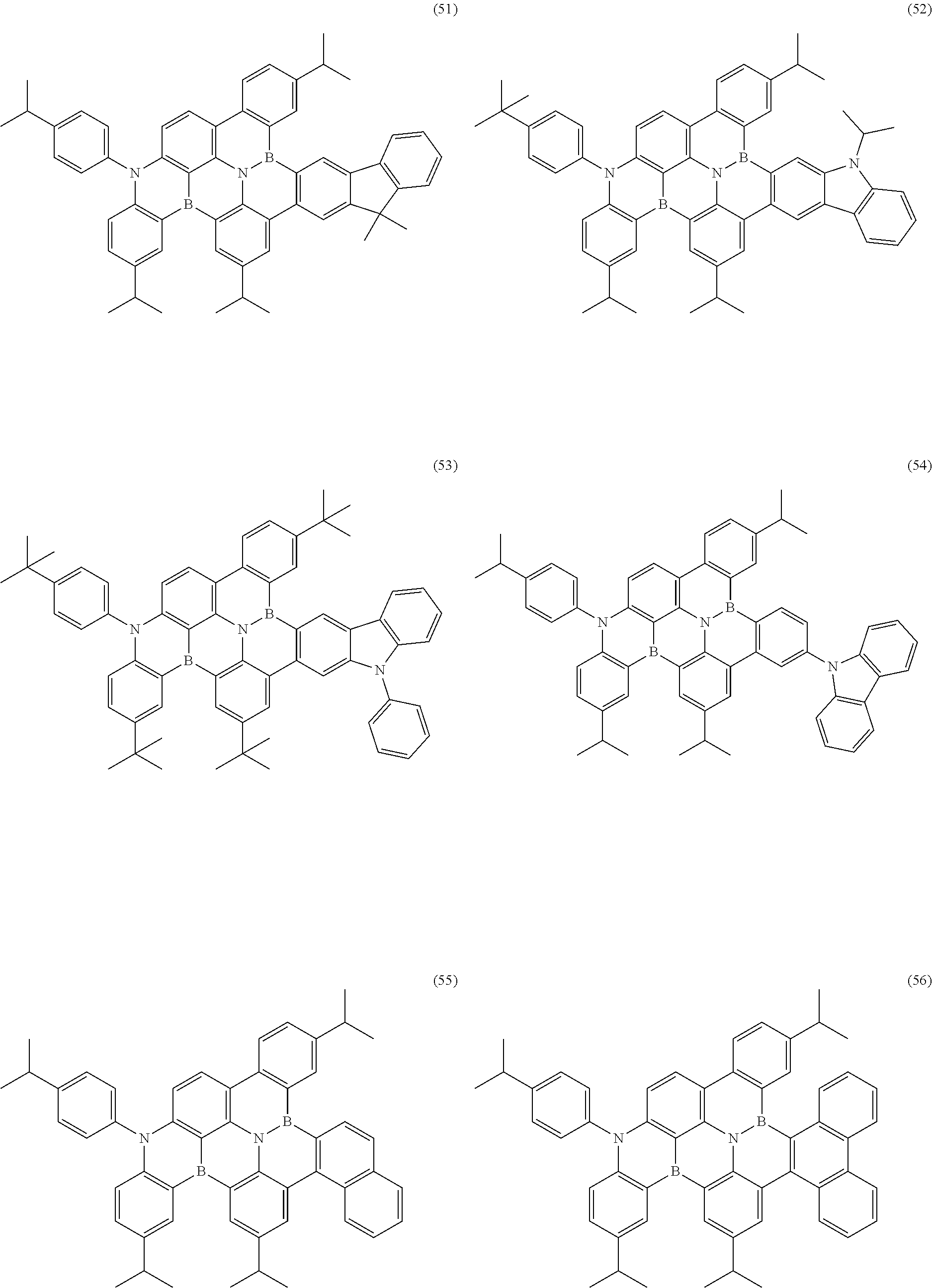

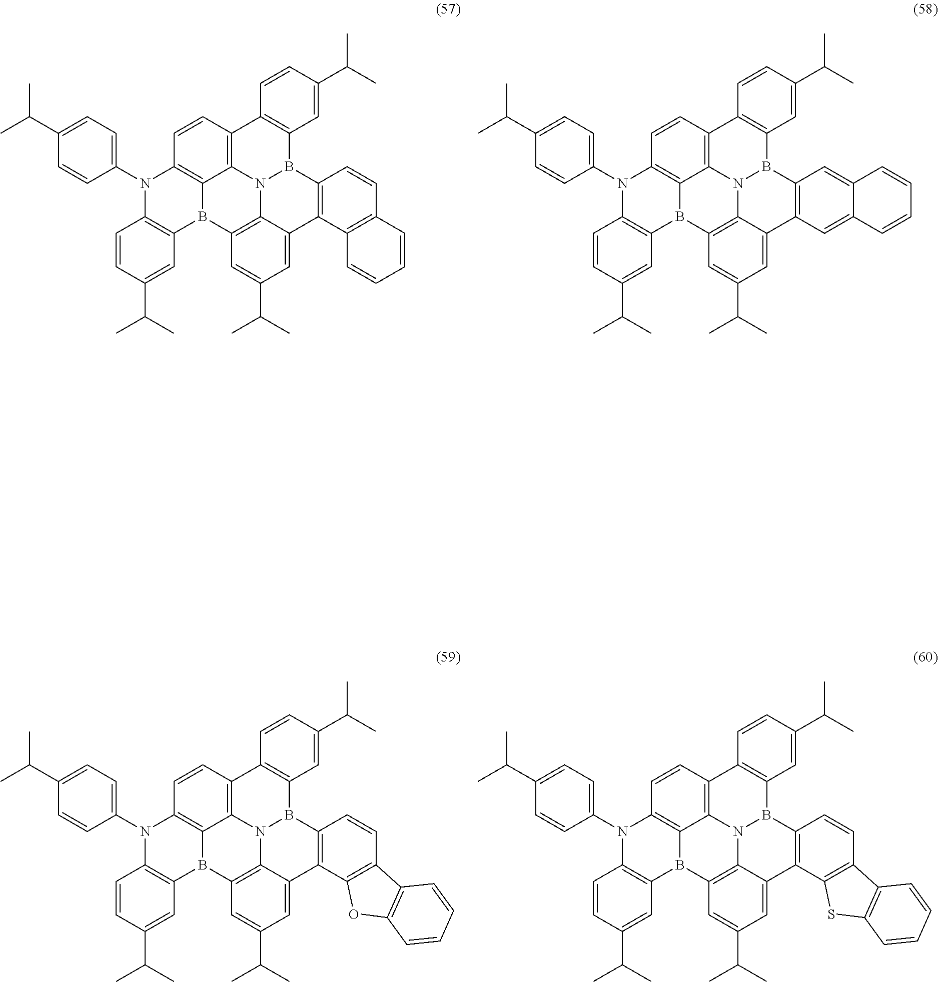 [SMILES: CC(C)c1ccc(N2c3ccc(C(C)C)cc3B3c4cc(C(C)C)cc5c4N4B(c6cc(C(C)C)ccc6-c6ccc2c3c64)c2ccc3ccccc3c2-5)cc1 ; CC(C)c1ccc(N2c3ccc(C(C)C)cc3B3c4cc(C(C)C)cc5c4N4B(c6cc7ccccc7cc6-5)c5cc(C(C)C)ccc5-c5ccc2c3c54)cc1 ; CC(C)c1ccc(N2c3ccc(C(C)C)cc3B3c4cc(C(C)C)cc5c4N4B(c6cc(C(C)C)ccc6-c6ccc2c3c64)c2ccc3c(oc4ccccc43)c2-5)cc1 ; CC(C)c1ccc(N2c3ccc(C(C)C)cc3B3c4cc(C(C)C)cc5c4N4B(c6cc(C(C)C)ccc6-c6ccc2c3c64)c2ccc3c(sc4ccccc43)c2-5)cc1]

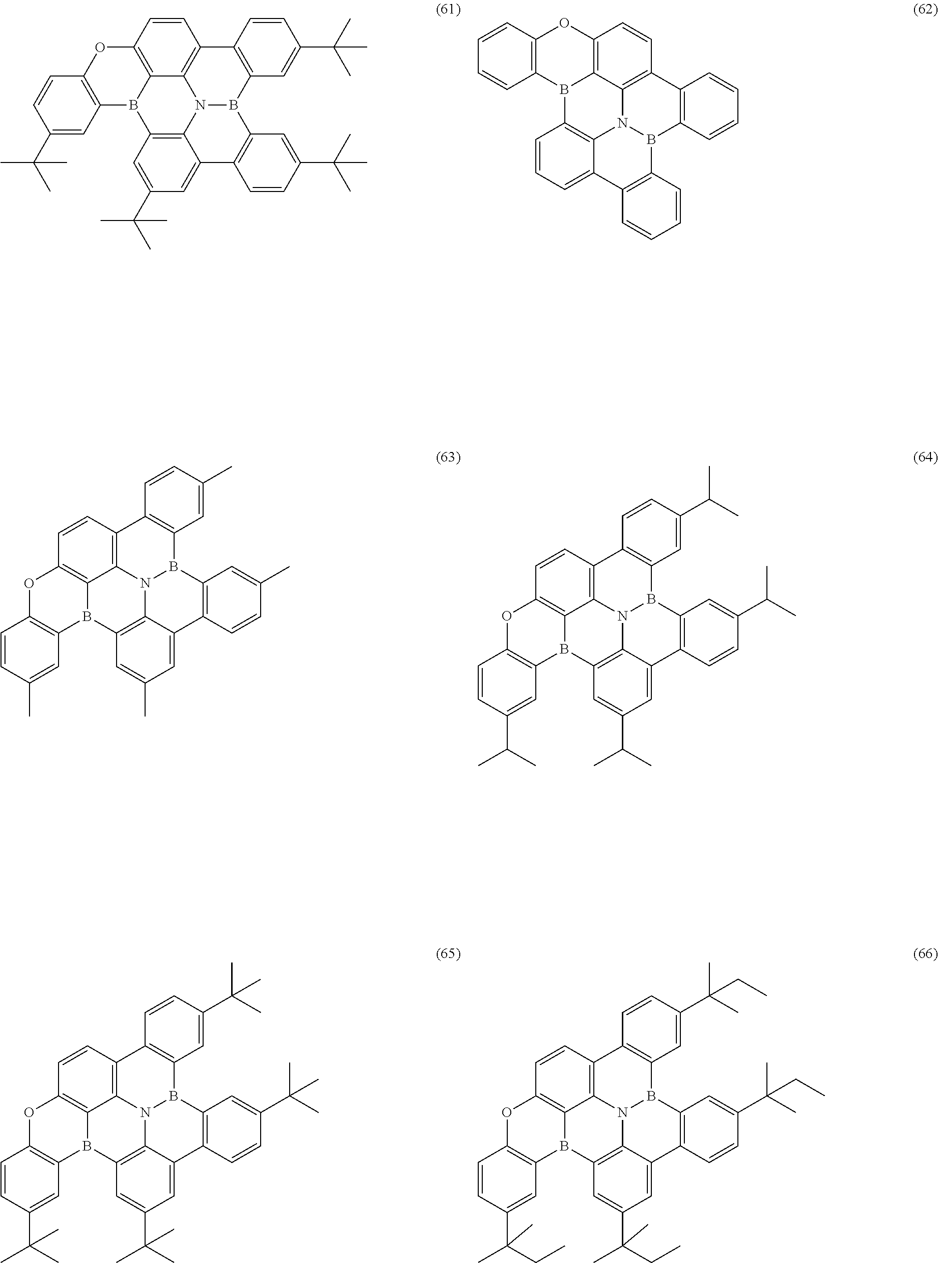

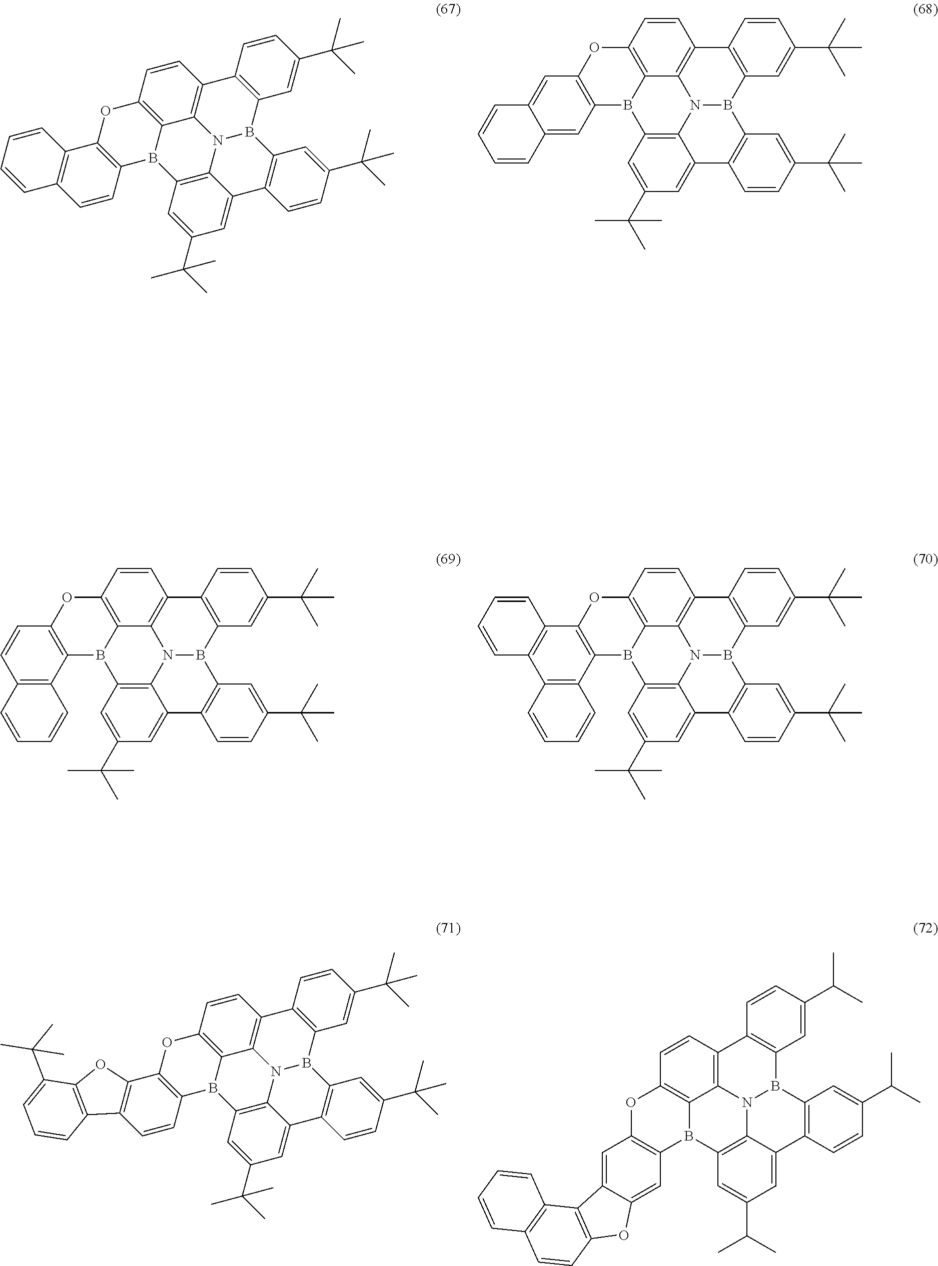

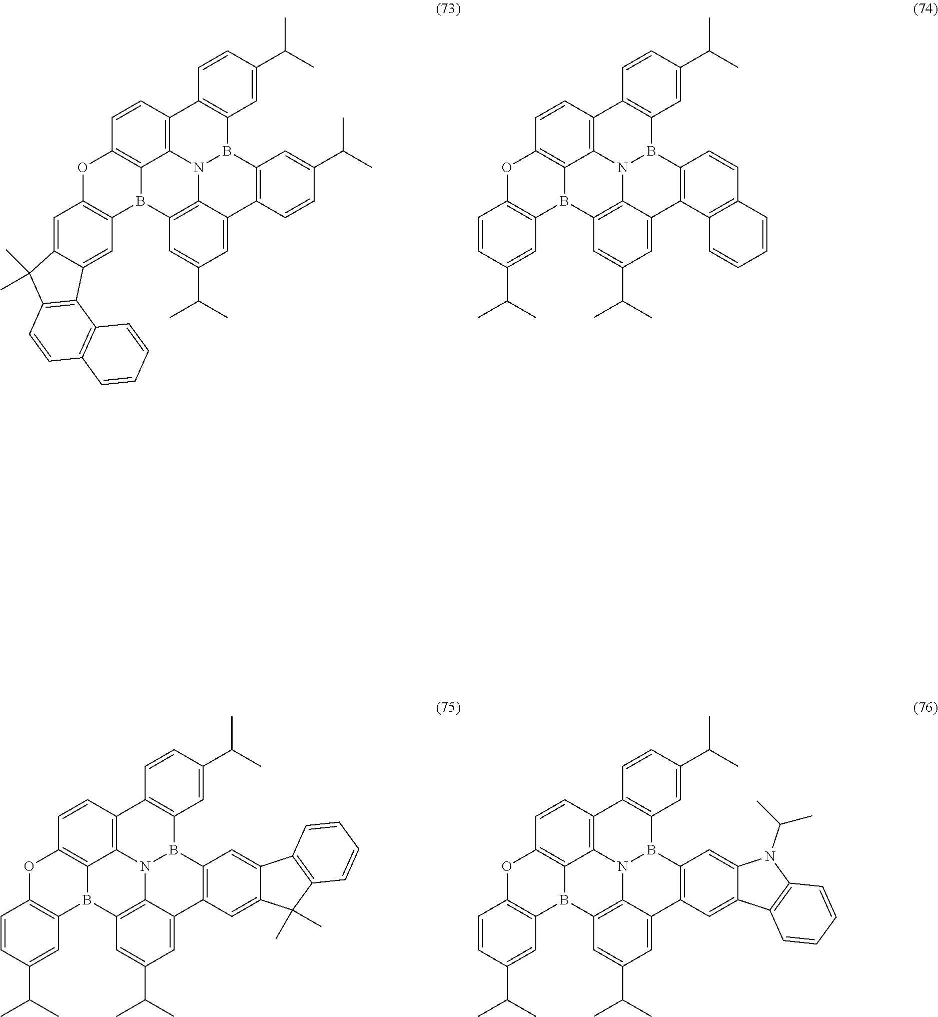 [SMILES: CC(C)c1ccc2c(c1)B1c3cc(C(C)C)ccc3-c3ccc4c5c3N1c1c(cc(C(C)C)cc1-2)B5c1cc2c(cc1O4)C(C)(C)c1ccc3ccccc3c1-2 ; CC(C)c1ccc2c(c1)B1c3cc(C(C)C)cc4c3N3B(c5cc(C(C)C)ccc5-c5ccc(c1c53)O2)c1ccc2ccccc2c1-4 ; CC(C)c1ccc2c(c1)B1c3cc(C(C)C)cc4c3N3B(c5cc6c(cc5-4)C(C)(C)c4ccccc4-6)c4cc(C(C)C)ccc4-c4ccc(c1c43)O2 ; CC(C)c1ccc2c(c1)B1c3cc(C(C)C)cc4c3N3B(c5cc6c(cc5-4)c4ccccc4n6C(C)C)c4cc(C(C)C)ccc4-c4ccc(c1c43)O2]

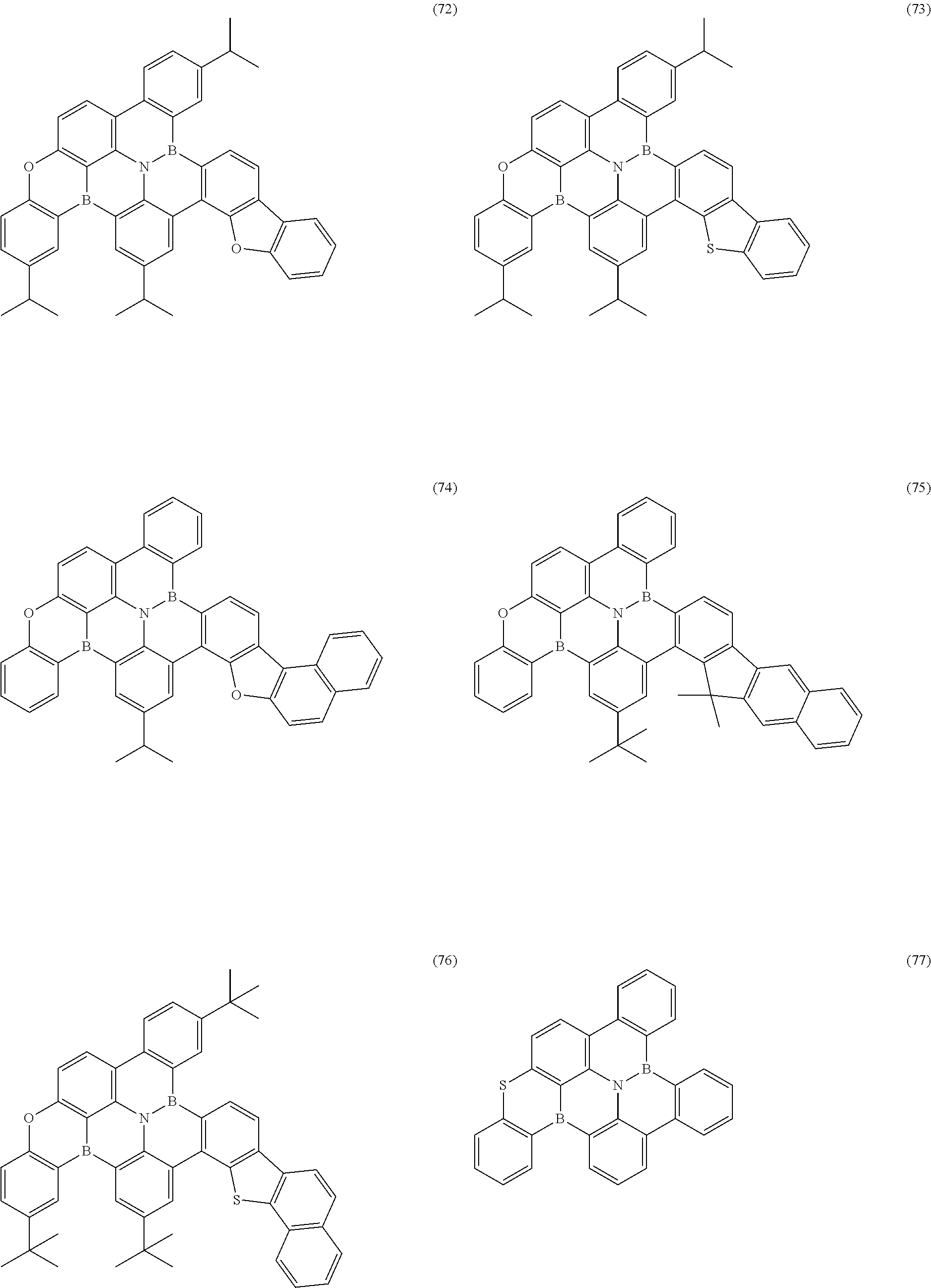

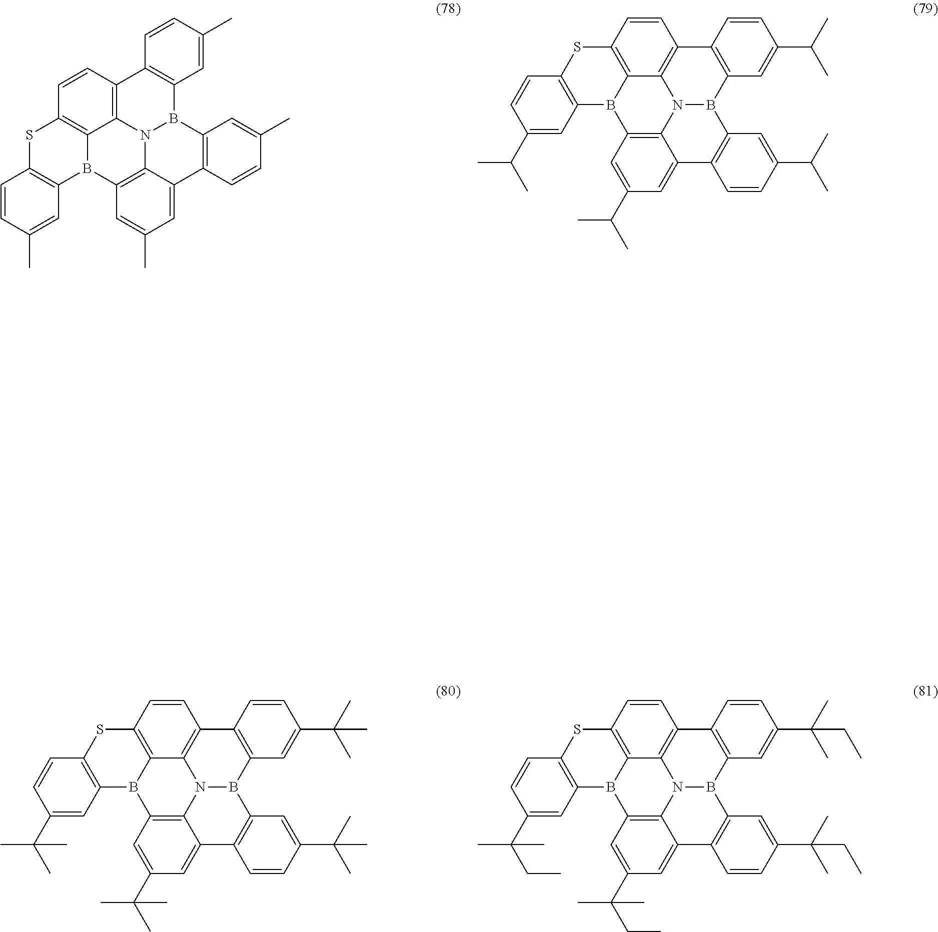 [SMILES: Cc1ccc2c(c1)B1c3cc(C)cc4c3N3B(c5cc(C)ccc5-4)c4cc(C)ccc4-c4ccc(c1c43)S2 ; CC(C)c1ccc2c(c1)B1c3cc(C(C)C)cc4c3N3B(c5cc(C(C)C)ccc5-4)c4cc(C(C)C)ccc4-c4ccc(c1c43)S2 ; CC(C)(C)c1ccc2c(c1)B1c3cc(C(C)(C)C)cc4c3N3B(c5cc(C(C)(C)C)ccc5-4)c4cc(C(C)(C)C)ccc4-c4ccc(c1c43)S2 ; CCC(C)(C)c1ccc2c(c1)B1c3cc(C(C)(C)CC)cc4c3N3B(c5cc(C(C)(C)CC)ccc5-4)c4cc(C(C)(C)CC)ccc4-c4ccc(c1c43)S2]

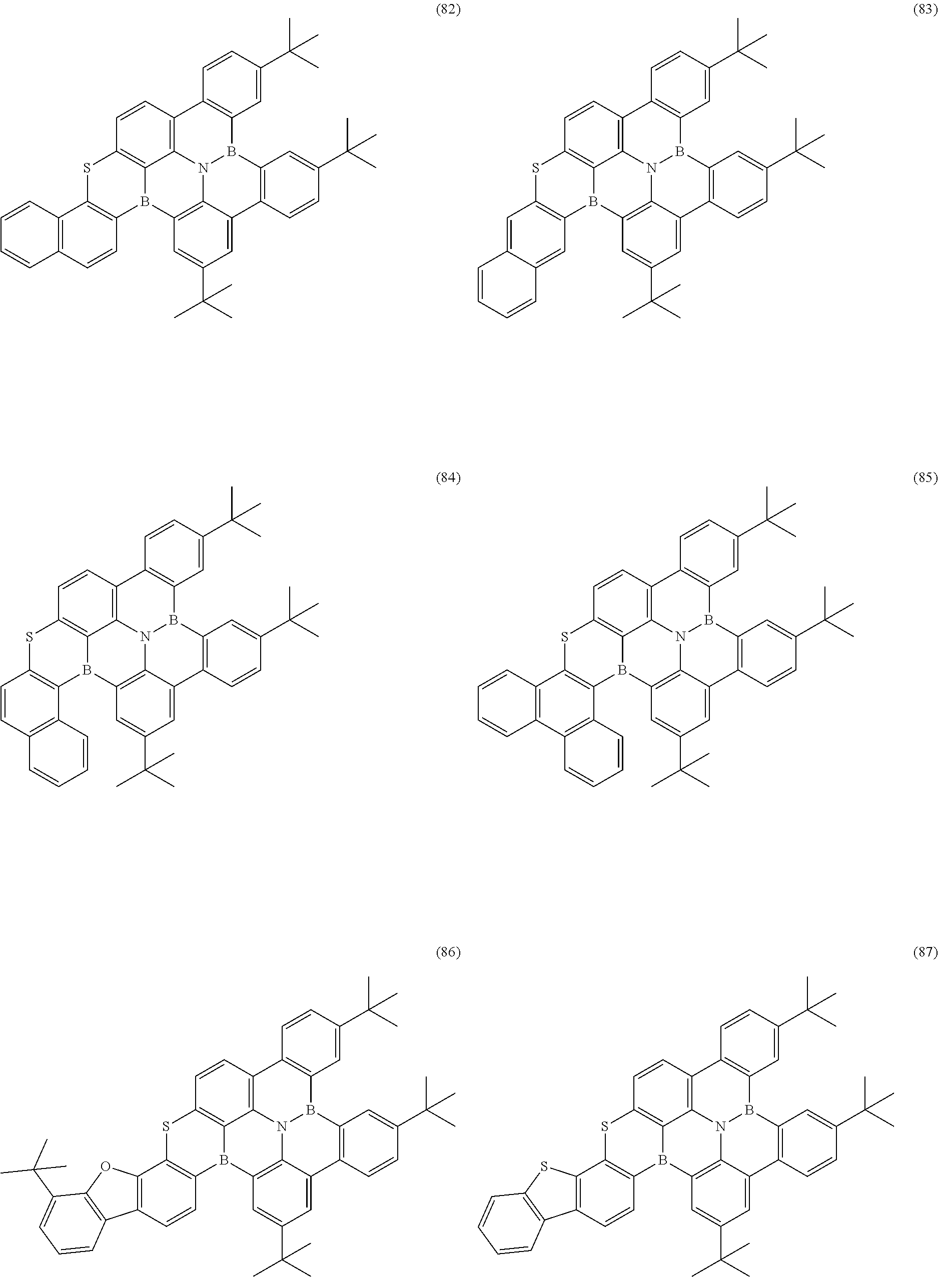

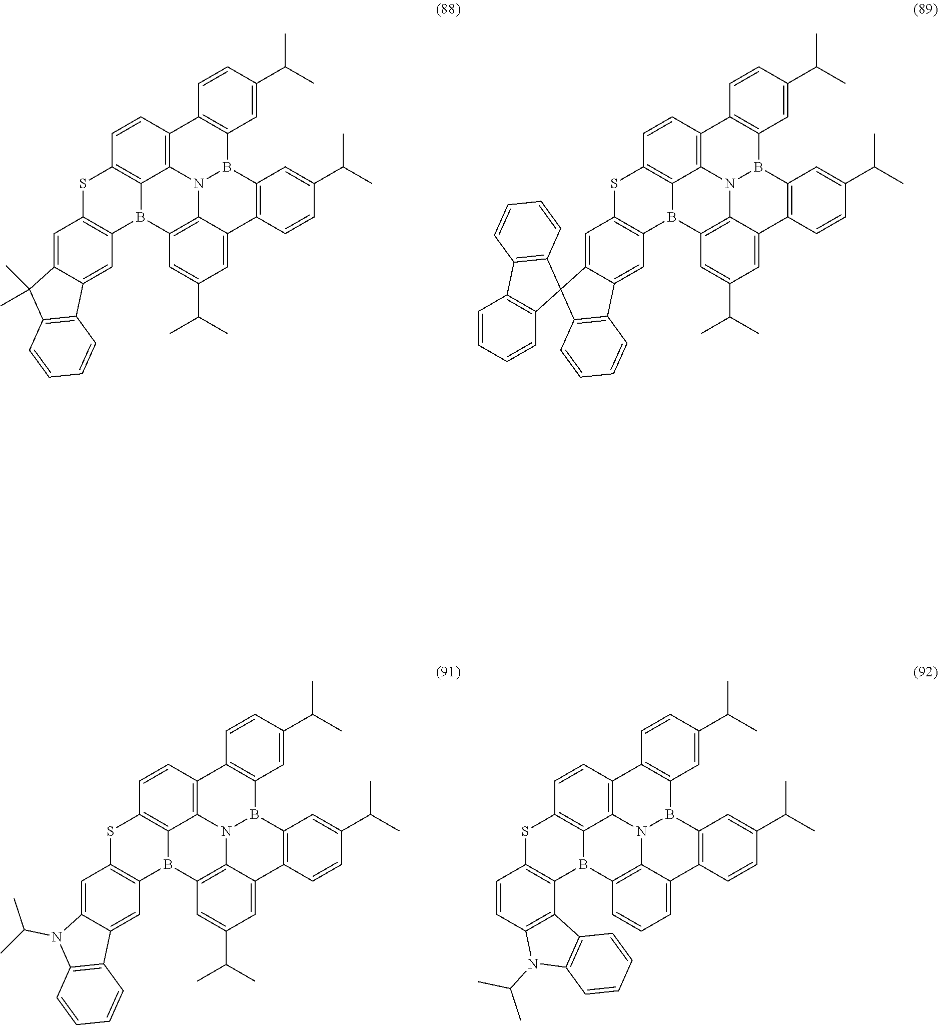 [SMILES: CC(C)c1ccc2c(c1)B1c3cc(C(C)C)ccc3-c3ccc4c5c3N1c1c(cc(C(C)C)cc1-2)B5c1cc2c(cc1S4)C(C)(C)c1ccccc1-2 ; CC(C)c1ccc2c(c1)B1c3cc(C(C)C)ccc3-c3ccc4c5c3N1c1c(cc(C(C)C)cc1-2)B5c1cc2c(cc1S4)C1(c3ccccc3-c3ccccc31)c1ccccc1-2 ; CC(C)c1ccc2c(c1)B1c3cc(C(C)C)ccc3-c3ccc4c5c3N1c1c(cc(C(C)C)cc1-2)B5c1cc2c3ccccc3n(C(C)C)c2cc1S4 ; CC(C)c1ccc2c(c1)B1c3cc(C(C)C)ccc3-c3ccc4c5c3N1c1c(cccc1-2)B5c1c(ccc2c1c1ccccc1n2C(C)C)S4]

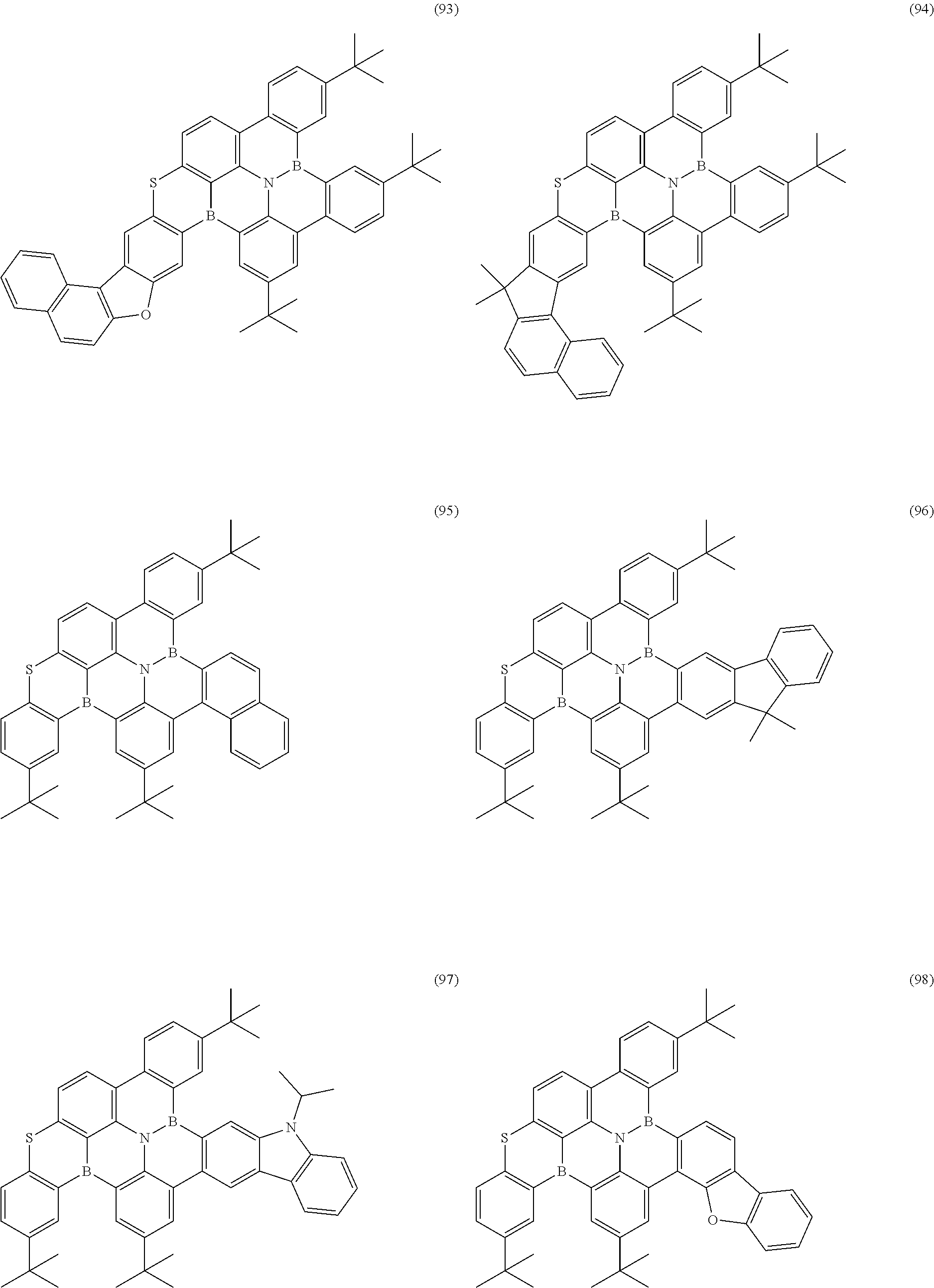

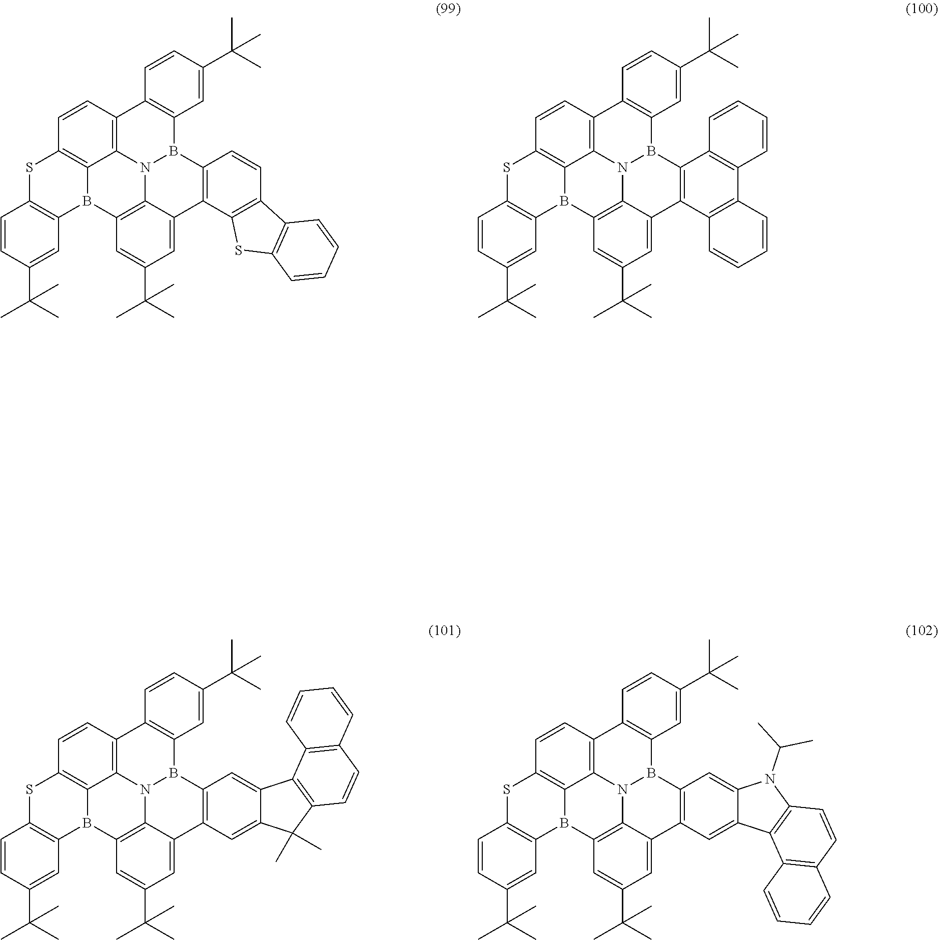 [SMILES: CC(C)(C)c1ccc2c(c1)B1c3cc(C(C)(C)C)cc4c3N3B(c5cc(C(C)(C)C)ccc5-c5ccc(c1c53)S2)c1ccc2c(sc3ccccc32)c1-4 ; CC(C)(C)c1ccc2c(c1)B1c3cc(C(C)(C)C)cc4c3N3B(c5cc(C(C)(C)C)ccc5-c5ccc(c1c53)S2)c1c-4c2ccccc2c2ccccc12 ; CC(C)(C)c1ccc2c(c1)B1c3cc(C(C)(C)C)cc4c3N3B(c5cc6c(cc5-4)C(C)(C)c4ccc5ccccc5c4-6)c4cc(C(C)(C)C)ccc4-c4ccc(c1c43)S2 ; CC(C)n1c2cc3c(cc2c2c4ccccc4ccc21)-c1cc(C(C)(C)C)cc2c1N1B3c3cc(C(C)(C)C)ccc3-c3ccc4c(c31)B2c1cc(C(C)(C)C)ccc1S4]

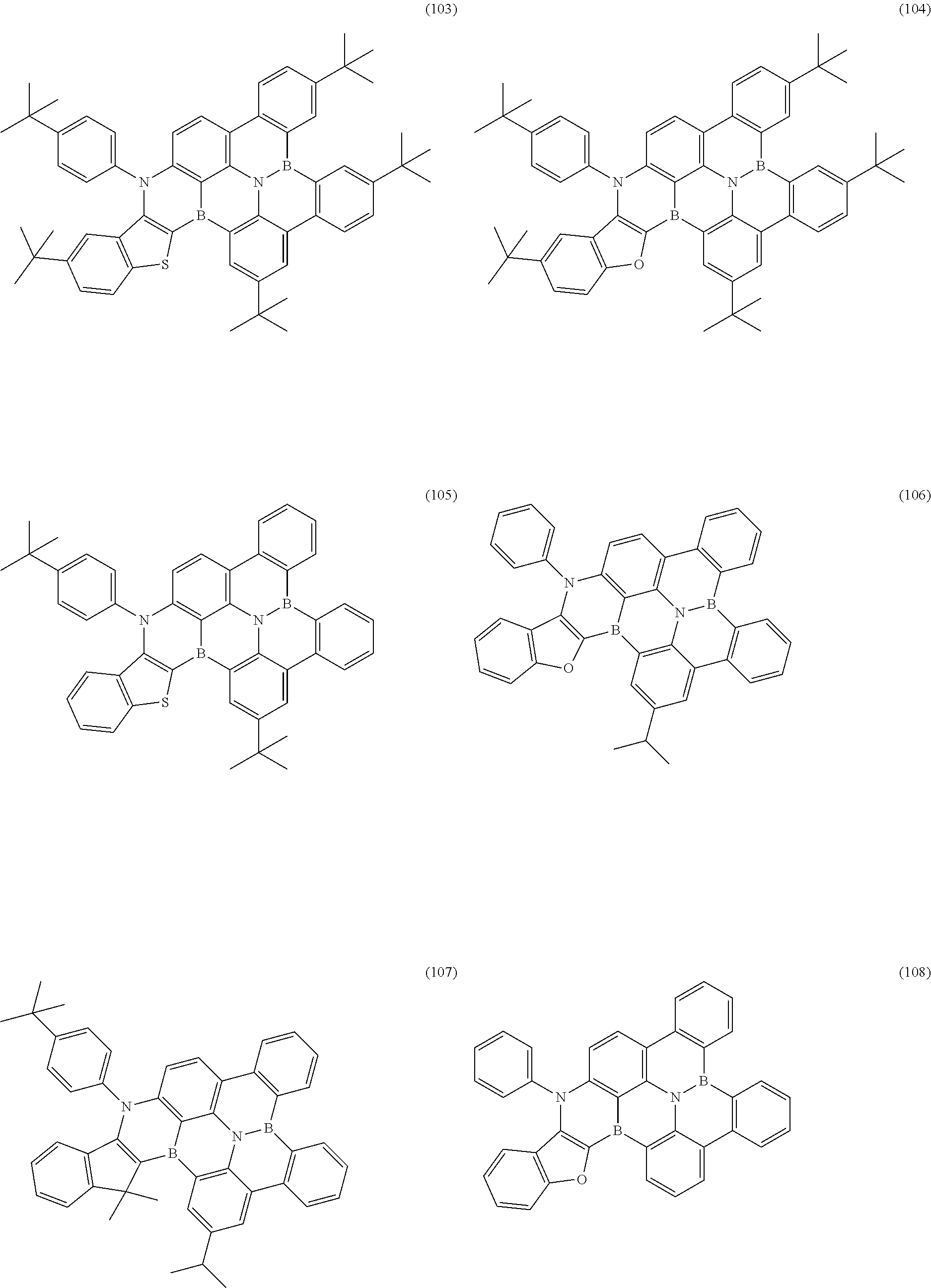

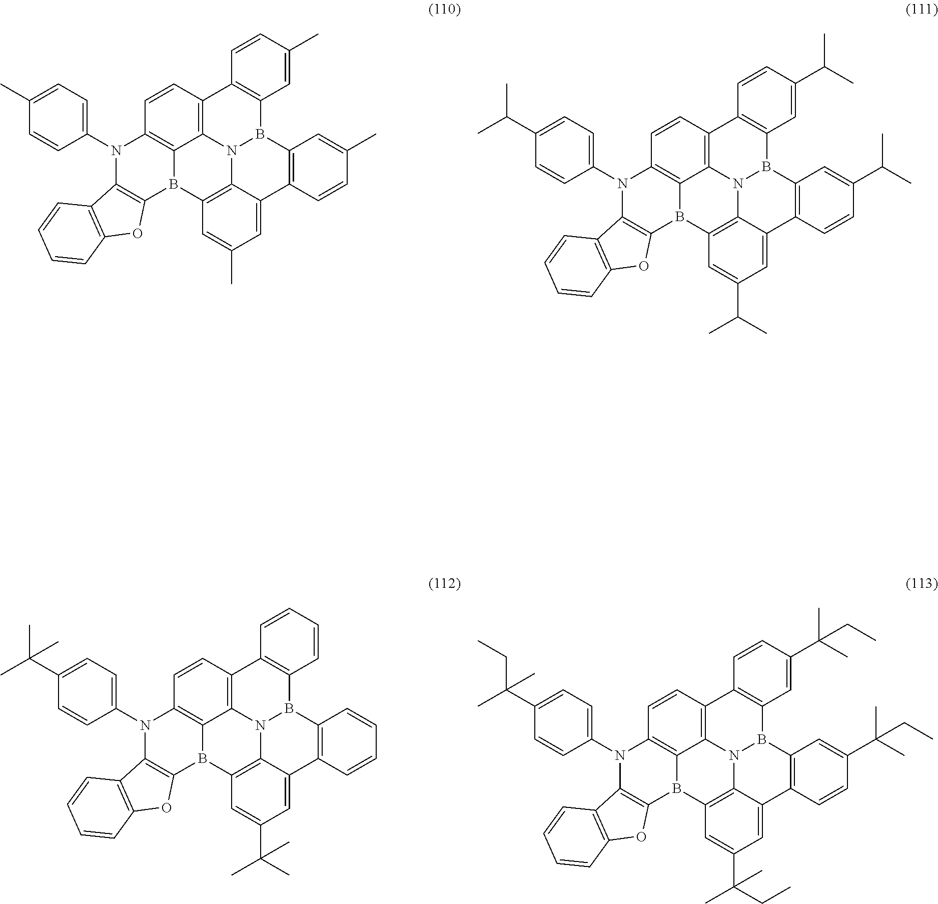

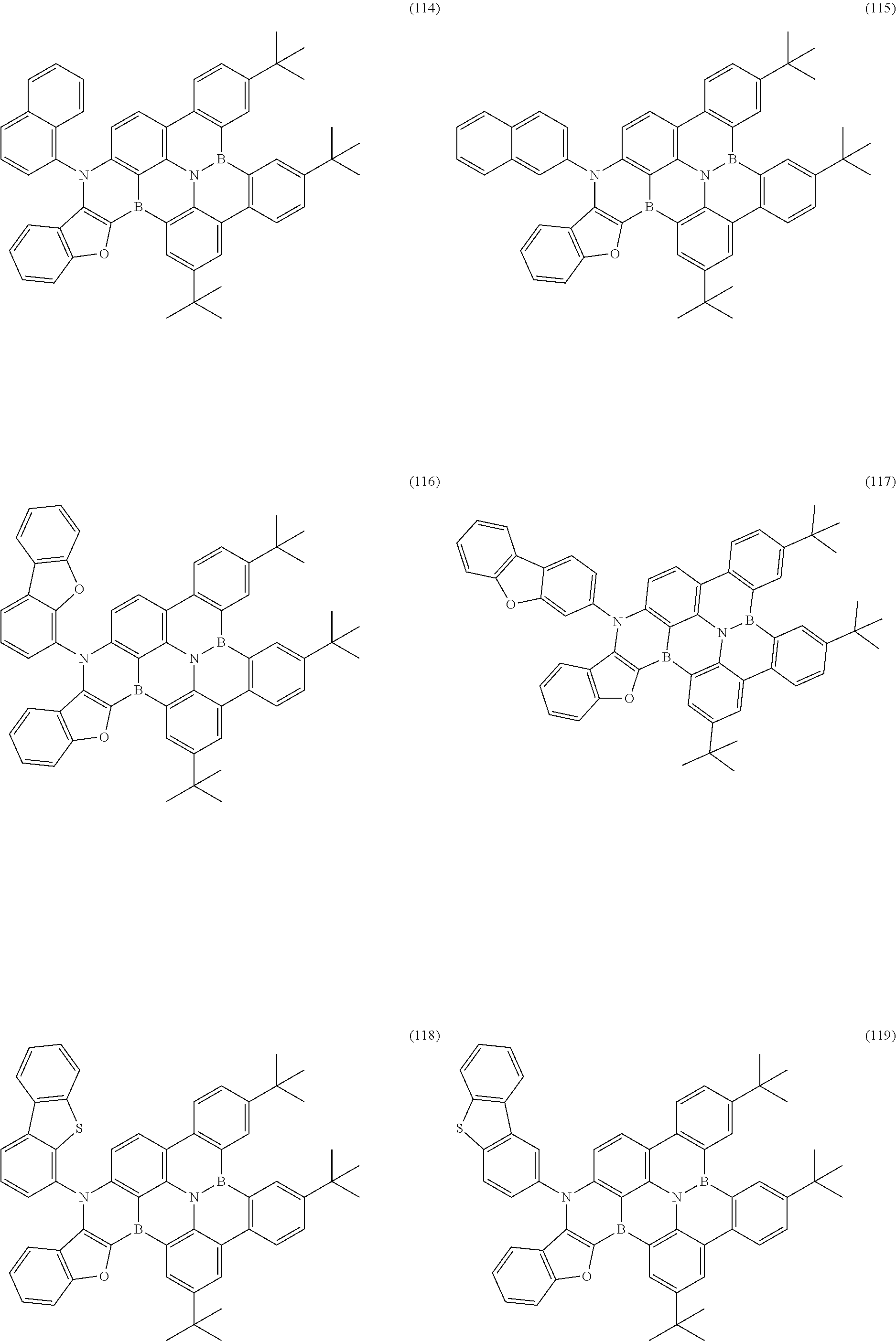

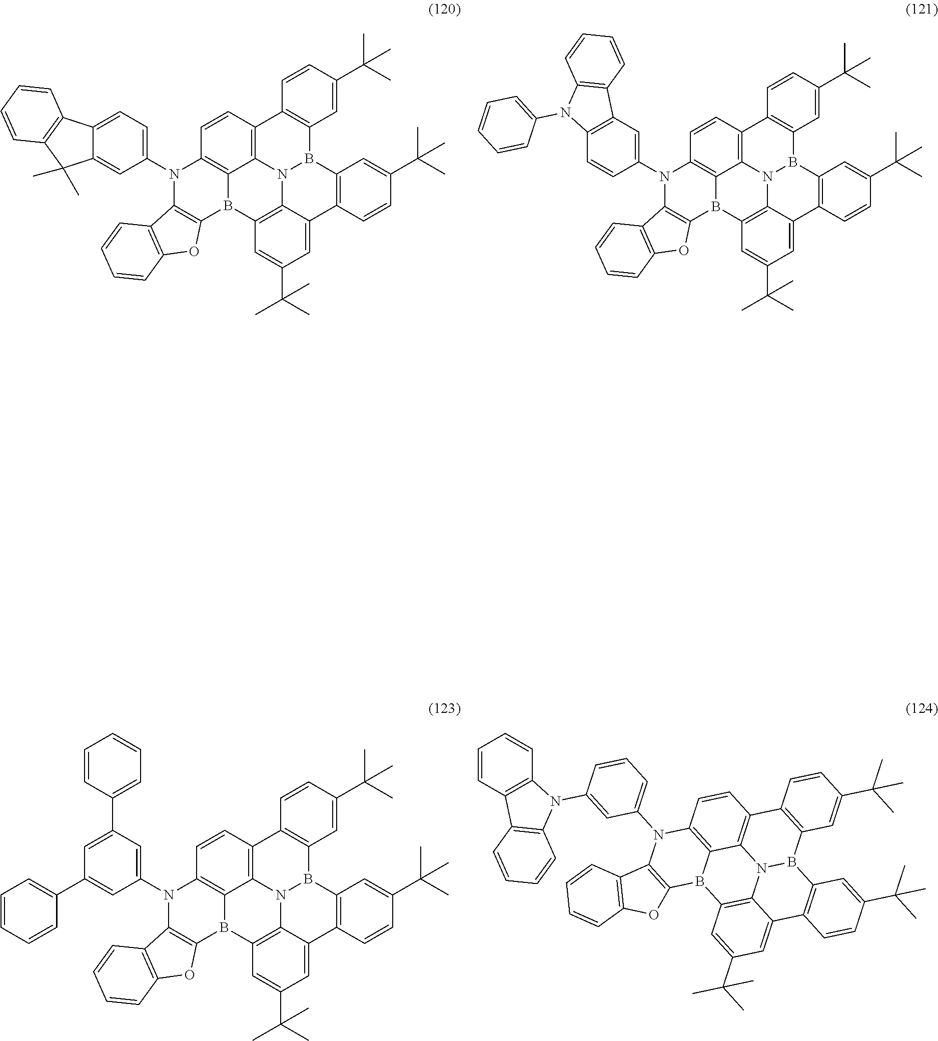

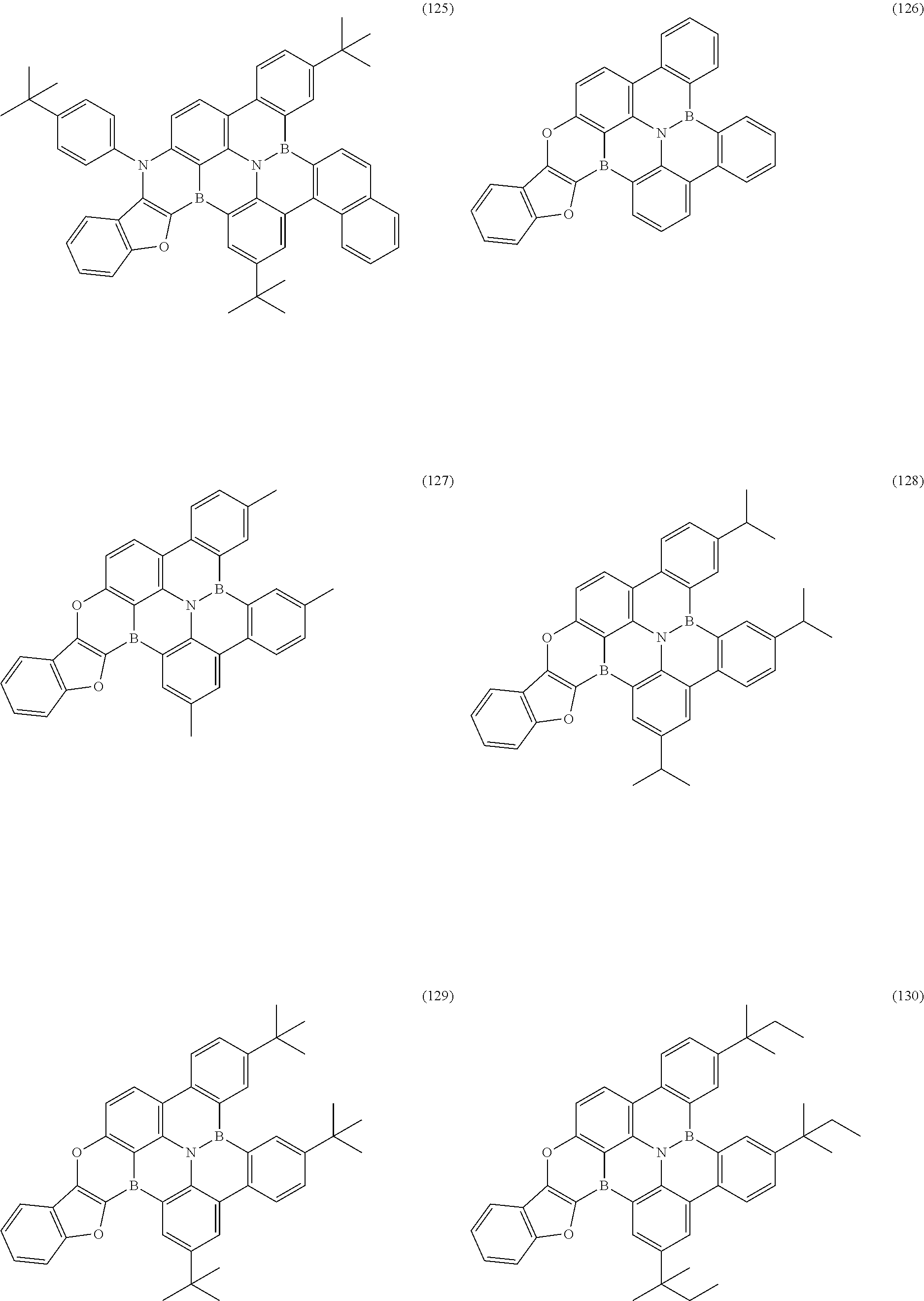

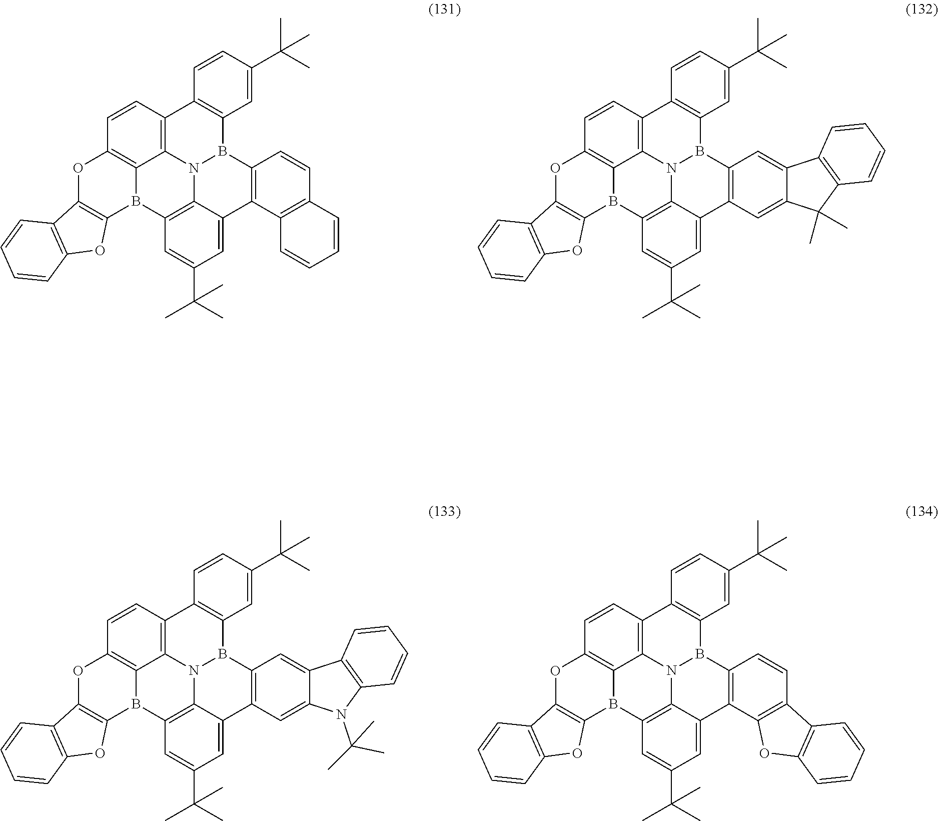 [SMILES: CC(C)(C)c1ccc2c(c1)B1c3ccc4ccccc4c3-c3cc(C(C)(C)C)cc4c3N1c1c-2ccc2c1B4c1oc3ccccc3c1O2 ; CC(C)(C)c1ccc2c(c1)B1c3cc4c(cc3-c3cc(C(C)(C)C)cc5c3N1c1c-2ccc2c1B5c1oc3ccccc3c1O2)C(C)(C)c1ccccc1-4 ; CC(C)(C)c1ccc2c(c1)B1c3cc4c5ccccc5n(C(C)(C)C)c4cc3-c3cc(C(C)(C)C)cc4c3N1c1c-2ccc2c1B4c1oc3ccccc3c1O2 ; CC(C)(C)c1ccc2c(c1)B1c3ccc4c(oc5ccccc54)c3-c3cc(C(C)(C)C)cc4c3N1c1c-2ccc2c1B4c1oc3ccccc3c1O2]

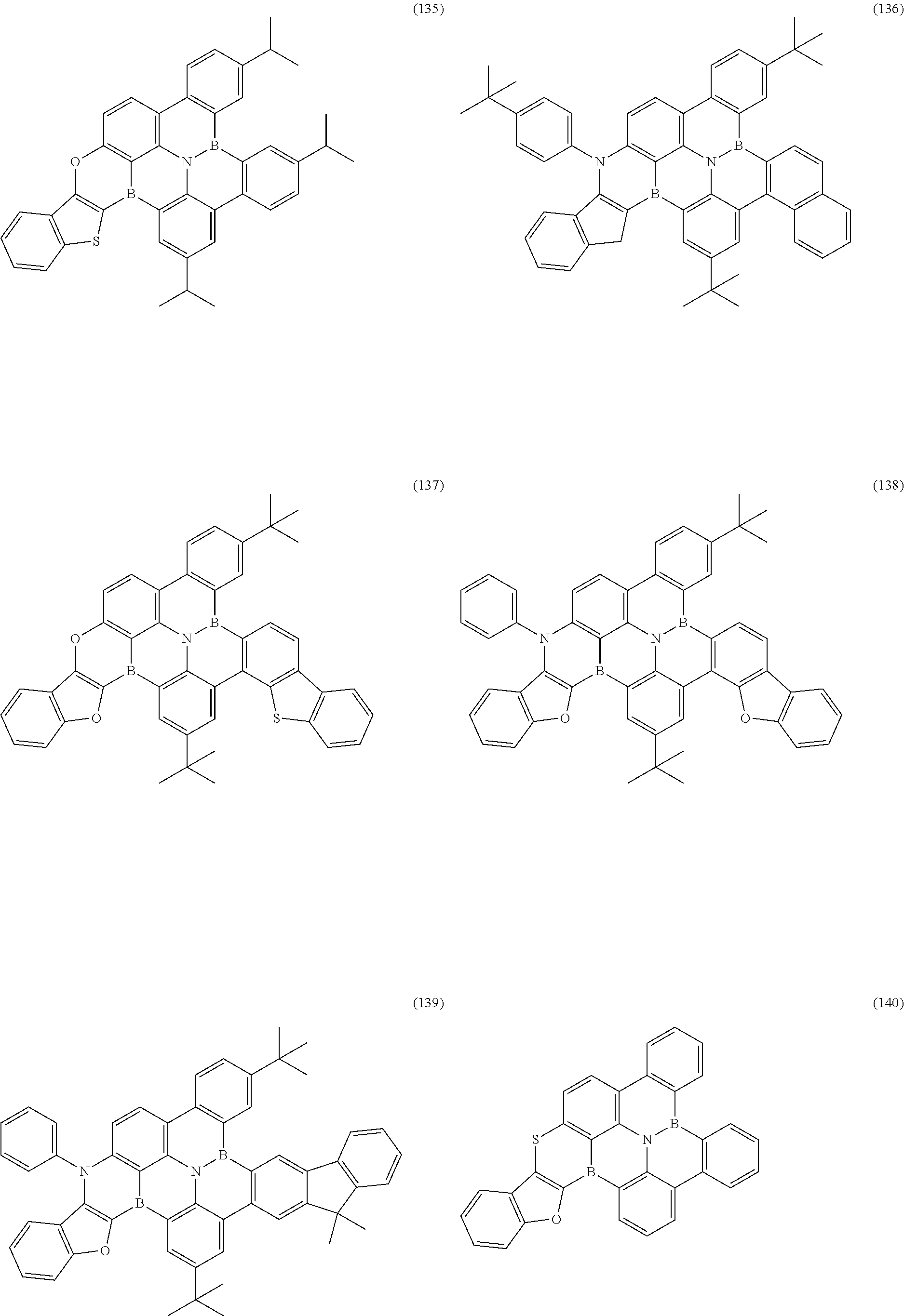

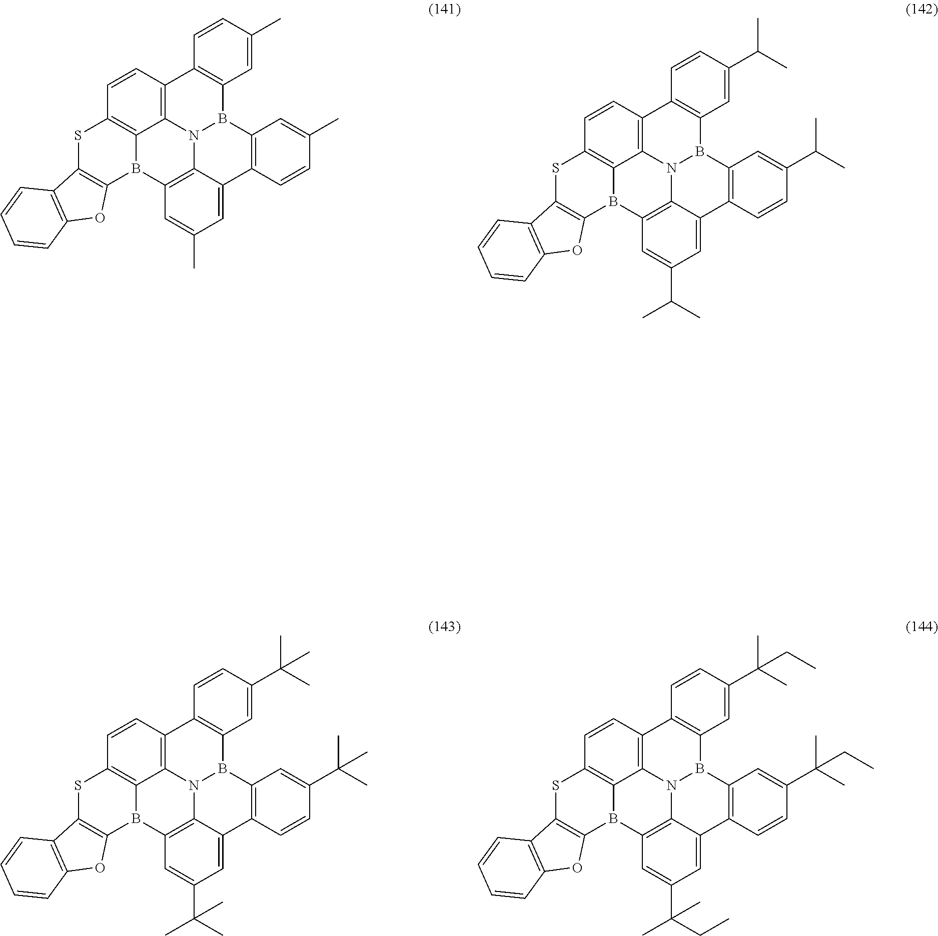 [SMILES: Cc1ccc2c(c1)B1c3cc(C)ccc3-c3ccc4c5c3N1c1c(cc(C)cc1-2)B5c1oc2ccccc2c1S4 ; CC(C)c1ccc2c(c1)B1c3cc(C(C)C)ccc3-c3ccc4c5c3N1c1c(cc(C(C)C)cc1-2)B5c1oc2ccccc2c1S4 ; CC(C)(C)c1ccc2c(c1)B1c3cc(C(C)(C)C)ccc3-c3ccc4c5c3N1c1c(cc(C(C)(C)C)cc1-2)B5c1oc2ccccc2c1S4 ; CCC(C)(C)c1ccc2c(c1)B1c3cc(C(C)(C)CC)ccc3-c3ccc4c5c3N1c1c(cc(C(C)(C)CC)cc1-2)B5c1oc2ccccc2c1S4]

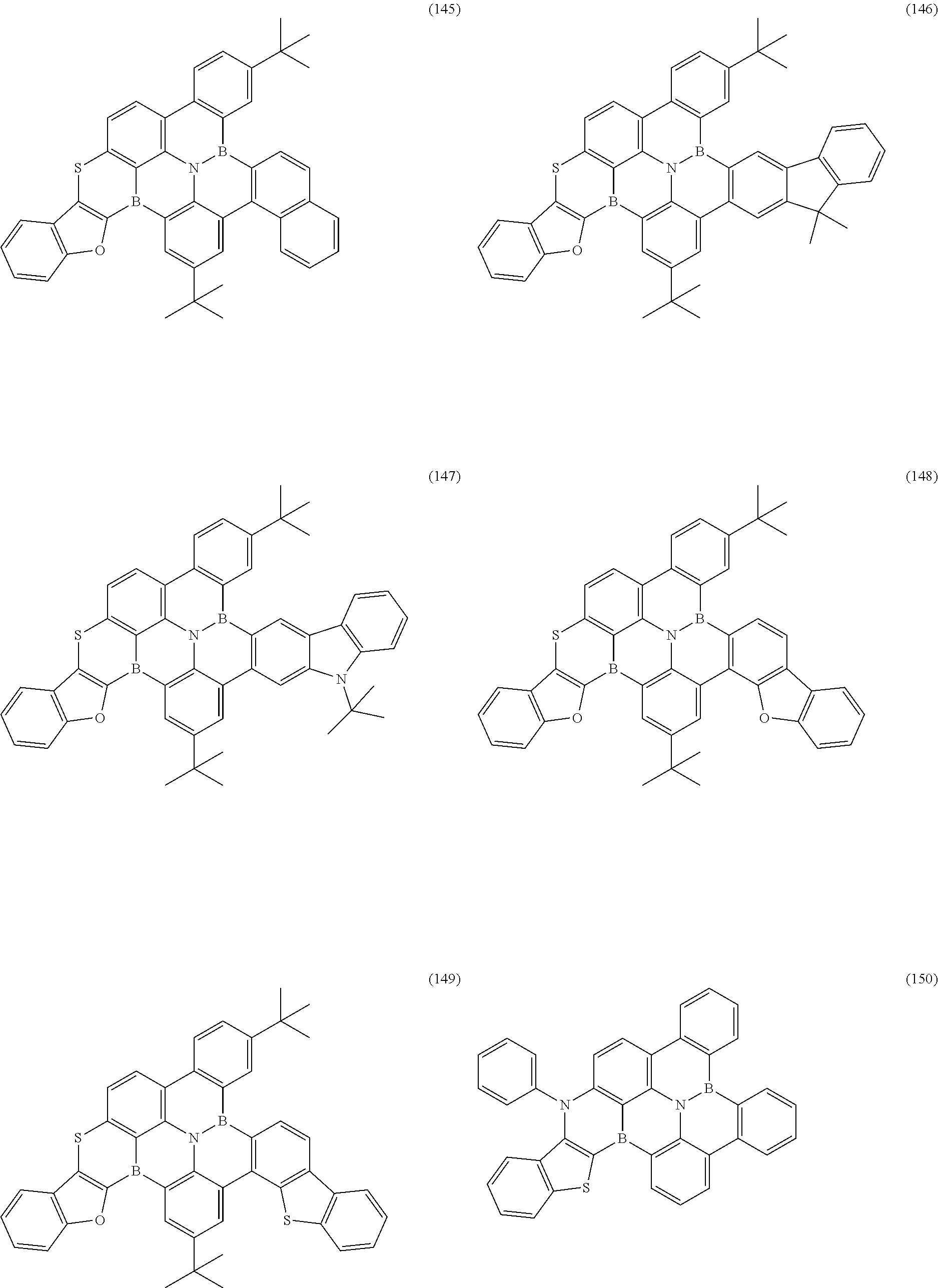

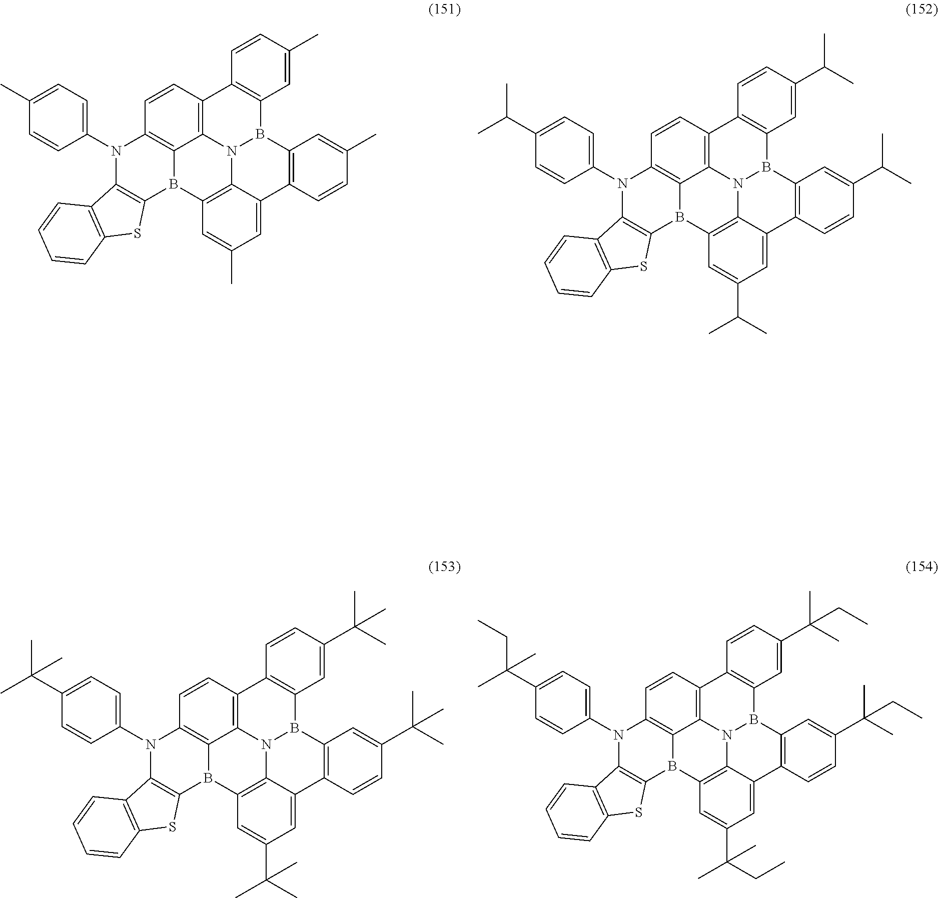

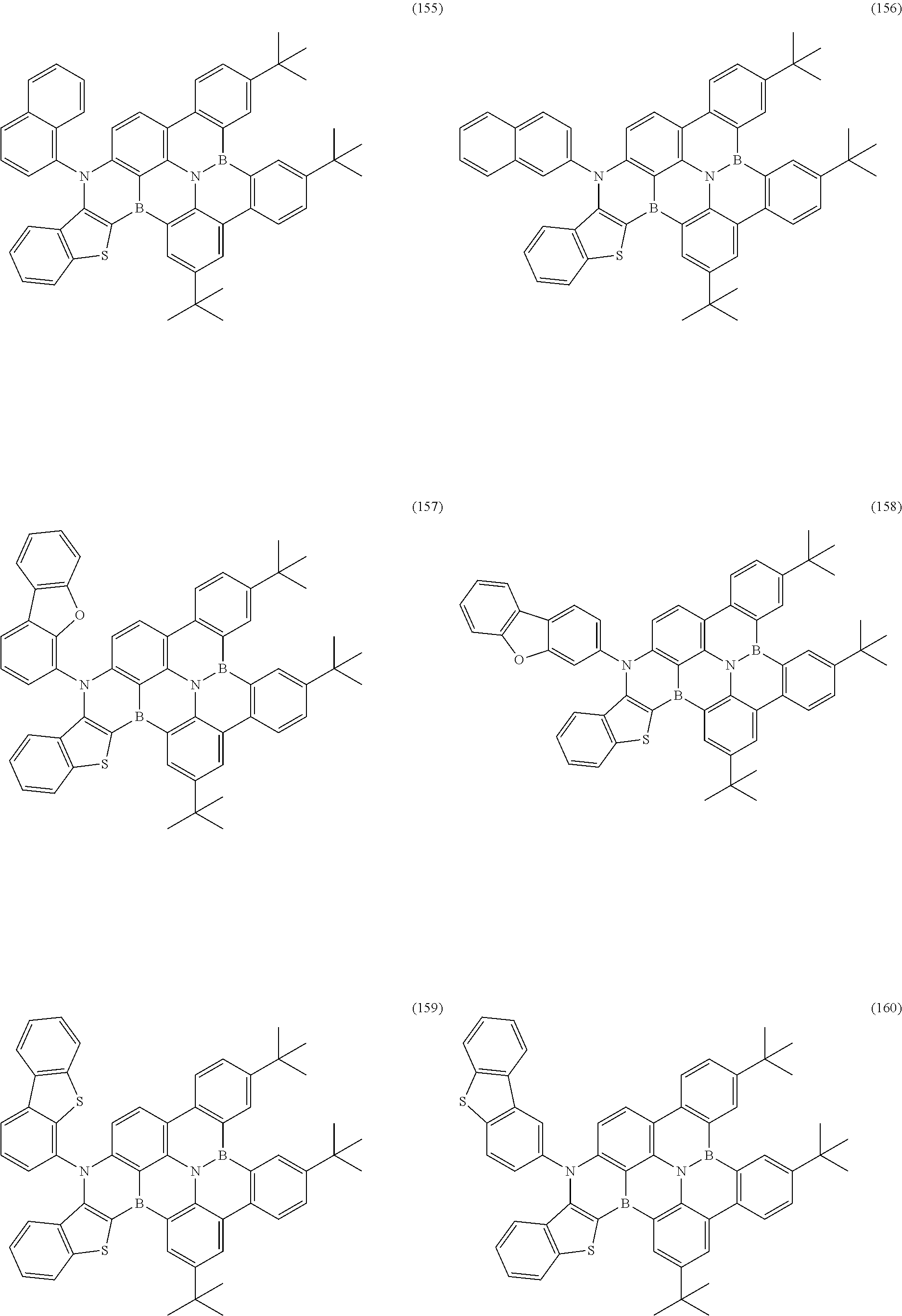

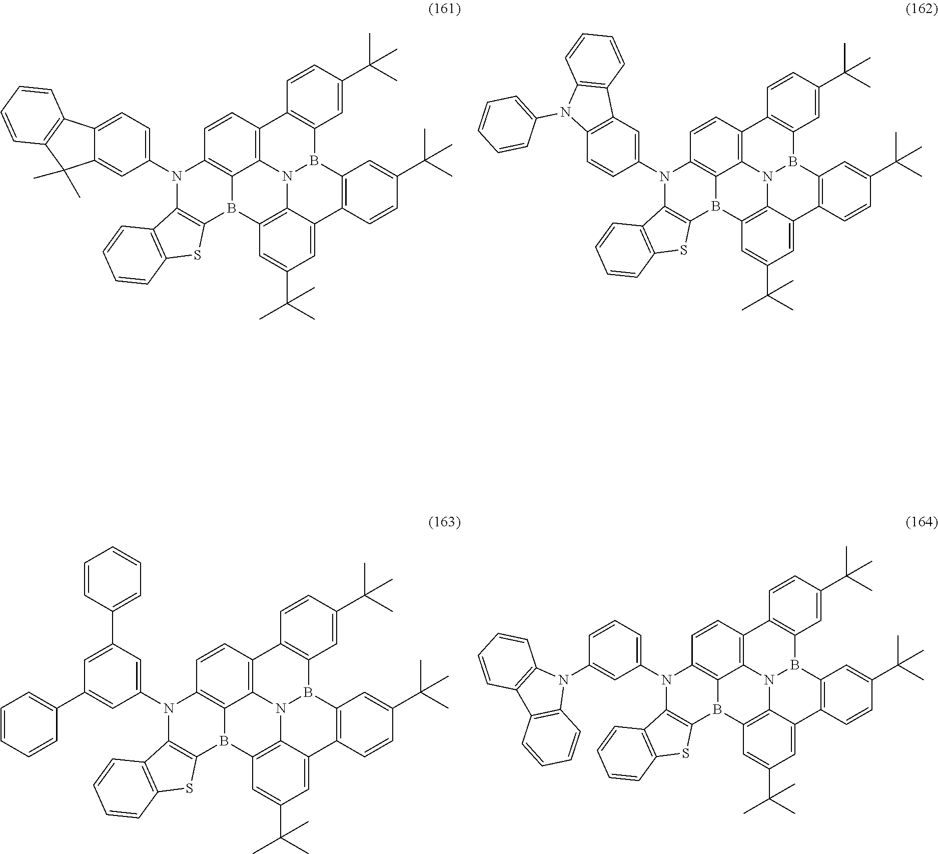

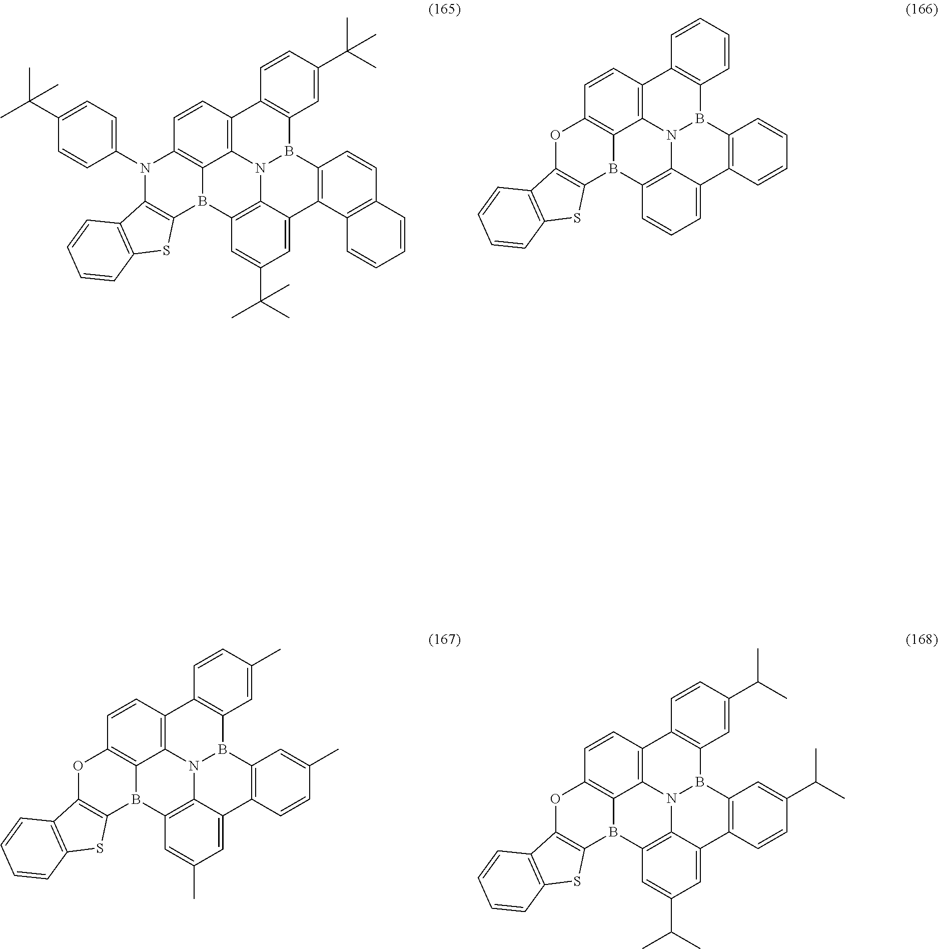 [SMILES: CC(C)(C)c1ccc(N2c3ccc4c5c3B(c3cc(C(C)(C)C)cc6c3N5B(c3cc(C(C)(C)C)ccc3-4)c3ccc4ccccc4c3-6)c3sc4ccccc4c32)cc1 ; c1ccc2c(c1)B1c3ccccc3-c3ccc4c5c3N1c1c(cccc1-2)B5c1sc2ccccc2c1O4 ; Cc1ccc2c(c1)B1c3cc(C)ccc3-c3ccc4c5c3N1c1c(cc(C)cc1-2)B5c1sc2ccccc2c1O4 ; CC(C)c1ccc2c(c1)B1c3cc(C(C)C)ccc3-c3ccc4c5c3N1c1c(cc(C(C)C)cc1-2)B5c1sc2ccccc2c1O4]

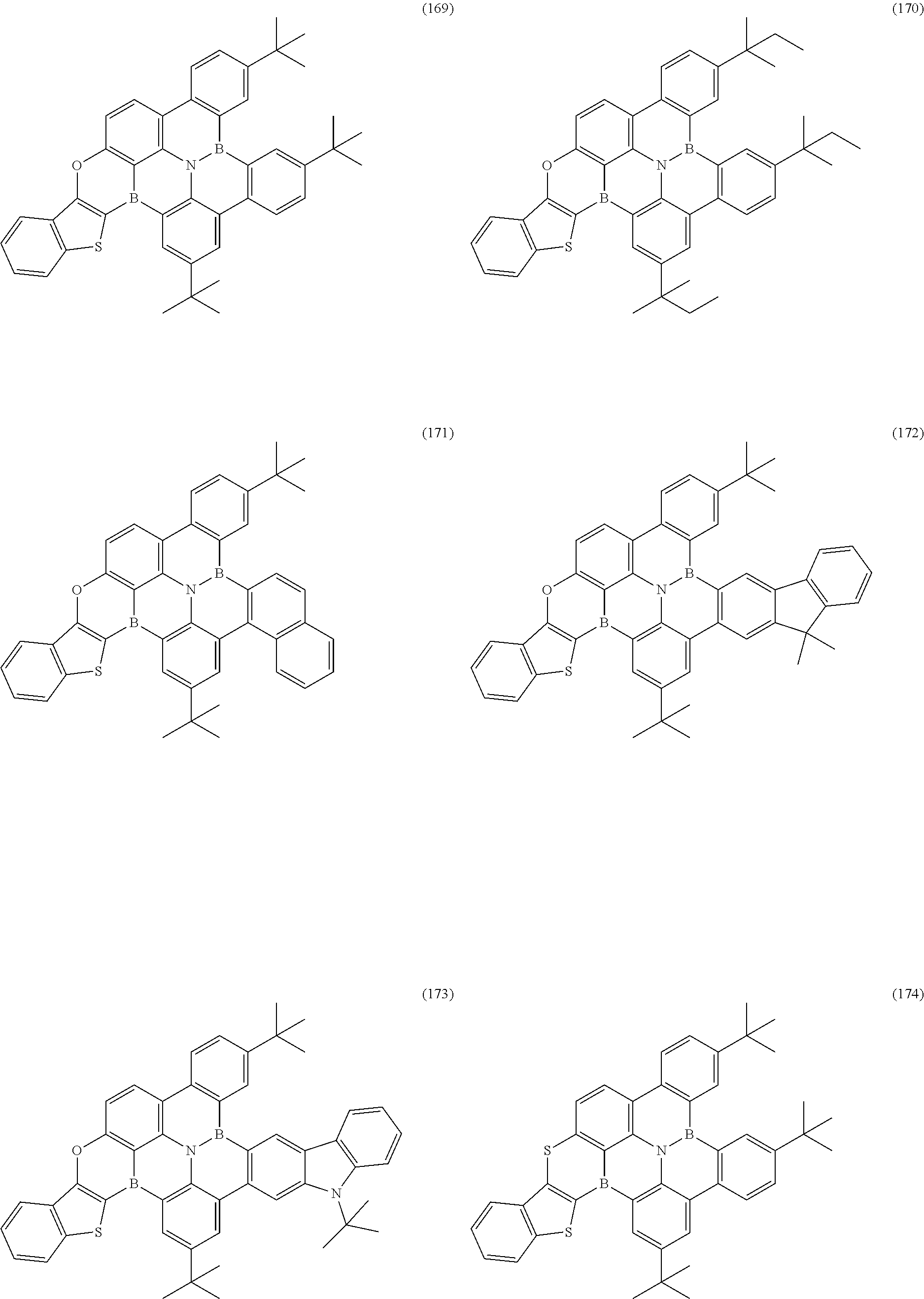

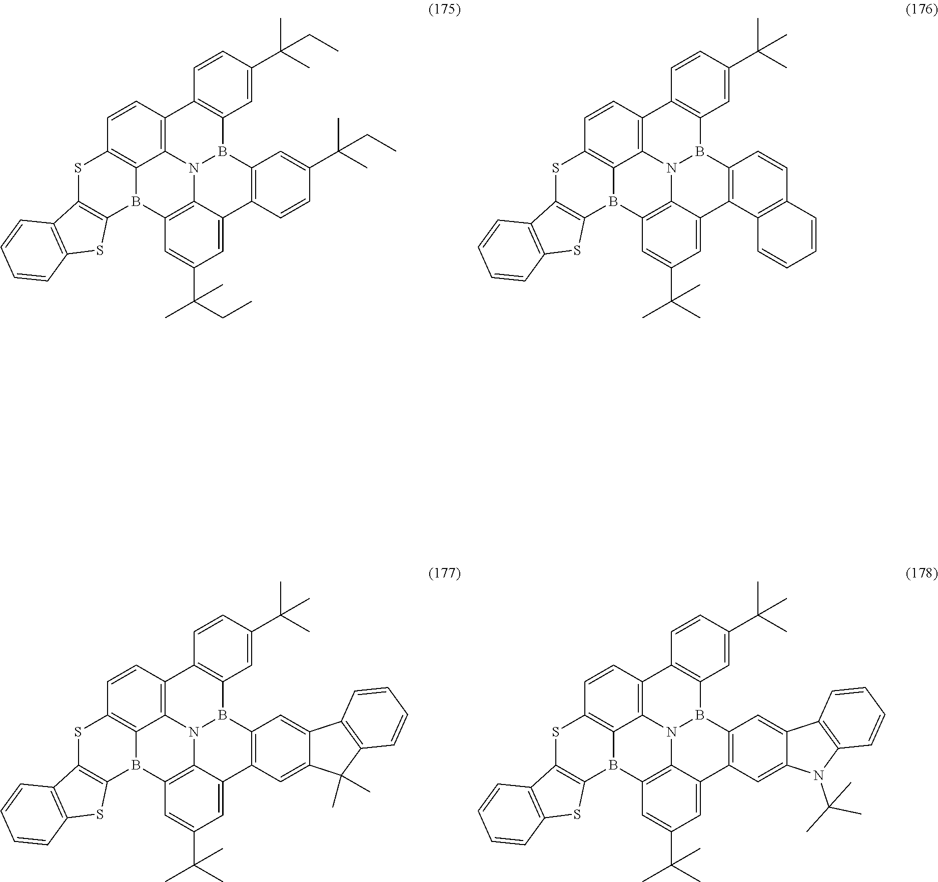 [SMILES: CCC(C)(C)c1ccc2c(c1)B1c3cc(C(C)(C)CC)ccc3-c3ccc4c5c3N1c1c(cc(C(C)(C)CC)cc1-2)B5c1sc2ccccc2c1S4 ; CC(C)(C)c1ccc2c(c1)B1c3ccc4ccccc4c3-c3cc(C(C)(C)C)cc4c3N1c1c-2ccc2c1B4c1sc3ccccc3c1S2 ; CC(C)(C)c1ccc2c(c1)B1c3cc4c(cc3-c3cc(C(C)(C)C)cc5c3N1c1c-2ccc2c1B5c1sc3ccccc3c1S2)C(C)(C)c1ccccc1-4 ; CC(C)(C)c1ccc2c(c1)B1c3cc4c5ccccc5n(C(C)(C)C)c4cc3-c3cc(C(C)(C)C)cc4c3N1c1c-2ccc2c1B4c1sc3ccccc3c1S2]

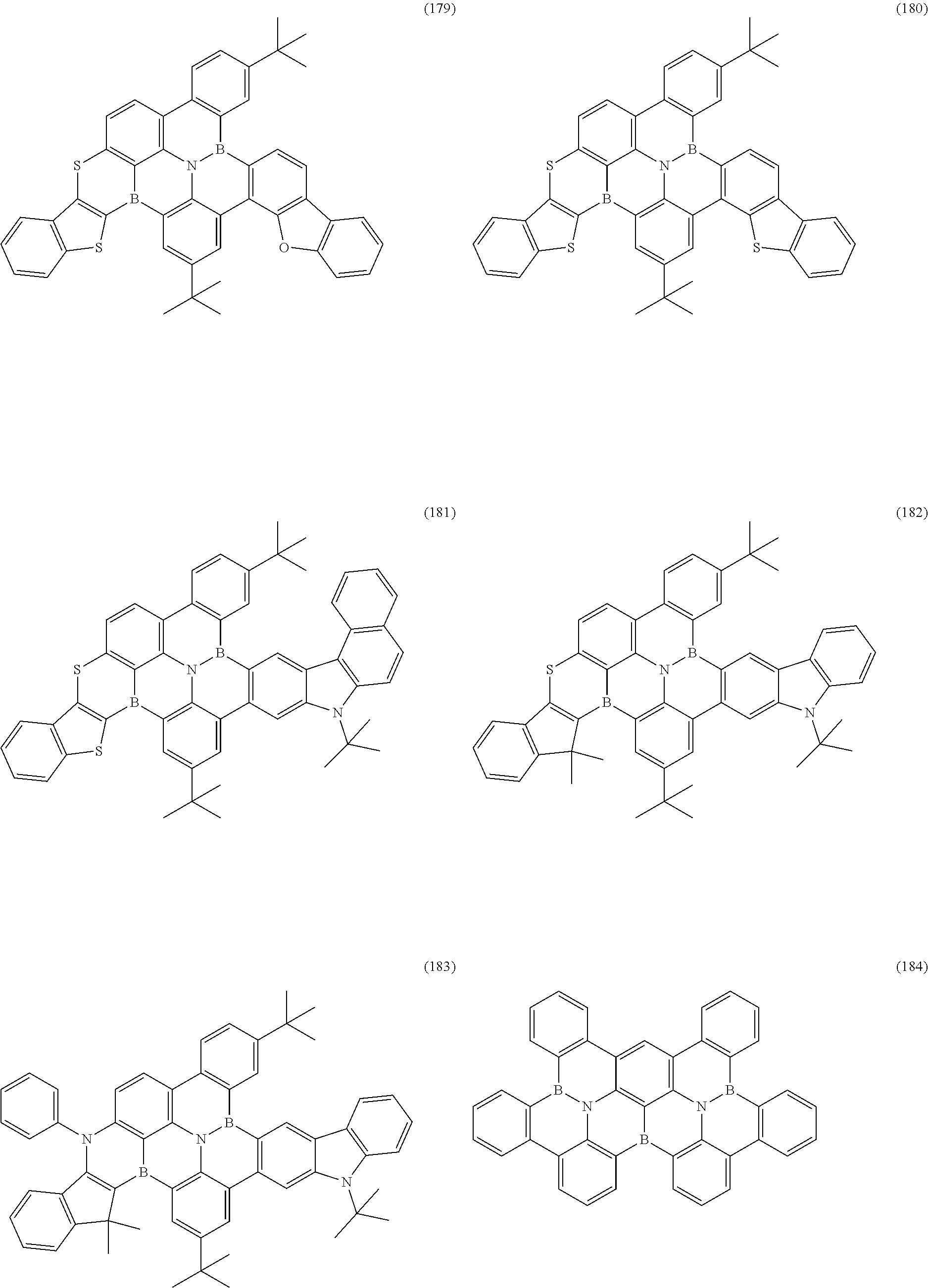

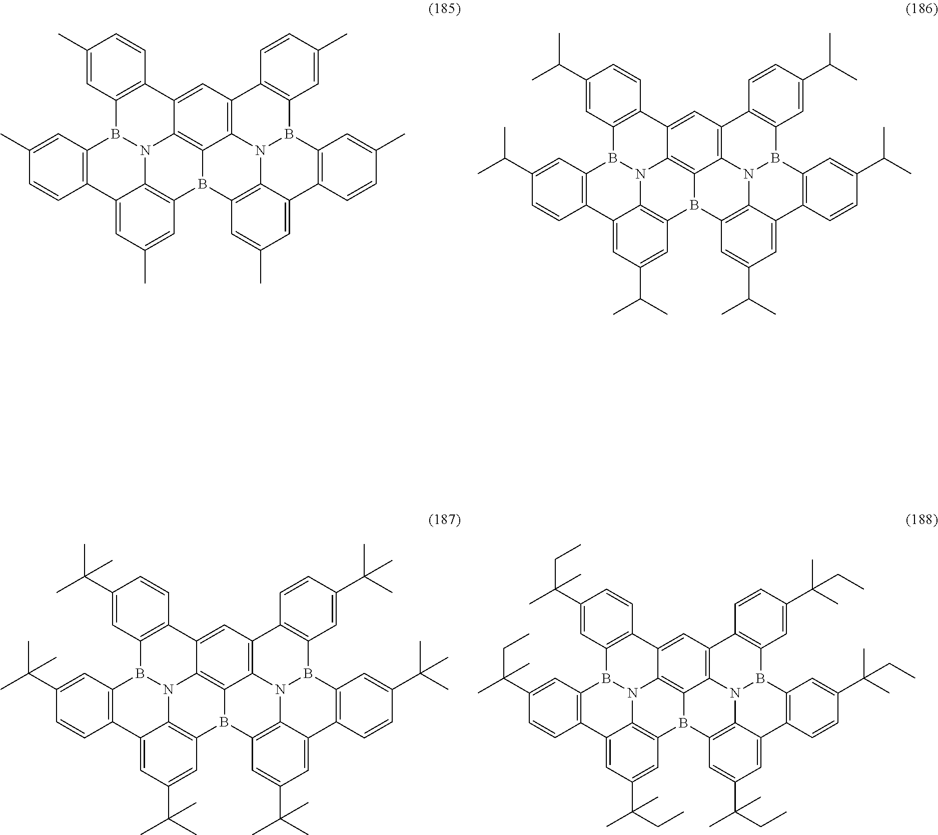

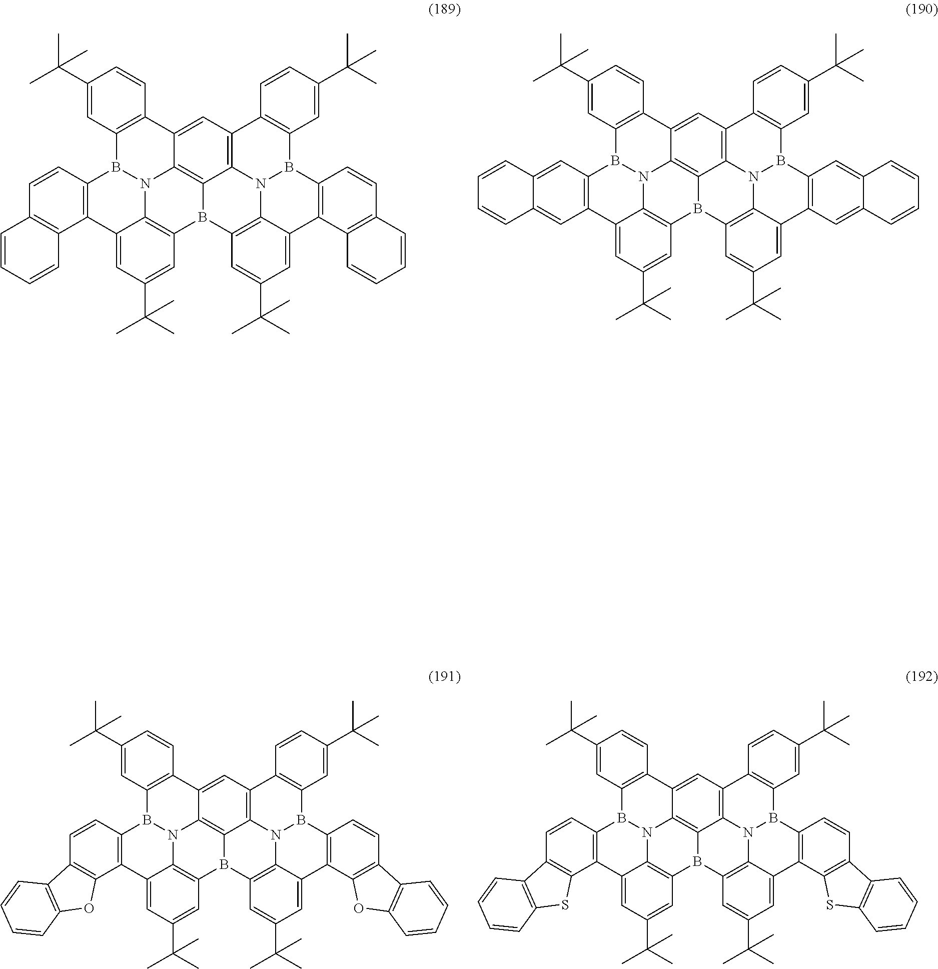

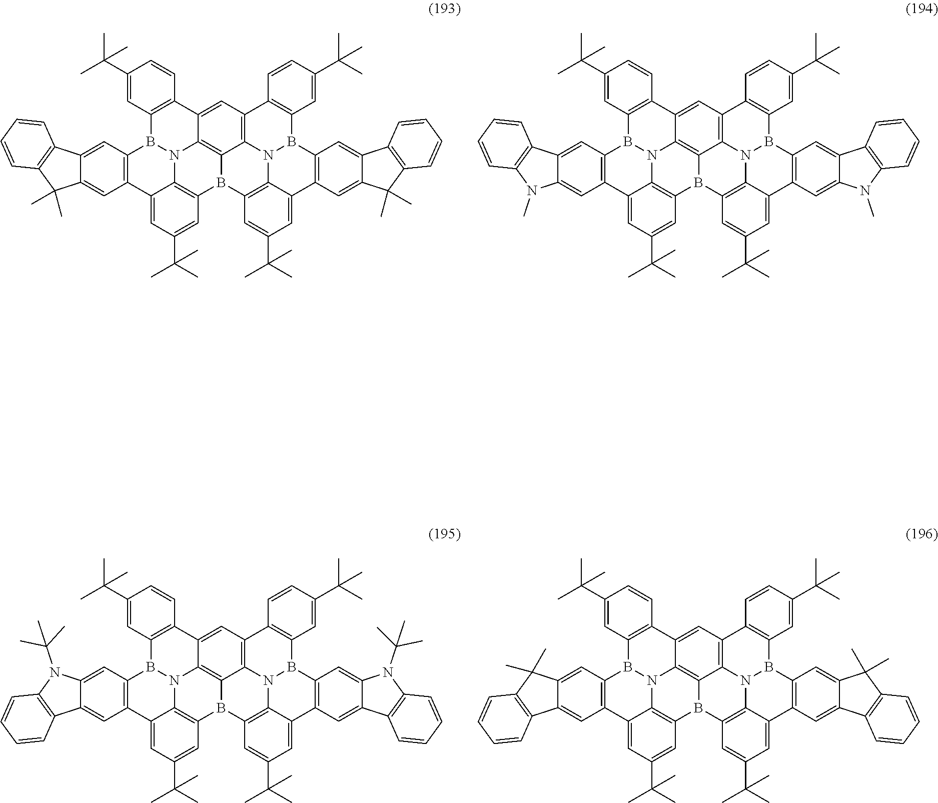

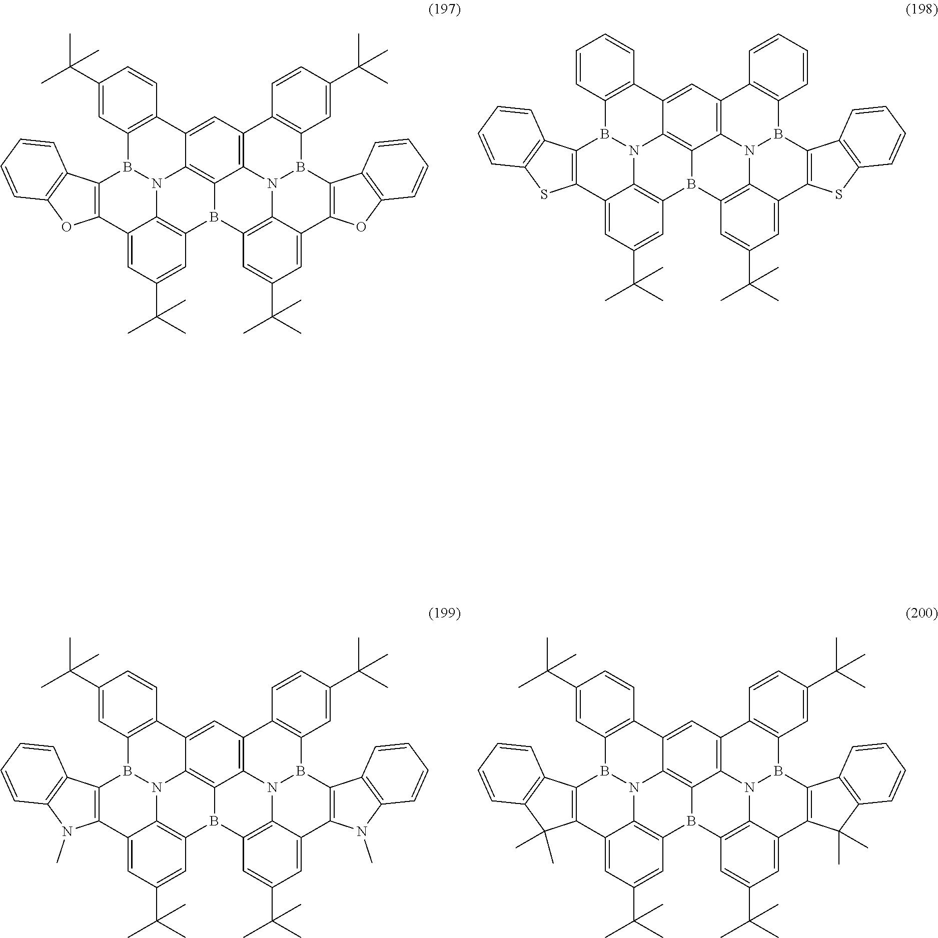

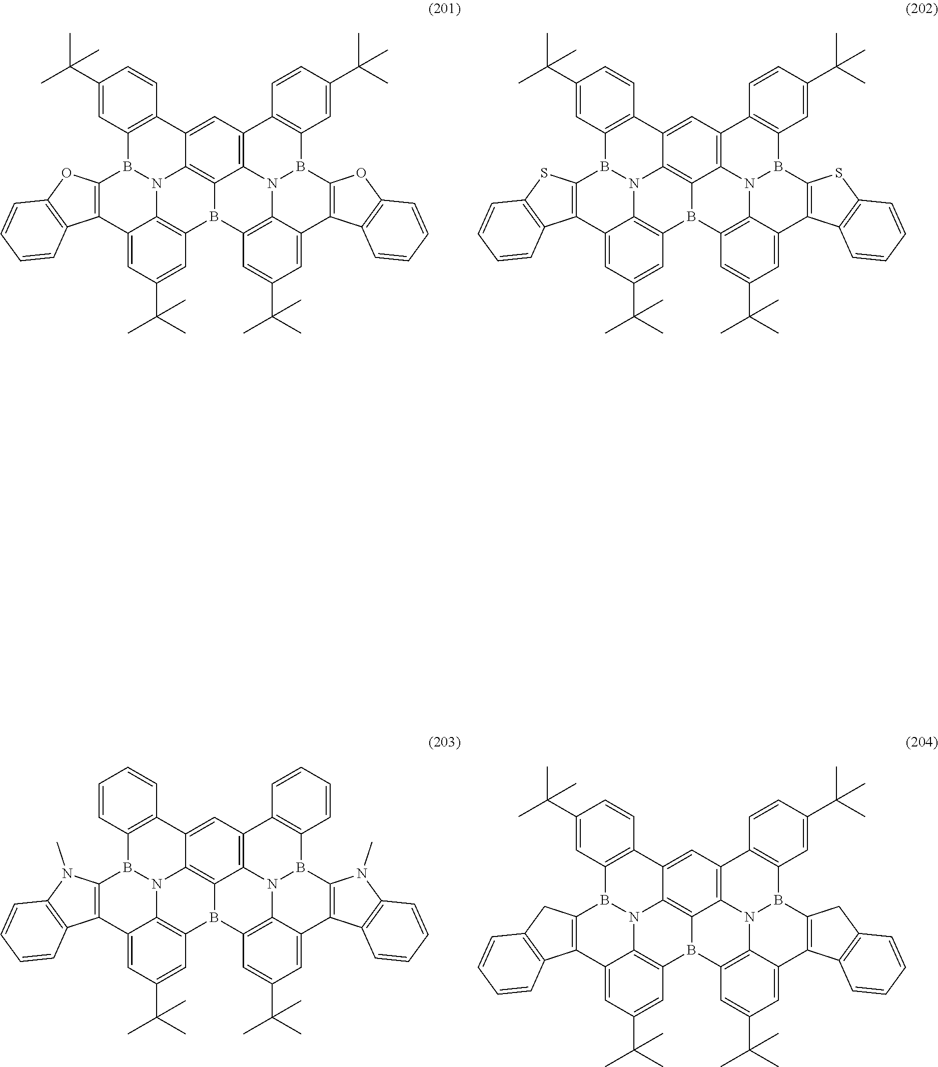

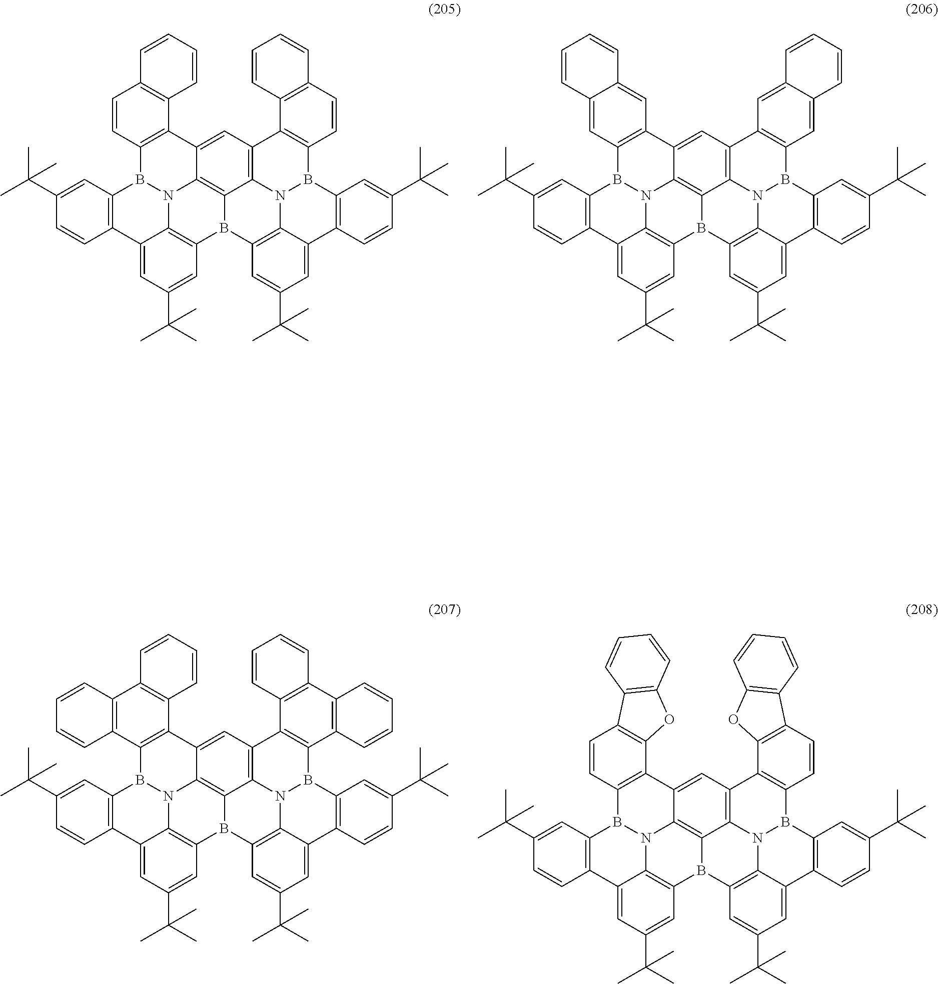

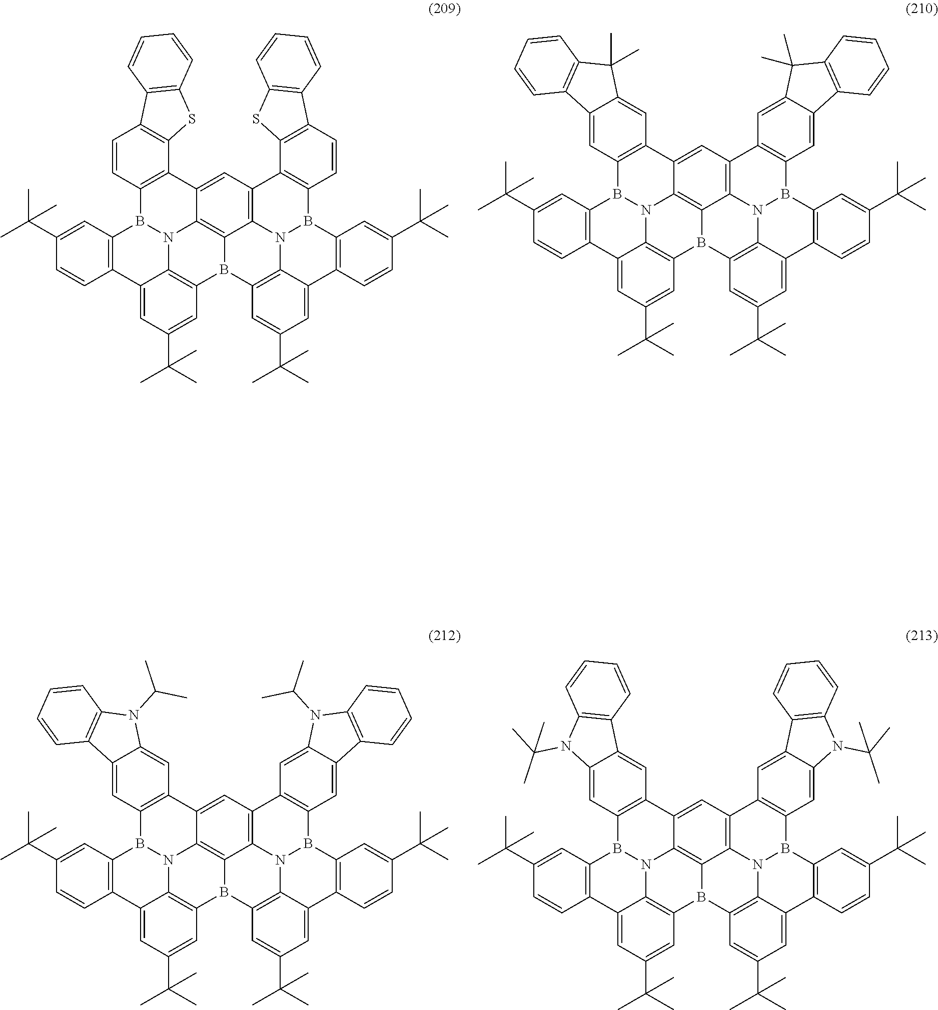

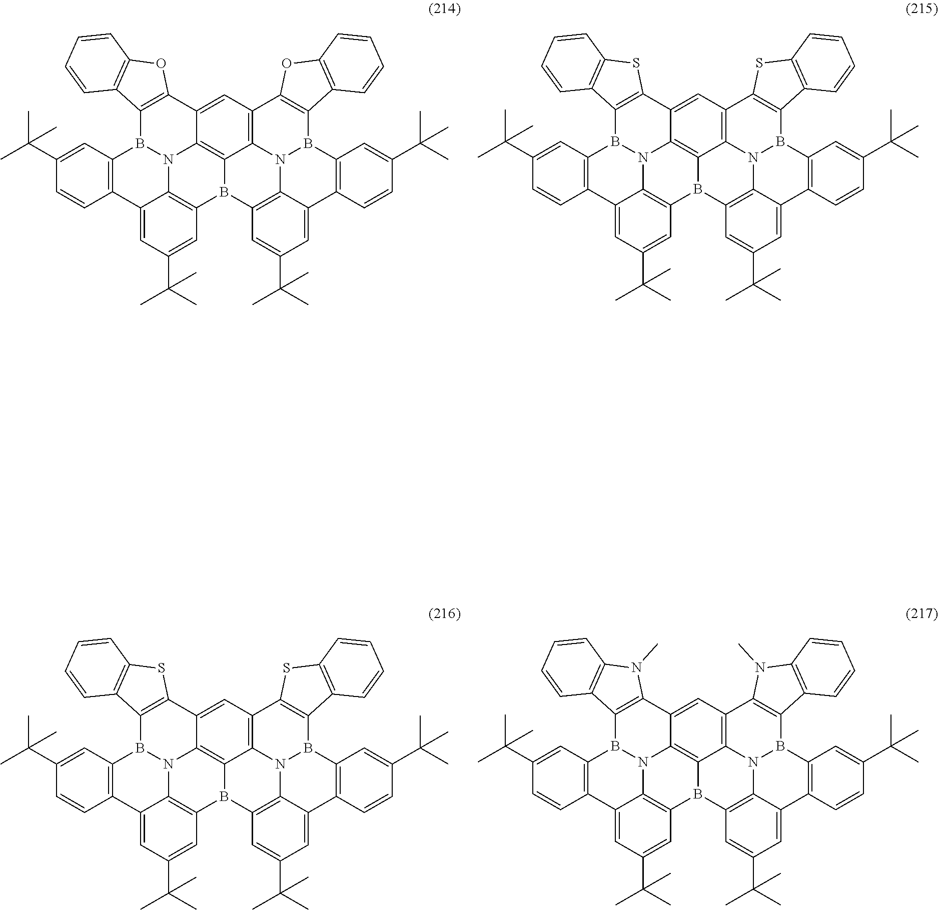

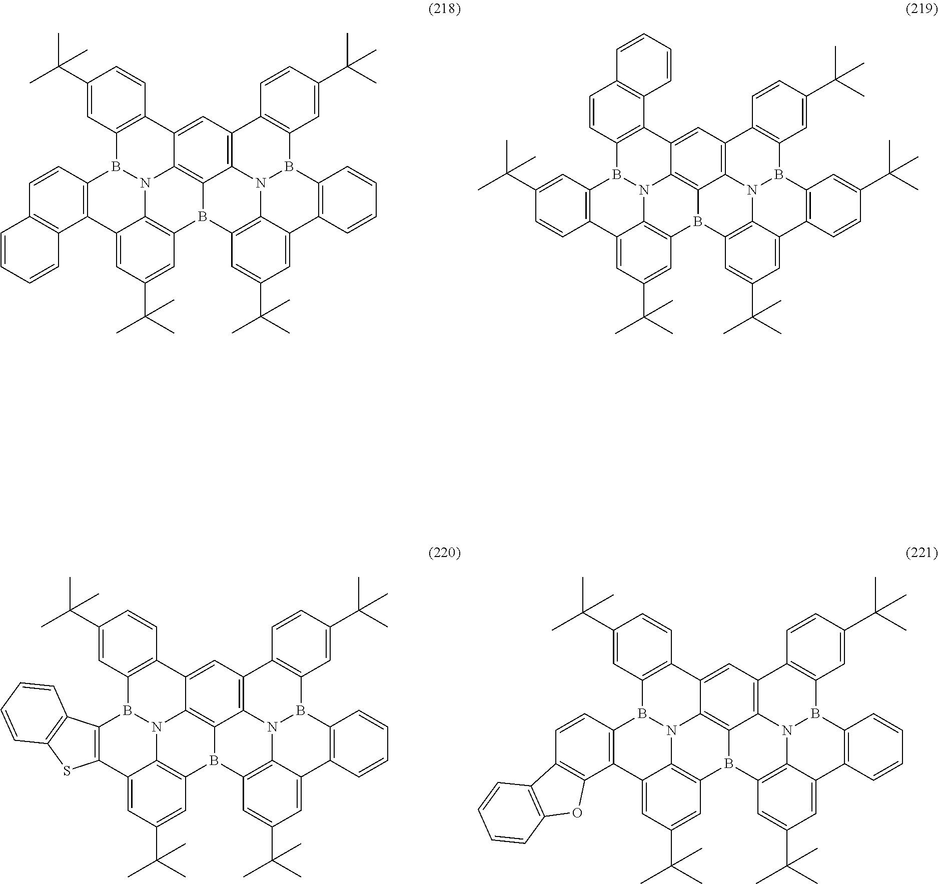

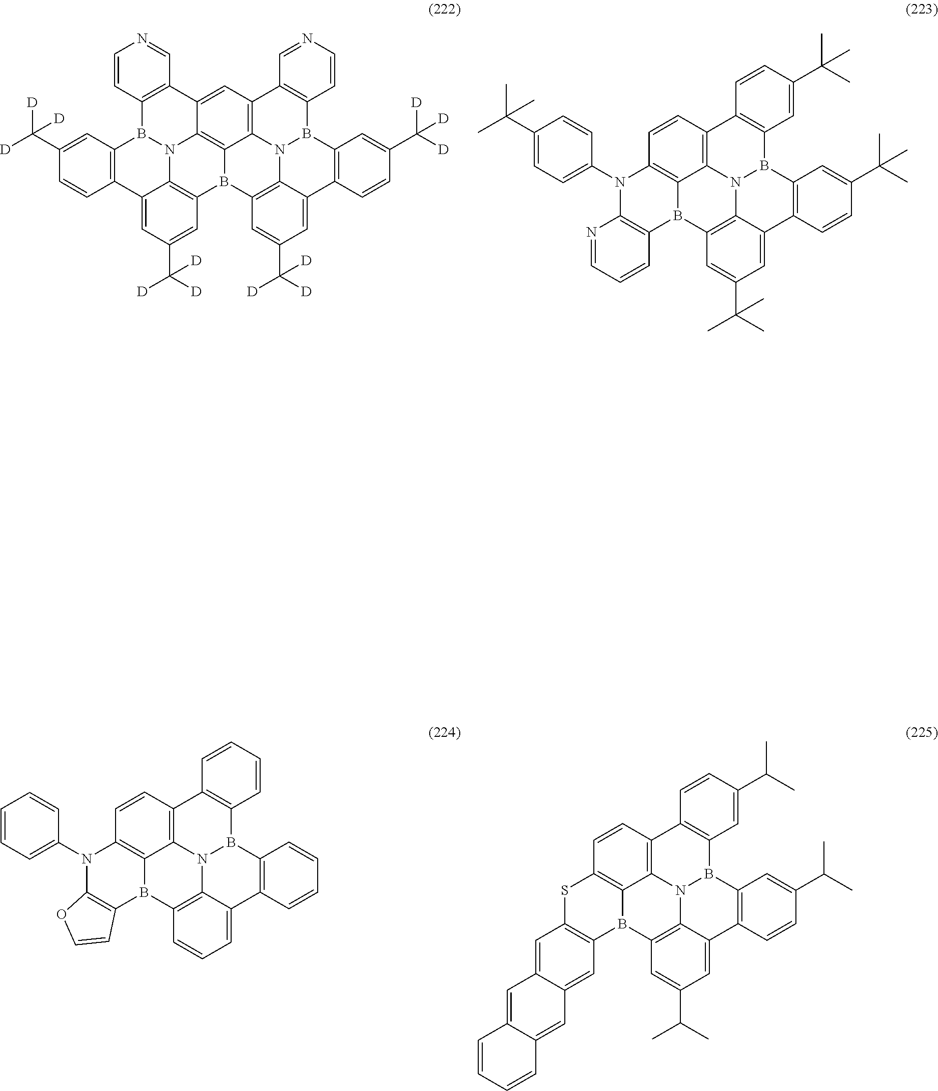

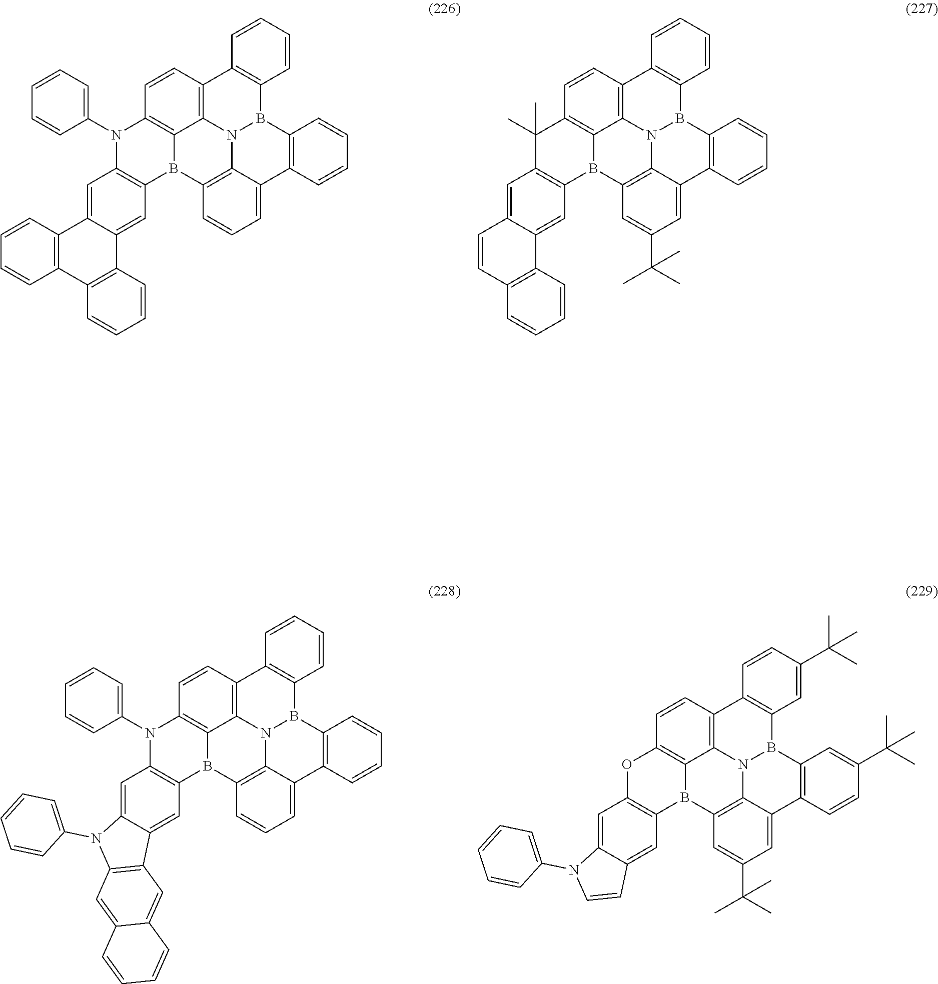 [SMILES: c1ccc(N2c3cc4c5ccccc5c5ccccc5c4cc3B3c4cccc5c4N4B(c6ccccc6-5)c5ccccc5-c5ccc2c3c54)cc1 ; CC(C)(C)c1cc2c3c(c1)-c1ccccc1B1c4ccccc4-c4ccc5c(c4N13)B2c1cc2c(ccc3ccccc32)cc1C5(C)C ; c1ccc(N2c3cc4c(cc3B3c5cccc6c5N5B(c7ccccc7-6)c6ccccc6-c6ccc2c3c65)c2cc3ccccc3cc2n4-c2ccccc2)cc1 ; CC(C)(C)c1ccc2c(c1)B1c3cc(C(C)(C)C)ccc3-c3ccc4c5c3N1c1c(cc(C(C)(C)C)cc1-2)B5c1cc2ccn(-c3ccccc3)c2cc1O4]

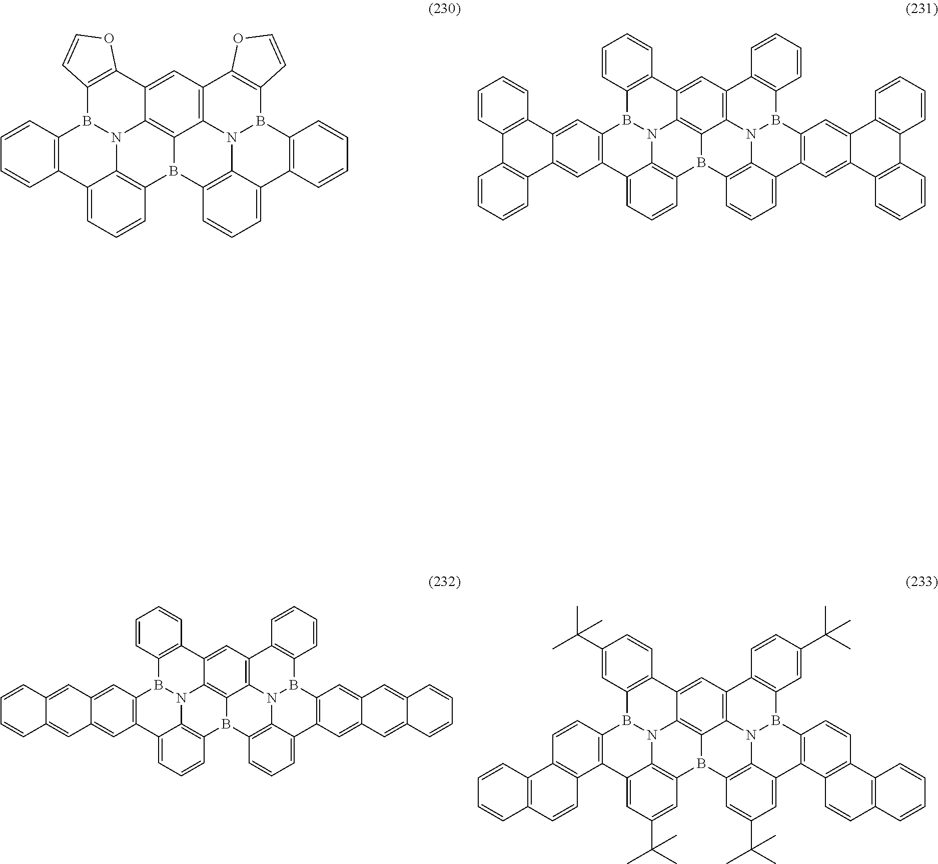 [SMILES: c1ccc2c(c1)B1c3ccoc3-c3cc4c5c6c3N1c1c(cccc1-2)B6c1cccc2c1N5B(c1ccccc1-2)c1ccoc1-4 ; c1ccc2c(c1)B1c3cc4c5ccccc5c5ccccc5c4cc3-c3cccc4c3N1c1c-2cc2c3c1B4c1cccc4c1N3B(c1cc3c5ccccc5c5ccccc5c3cc1-4)c1ccccc1-2 ; c1ccc2c(c1)B1c3cc4cc5ccccc5cc4cc3-c3cccc4c3N1c1c-2cc2c3c1B4c1cccc4c1N3B(c1cc3cc5ccccc5cc3cc1-4)c1ccccc1-2 ; CC(C)(C)c1ccc2c(c1)B1c3ccc4c(ccc5ccccc54)c3-c3cc(C(C)(C)C)cc4c3N1c1c-2cc2c3c1B4c1cc(C(C)(C)C)cc4c1N3B(c1cc(C(C)(C)C)ccc1-2)c1ccc2c(ccc3ccccc32)c1-4]

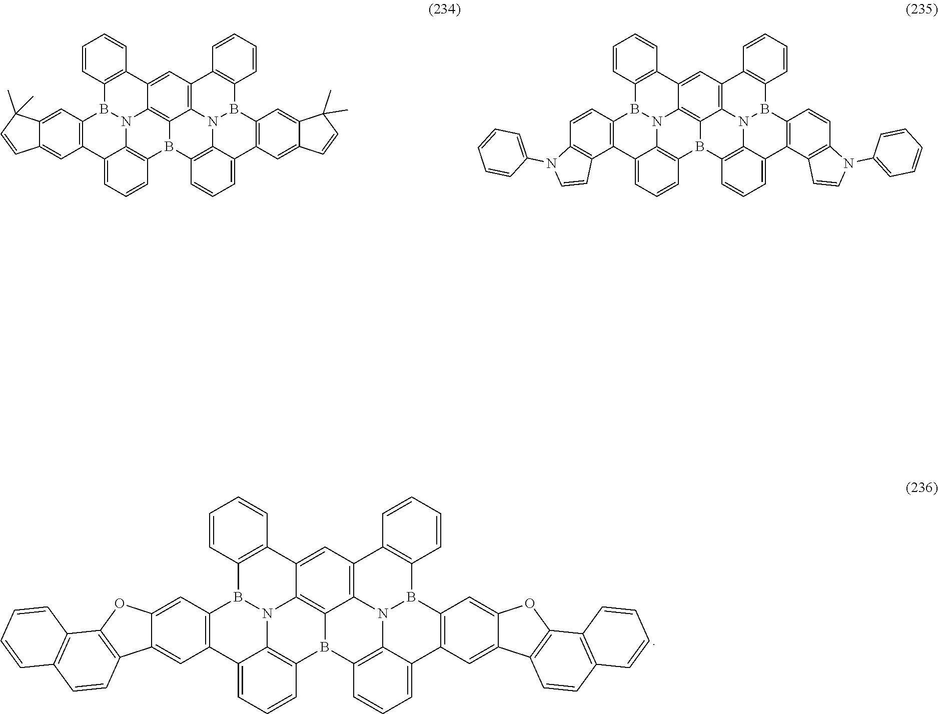 [SMILES: CC1(C)C=Cc2cc3c(cc21)B1c2ccccc2-c2cc4c5c6c2N1c1c(cccc1-3)B6c1cccc2c1N5B(c1cc3c(cc1-2)C=CC3(C)C)c1ccccc1-4 ; c1ccc(-n2ccc3c4c(ccc32)B2c3ccccc3-c3cc5c6c7c3N2c2c(cccc2-4)B7c2cccc3c2N6B(c2ccccc2-5)c2ccc4c(ccn4-c4ccccc4)c2-3)cc1 ; c1ccc2c(c1)B1c3cc4oc5c6ccccc6ccc5c4cc3-c3cccc4c3N1c1c-2cc2c3c1B4c1cccc4c1N3B(c1cc3oc5c6ccccc6ccc5c3cc1-4)c1ccccc1-2]

In one embodiment, the organic boron-nitrogen compound of the disclosure is partially deuterated. Preferably, 10% to 50% of H atoms are deuterated; more preferably, 20% to 50% of H atoms are deuterated; further preferably, 30% to 50% of H atoms are deuterated; most preferably, 40% to 50% of H atoms are deuterated.

The organic boron-nitrogen compound of the disclosure can be used as a functional material to prepare organic electronic devices, especially OLED devices. Further, when the organic boron-nitrogen compound of the disclosure is used in organic electronic devices, it can be used to prepare light-emitting layers. Preferably, the organic boron-nitrogen compound is used as a guest material to prepare light-emitting layers.

One embodiment of the disclosure further provides a mixture that includes at least one organic boron-nitrogen compound as described above, and at least another organic functional material. The organic functional material is selected from a hole injection material, a hole transport material, an electron transport material, an electron injection material, an electron blocking material, a hole blocking material, a light-emitting material, a host material, or an organic dye.

In some embodiments, the above-mentioned organic functional material may be selected from a group consisting of a hole injection material (HIM), a hole transport material (HTM), an electron transport material (ETM), an electron injection material (EIM), an electron blocking material (EBM), a hole blocking material (HBM), a light-emitting material (emitter), a host material, and an organic dye. Detailed descriptions of these organic functional materials can refer to WO 2010135519 A1, US 20090134784 A1, and WO 2011110277 A1, all contents of these three patent applications are incorporated herein by reference in their entirety.

One embodiment of the disclosure further provides a composition that includes at least one organic boron-nitrogen compound or the mixture as described above, and at least one organic solvent.

In some embodiments, the organic solvent is selected from an aromatic-based organic solvent, a heteroaromatic-based organic solvent, an ester-based organic solvent, an aromatic ketone-based organic solvent, an aromatic ether-based organic solvent, an aliphatic ketone-based organic solvent, an aliphatic ether-based organic solvent, an alicyclic-based organic solvent, an olefin-based organic solvent, a borate ester-based organic solvent, a phosphate ester-based organic solvent, or a mixture of two or more of the solvents above.

In one preferable embodiment, according to the composition of the disclosure, at least one organic solvent is n aromatic-based or a heteroaromatic-based organic solvent.

Examples of the aromatic-based or the heteroaromatic-based organic solvent suitable for the disclosure include, but not limited to, p-diisopropylbenzene, pentyl benzene, tetrahydroa naphthyl group, cyclohexylbenzene, chloroa naphthyl group, 1,4-dimethyla naphthyl group, 3-isopropylbia phenyl group, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butadiene benzene, dodecylbenzene, dihexylbenzene, dibutylbenzene, p-diisopropylbenzene, cyclohexylbenzene, benzylbutylbenzene, dimethyla naphthyl group, 3-isopropylbia phenyl group, p-methylcumene, 1-methyla naphthyl group, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbia phenyl group, α,α-dichlorodiphenylmethane, 4-(3-phenylpropyl) pyridine, benzyl benzoate, 1,1-bis(3,4-dimethylphenyl) ethane, 2-isopropyla naphthyl group, quinoline, isoquinoline, methyl 2-furanoate, ethyl 2-furanoate, and the like.

Examples of the aromatic ketone-based organic solvent suitable for the disclosure include, but not limited to, 1-tetrahydronaphthalenone, 2-tetrahydronaphthalenone, 2-(phenyl epoxy) tetrahydronaphthalenone, 6-(methoxyl) tetrahydronaphthalenone, acetophenone, phenylacetone, benzophenone, and derivatives of these compounds, for example, 4-methylacetophenone, 3-methylacetophenone, 2-methylacetophenone, 4-methylphenylacetone, 3-methylphenylacetone, 2-methylphenylacetone, and the like.

Examples of the aromatic ether-based organic solvent suitable for the disclosure include, but not limited to, 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxya naphthyl group, diphenyl ether, 2-phenoxymethyl ether, 2-phenoxytetrahydrofuran, and ethyl-2-naphthyl ether.

In some preferable embodiments, according to the composition of the disclosure, at least one organic solvents is selected from the aliphatic ketone-based organic solvent, such as 2-nonone, 3-nonone, 5-nonone, 2-decanone, 2,5-hexanedione, 2,6,8-trimethyl-4-nonone, fenchone, phorone, isophorone, di-n-pentyl ketone, or the like; or, at least one organic solvent is selected from the aliphatic ether-based organic solvent, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, or tetraethylene glycol dimethyl ether.

In some preferable embodiments, according to the composition of the disclosure, at least one organic solvent is selected from the ester-based organic solvent, which includes, but not limited to, octanoate, sebacate, stearate, benzoate, phenylacetate, cinnamate, oxalate, maleate, alkyl lactone, oleate, and the like. Preferably, the first organic solvent may be selected from octyl octanoate, diethyl sebacate, diallyl phthalate, isononyl isononanoate, or the like.

The above-mentioned organic solvents can be used individually or in a mixture form comprising two or more organic solvents.

In some preferable embodiments, the composition of the disclosure includes at least one organic boron-nitrogen compound or the mixture as described above, and at least one organic solvent, and further includes another organic solvent. Examples of another organic solvent include, but not limited to, methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, naphthane, indene, and/or mixtures thereof.

In some preferable embodiments, the organic solvents particularly suitable for the disclosure have Hansen solubility parameters in the following ranges:
δd (dispersion force) ranging from 17.0 MPa^{1/2} to 23.2 MPa^{1/2}, preferably ranging from 18.5 to 21.0 MPa^{1/2};
δp (polarity force) ranging from 0.2 MPa^{1/2} to 12.5 MPa^{1/2}, preferably ranging from 2.0 to 6.0 MPa^{1/2}; and
δh (hydrogen bonding force) ranging from 0.9 MPa^{1/2} to 14.2 MPa^{1/2}, preferably ranging from 2.0 to 6.0 MPa^{1/2}.

According to the composition of the disclosure, when selecting the organic solvents, their boiling points need to be considered. In the disclosure, the boiling point of the organic solvents is greater than or equal to 150° C., preferably greater than or equal to 180° C., more preferably greater than or equal to 200° C., further preferably greater than or equal to 250° C., most preferably greater than or equal to 300° C. The boiling points of the organic solvents in the above ranges are beneficial to preventing nozzles of inkjet printing heads from clogging. The organic solvents can evaporate from a solvent system to form films containing functional materials.

In one preferable embodiment, the composition according to the disclosure is a solution.

In another preferable embodiment, the composition according to the disclosure is a suspension.

The composition in the embodiments of the disclosure may include from 0.01 wt % to 10 wt % of the organic boron-nitrogen compound or the mixture, based on the weight of the composition, preferably 0.1 wt % to 15wt %, more preferably 0.2 wt % to 5wt %, most preferably 0.25 wt % to 3wt %.

The disclosure further relates to the use of the composition as a coating material or printing ink for preparing organic electronic devices, preferably using the composition in the preparation method by printing or coating.

Suitable printing or coating technologies include, but not limited to, inkjet printing, nozzle printing, letterpress printing, screen printing, dip coating, rotating coating, scraper coating, roller printing, torsion roller printing, lithographic printing, flexographic printing, rotary printing, spray coating, brush coating, transfer printing, slit extrusion coating, and the like. Gravure printing, nozzle printing, and inkjet printing are preferred. The solution or the suspension may further include one or more components, such as a surfactant , a lubricant, a wetting agent, a dispersant, a hydrophobic agent, an adhesive, or the like, for adjusting viscosity, improving forming performance of a film and adhesiveness. Regarding printing technology and its requirements for solutions, such as solvents, concentration, viscosity, and the like.

One embodiment of the disclosure further provides the use of the organic boron-nitrogen compound, the mixture, or the composition as described above in the preparation of organic electronic devices.

Further, the organic electronic devices above are selected from, but not limited to, organic light-emitting diodes (OLEDs), organic photovoltaic cells (OPVs), organic light-emitting cells (OLEECs), organic field-effect transistors (OFETs), organic light-emitting field-effect transistors, organic lasers, organic spintronic devices, organic sensors, organic plasmon emitting diodes (OPEDs), or the like. In particular, OLEDs are preferred. In the embodiments of the disclosure, the organic boron-nitrogen compound, the mixture, or the composition is preferably used as functional materials to prepare functional layers of OLED devices.

Further, the above functional layers include the organic boron-nitrogen compound or the mixture as described above, or the functional layers are prepared from the above-mentioned composition.

Further, the functional layers are light-emitting layers. A light-emitting layer includes a host material and a guest material, and the guest material is the above-mentioned organic boron-nitrogen compound or the mixture. Furthermore, a mass ratio of the host material to the guest material is from (8 to12): 1. Furthermore, a mass ratio of the host material to the guest material is 10:1.

One embodiment of the disclosure further provides an organic electronic device, which includes a first electrode, a second electrode, and one or more functional layers disposed between the first electrode and the second electrode. At least one functional layer in the one or more functional layers includes the organic boron-nitrogen compound or the mixture as described above, or is prepared from the composition as described above.

Further, the first electrode is a cathode and the second electrode is an anode. The above-mentioned functional layer is selected from a hole injection layer (HIL), a hole transport layer (HTL), a light-emitting layer (EML), an electron blocking layer (EBL), an electron injection layer (EIL), an electron transport layer (ETL), or a hole blocking layer (HBL). Preferably, the functional layer is selected from the light-emitting layer.

In some embodiments, the above-mentioned one or more organic functional layers include at least one light-emitting layer, which includes the organic boron-nitrogen compound or the mixture as described above, or is prepared from the composition as described above.

Further, the organic electronic device includes an anode, a hole injection layer (HIL), a hole transport layer (HTL), a light-emitting layer (EML) 104, an electron injection layer (EIL), an electron transport layer (ETL), and a cathode.

Further, the organic electronic device may be selected from, but not limited to, an organic light-emitting diode (OLED), an organic photovoltaic cell (OPV), an organic light-emitting cell (OLEEC), an organic field-effect transistor (OFET), an organic light-emitting field-effect transistor, an organic laser, an organic spintronic device, an organic sensor, an organic plasmon emission diode (OPED), or the like. An organic electroluminescent device such as the OLED, the OLEEC, or the organic light-emitting field-effect transistor, is particularly preferred.

In some embodiments, the above-mentioned organic electronic device is an OLED device including a substrate, an anode, at least one light-emitting layer, and a cathode.

Specifically, the substrate may be opaque or transparent. A transparent substrate can be used to prepare a transparent light-emitting element. Detailed description about the substrate can refer to Bulovic et al. (Nature 1996, 380, p29), and Gu et al. (Appl Phys Lett 1996, 68, p2606). The substrate may be rigid or elastic. The substrate may be plastic, metal, a semiconductor chip, or a glass. It is preferable for the substrate to have a smooth surface. A substrate without surface defects is a particularly ideal choice. In one preferable embodiment, the substrate is flexible, and selected from, but not limited to, a polymer film or plastic. A glass transition temperature Tg of a material of the substrate is greater than 150° C., preferably greater than 200° C., more preferably greater than 250° C., most preferably greater than 300° C. Suitable examples of the material of a flexible substrate include polyethylene terephthalate (PET) and polyethylene naphthalene-2,6-dicarboxylate (PEN).

The anode may include conductive metal, metal oxide, or conductive polymer. Holes in the anode can be easily injected into a hole injection layer (HIL), a hole transport layer (HTL), or a light-emitting layer. In one embodiment, an absolute value of a difference between work function of the anode and HOMO energy level or valence band energy level of an emitter of the light-emitting layer, or a p-type semiconductor material of the HIL, the HTL, or an electron blocking layer (EBL) is less than 0.5 eV, preferably less than 0.3 eV, more preferably less than 0.2 eV. Examples of materials of the anode include, but not limited to, Al, Cu, Au, Ag, Mg, Fe, Co, Ni, Mn, Pd, Pt, ITO, zinc oxide doped with aluminum (AZO), and the like. Other suitable materials are known, and ordinary skilled in the art can easily select. The materials of the anode can be applied to any suitable technology, such as a suitable physical vapor deposition method, including RF magnetron sputtering, vacuum thermal evaporation, electron beam (e-beam), or the like. In some embodiments, the anode is a patterned structure. A patterned ITO conductive substrate is commercially available and can be used to prepare the devices according to the disclosure.

The cathode may include conductive metal or metal oxide. Electrons in the cathode can be easily injected into an electron injection layer (EIL), an electron transport layer (ETL), or the light-emitting layer. In one embodiment, an absolute value of a difference between work function of the cathode and LUMO energy level or valence band energy level of an emitter of the light-emitting layer, or a n-type semiconductor material of the EIL, the ETL, or a hole blocking layer (HBL) is less than 0.5 eV, preferably less than 0.3 eV, more preferably less than 0.2 eV. In principle, all materials that can be used for the cathode of OLEDs can be used as materials of the cathode of the devices according to the disclosure. Examples of the materials of the cathode include, but not limited to, Al, Au, Ag, Ca, Ba, Mg, LiF/Al, MgAg alloy, BaF₂/Al, Cu, Fe, Co, Ni, Mn, Pd, Pt, ITO, and the like. The materials of the cathode can be applied to by any suitable technology, such as a suitable physical vapor deposition method including RF magnetron sputtering, vacuum thermal evaporation, electron beam (e-beam), or the like.

The OLED may further include other functional layers, such as a hole injection layer (HIL), a hole transport layer (HTL), an electron blocking layer (EBL), an electron injection layer (EIL), an electron transport layer (ETL), and a hole blocking layer (HBL). Materials suitable for use in these functional layers have been described in detail above and can also refer to patent applications WO 2010/135519 A1, US 2009/0134784 A1, and WO 2011/110277 A1, all the contents of these three patent applications are incorporated herein by reference in their entirety.

In one preferable embodiment, the light-emitting layer of the organic electronic device according to the disclosure includes the organic boron-nitrogen compound or the mixture of the disclosure, or the light-emitting layer is prepared from the composition of the disclosure.

The organic electronic device according to the disclosure has an emission wavelength ranging from 300 nm to 1000 nm, preferably 350 nm to 900 nm, more preferably 400 nm to 800 nm.

The disclosure further relates to the application of the organic electronic device according to the disclosure in various electronic apparatuses, which include, but not limited to, display devices, illumination devices, light sources, sensors, and the like.

The disclosure further relates to an electronic apparatus that includes the organic electronic device according to the disclosure. The electronic apparatus may include, but not limited to, a display device, an illumination device, a light source, a sensor, or the like.

The following contents will provide a description of the disclosure in conjunction with preferable examples, but not limited to these examples. It can be understood that, the accompanying claims summarize the scope of the disclosure. Under the guidance of concepts of the disclosure, those skilled in the art should be aware that certain changes made to each example of the disclosure will be covered by the spirits and scope of the claims.

### EXAMPLES

The following contents will provide examples of the organic boron-nitrogen compound, the mixture, the composition, and the organic electronic device according to the disclosure, but not limited to the following examples.

### Example 1

### Synthesis Route of Compound (M1)

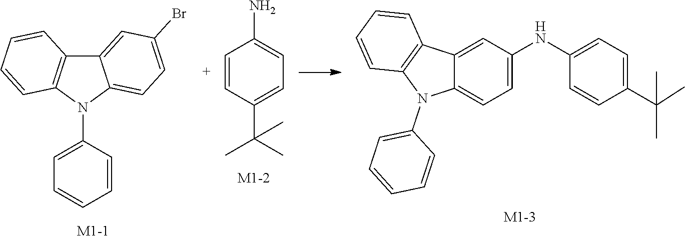 [SMILES: Brc1ccc2c(c1)c1ccccc1n2-c1ccccc1 ; CC(C)(C)c1ccc(N)cc1 ; CC(C)(C)c1ccc(Nc2ccc3c(c2)c2ccccc2n3-c2ccccc2)cc1]

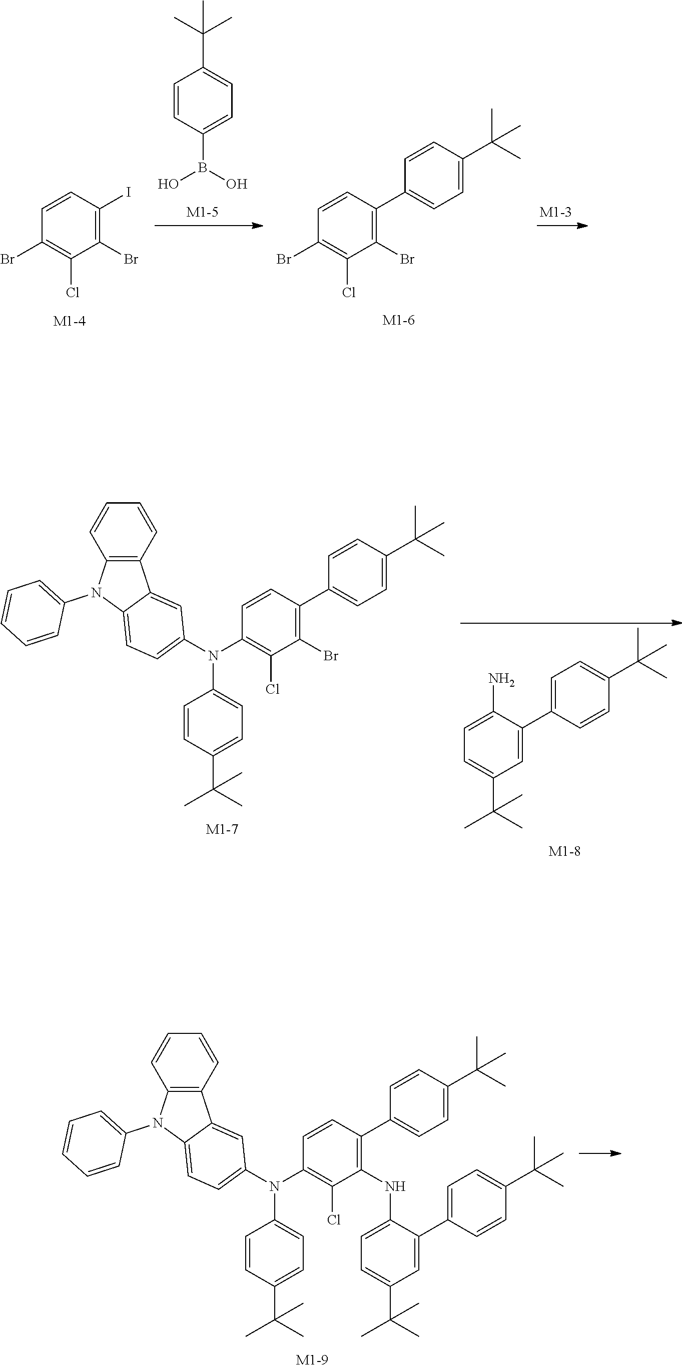

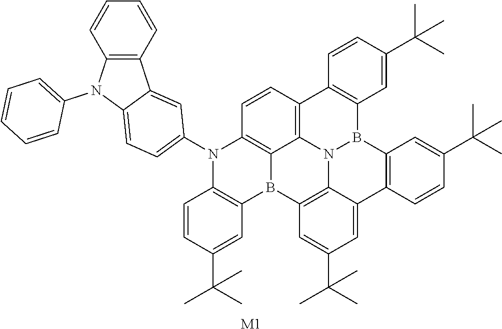

### Synthesis of Compound (M1)

1) Synthesis of intermediate M1-3: in a nitrogen environment, compound M1-1 (32.1 g, 100 mmol), compound M1-2 (14.9 g, 100 mmol), Pd₂(dba)₃ (0.92 g, 1 mmol), tri-tert-butylphosphine (0.4 g, 2 mmol), sodium tert-butoxide (13.7 g, 150 mmol), and 200 mL of anhydrous toluene solvent were added to a two-necked flask (500 mL), heated to 60° C., stirred and reacted for 6 hours, then cooled to room temperature. The reaction was quenched with water, and most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M1-3 with yield of 80%. The eluent used in the purification was composed of petroleum ether and dichloromethane with a volume ratio of 3:1.
2) Synthesis of intermediate M1-6: in a nitrogen environment, compound M1-4 (39.6 g, 100 mmol), compound M1-5 (17.8 g, 100 mmol), tetrakis(triphenylphosphine)palladium (3.31 g, 3 mmol), 50 mL of aqueous solution of potassium carbonate (27.6 g, 200 mmol), and 200 mL of toluene were added to a three-necked flask (500 mL), heated and stirred to 110° C., and reacted for 12 hours. After the reaction was completed, the reaction solution was cooled to room temperature. The filtrate was treated by suction filtration, then most of the solvent was removed by rotary evaporation. The reaction solution was dissolved in dichloromethane and washed three times with water. Organic liquids were collected, mixed with silica gel, and purified by silica gel column chromatography to obtain the intermediate M1-6 with yield of 70%. The eluent used in the purification was composed of petroleum ether and dichloromethane with a volume ratio of 5:1.
3) Synthesis of intermediate M1-7: in a nitrogen environment, compound M1-6 (24.2 g, 60 mmol), compound M1-3 (23.4 g, 60 mmol), Pd₂(dba)₃ (0.55 g, 0.6 mmol), tri-tert-butylphosphine (0.24 g, 1.2 mmol), sodium tert-butoxide (8.2 g, 90 mmol), and 150 mL of anhydrous toluene solvent were added to a two-necked flask (300 mL), heated to 60 ºC, stirred and reacted for 6 hours, then cooled to room temperature. The reaction was quenched with water, and most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M1-7 with yield of 70%. The eluent used in the purification was composed of petroleum ether and dichloromethane with a volume ratio of 4:1.
4) Synthesis of intermediate M1-9: in a nitrogen environment, compound M1-7 (28.5 g, 40 mmol), compound M1-8 (11.3 g, 40 mmol), compound Pd₂(dba)₃ (0.37 g, 0.4 mmol), tri-tert-butylphosphine (0.16 g, 0.8 mmol), sodium tert-butoxide (5.5 g, 60 mmol), and 100 mL of anhydrous toluene solvent were added to a two-necked flask (250 mL), heated to 60° C., stirred and reacted for 6 hours, then cooled to room temperature. The reaction was quenched with water, and most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M1-9 with yield of 70%. The eluent used in the purification was composed of petroleum ether and dichloromethane with a volume ratio of 2.5:1.
5) Synthesis of compound M1: in a nitrogen environment, compound M1-9 (18.3 g, 20 mmol) and 100 mL of anhydrous toluene solvent were added to a three-necked flask (300 mL), stirred to dissolve them, then cooled to −78° C., and 45 mmol of tert-butyllithium was slowly added. After the reaction solution was reacted for 2 hours, 50 mmol of boron tribromide was added at one time, then slowly raise the reaction solution to room temperature. The reaction solution was continuously stirred and reacted for 3 hours, then 80 mmol of N, N-diisopropylethylamine was added at one time. Subsequently, the reaction solution was heated to 100° C. and reacted for 4 hours. After the reaction was completed, most of the solvent was removed from the reaction solution by rotary evaporation. The reaction solution was dissolved in dichloromethane and washed three times with water. Organic liquids were collected, mixed with silica gel, and purified by silica gel column chromatography to obtain the compound M1 with yield of 53%. The eluent used in the purification was composed of petroleum ether and dichloromethane with a volume ratio of 3.5:1. MS (ASAP): 894.

### Example 2

### Synthesis Route of Compound (M2)

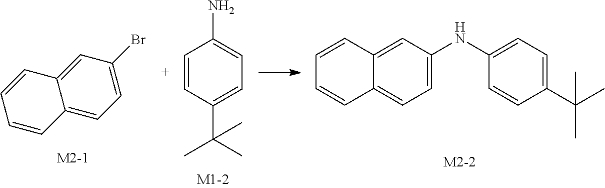 [SMILES: Brc1ccc2ccccc2c1 ; CC(C)(C)c1ccc(N)cc1 ; CC(C)(C)c1ccc(Nc2ccc3ccccc3c2)cc1]

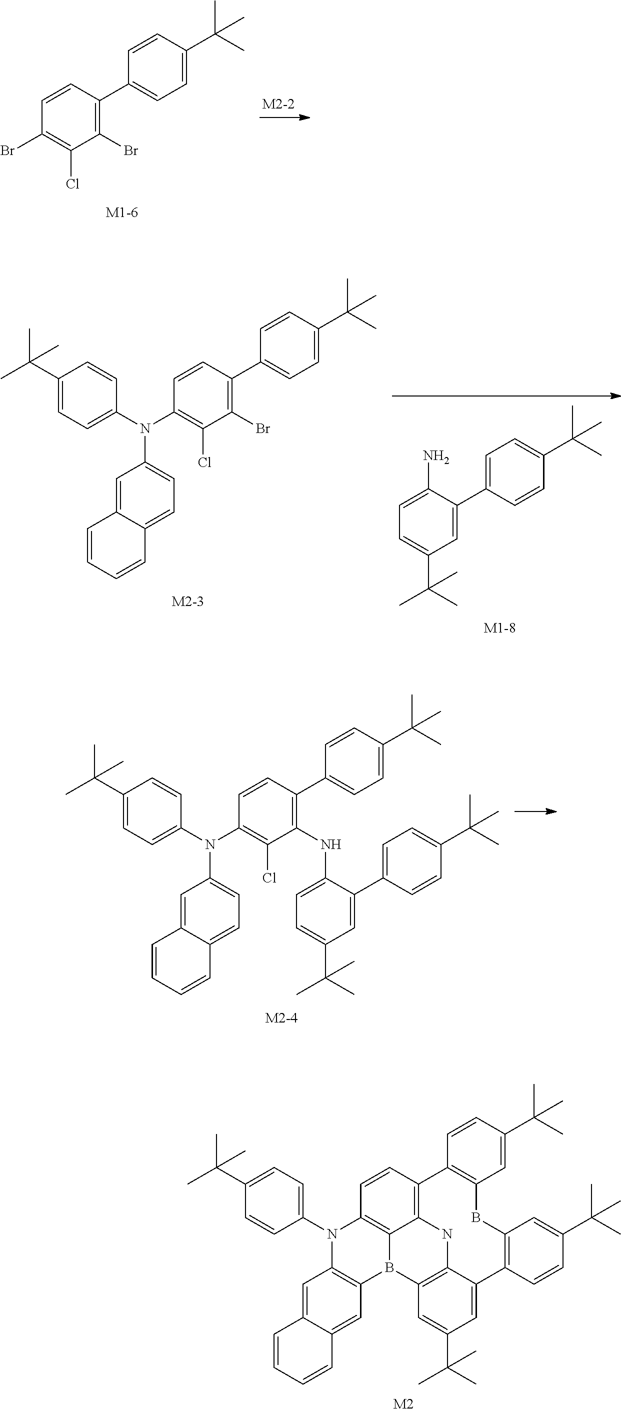

### Synthesis of Compound (M2)

1) Synthesis of intermediate M2-2: according to the synthesis method of compound M1-3, compound M2-1 was substituted for compound M1-1 to obtain intermediate M2-2 with yield of 85%.
2) Synthesis of intermediate M2-3: according to the synthesis method of compound M1-7, compound M2-2 was substituted for compound M1-3 to obtain intermediate M2-3 with yield of 72%.
3) Synthesis of intermediate M2-4: according to the synthesis method of compound M1-9, compound M2-3 was substituted for compound M1-7 to obtain intermediate M2-4 with yield of 68%.
4) Synthesis of compound M2: according to the synthesis method of compound M1, compound M2-4 was substituted for compound M1-9 to obtain compound M2 with yield of 55%. MS (ASAP): 779.

### Example 3

### Synthesis Route of Compound (M3)

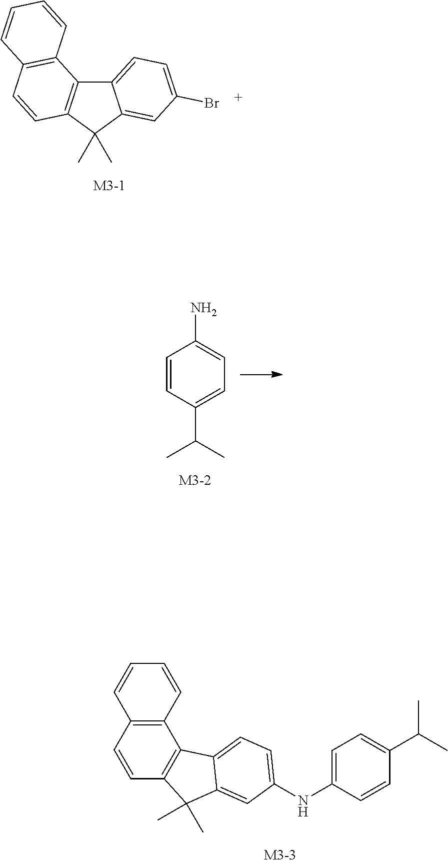

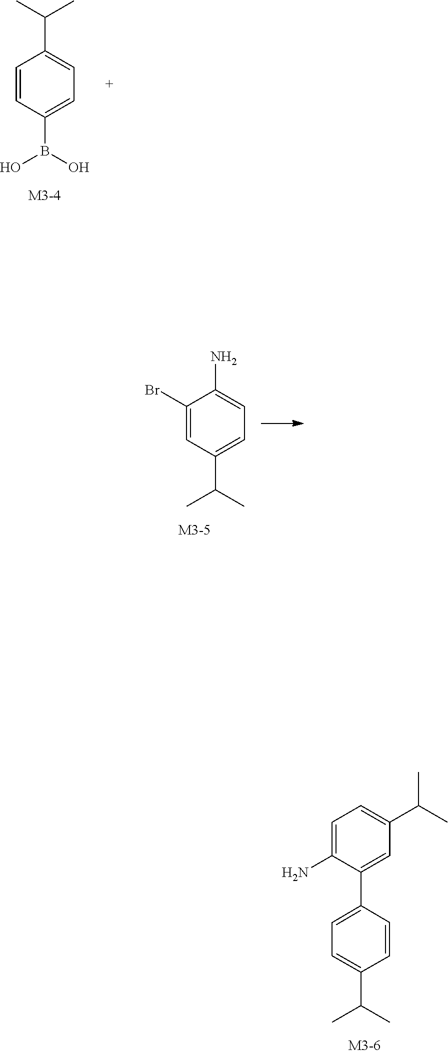 [SMILES: CC(C)c1ccc(B(O)O)cc1 ; CC(C)c1ccc(N)c(Br)c1 ; CC(C)c1ccc(-c2cc(C(C)C)ccc2N)cc1]

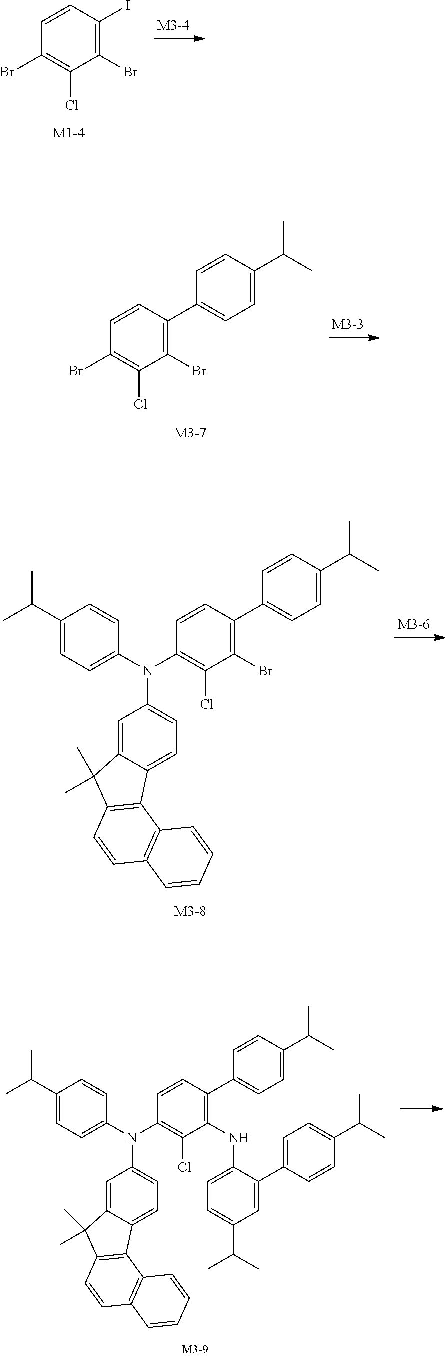

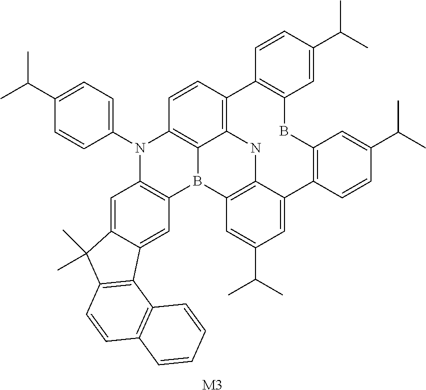

### Synthesis of Compound (M3)

1) Synthesis of intermediate M3-3: according to the synthesis method of compound M1-3, compounds M3-1 and M3-2 were substituted for compounds M1-1 and M1-2, respectively, to obtain intermediate M3-3 with yield of 82%.
2) Synthesis of intermediate M3-6: according to the synthesis method of compound M1-6, compounds M3-5 and M3-4 were substituted for compounds M1-4 and M1-5, respectively, to obtain intermediate M3-6 with yield of 75%.
3) Synthesis of intermediate M3-7: according to the synthesis method of compound M1-6, compound M3-4 was substituted for compound M1-5 to obtain intermediate M3-7 with yield of 68%.
4) Synthesis of intermediate M3-8: according to the synthesis method of compound M1-7, compounds M3-7 and M3-3 were substituted for compounds M1-6 and M1-3, respectively, to obtain intermediate M3-8 with yield of 72%.
5) Synthesis of intermediate M3-9: according to the synthesis method of compound M1-9, compounds M3-8 and M3-6 were substituted for compounds M1-7 and M1-8, respectively, to obtain intermediate M3-9 with yield of 73%.
7) Synthesis of compound M3: according to the synthesis method of compound M1, compound M3-9 was substituted for compound M1-9 to obtain compound M3 with yield of 54%. MS (ASAP): 839.

### Example 4

### Synthesis Route of Compound (M4)

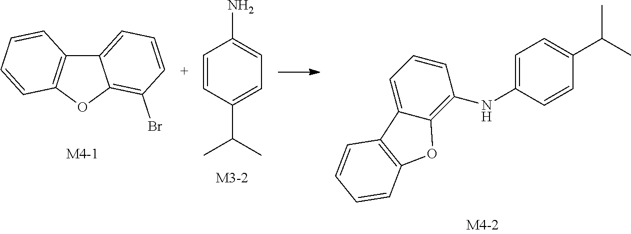

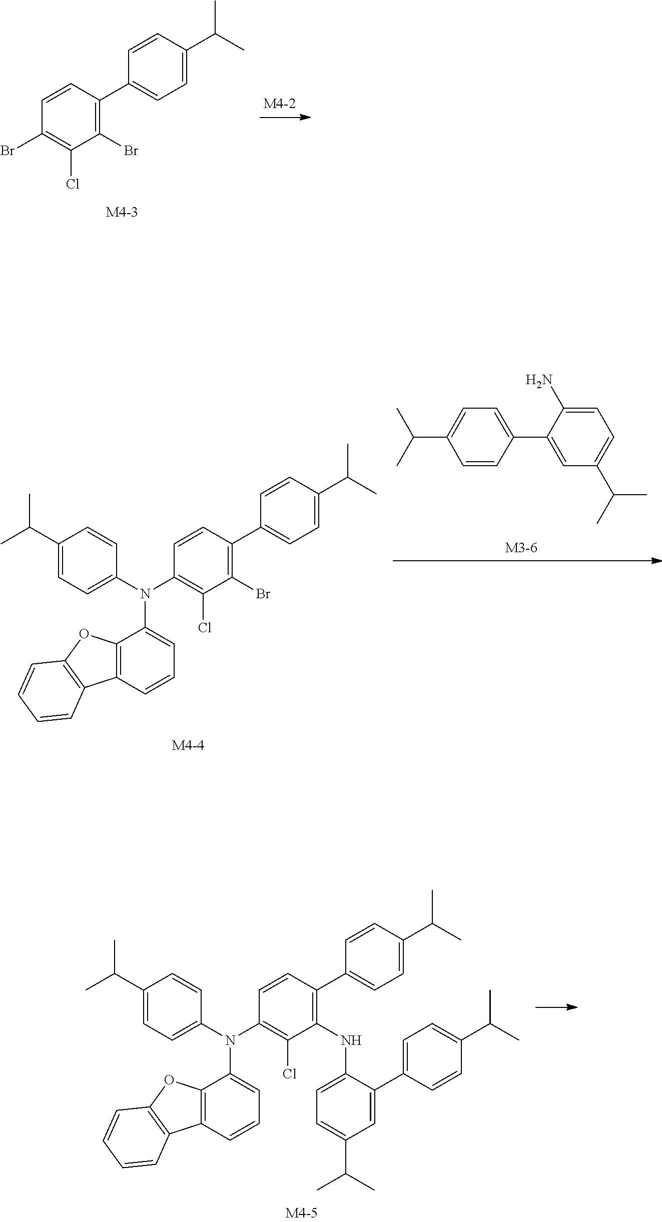

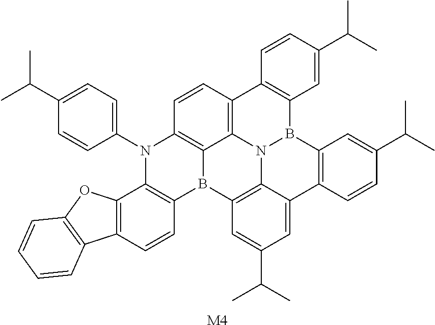

### Synthesis of Compound (M4)

1) Synthesis of intermediate M4-2: according to the synthesis method of compound M1-3, compounds M4-1 and M3-2 were substituted for compounds M1-1 and M1-2, respectively, to obtain intermediate M4-2 with yield of 78%.
2) Synthesis of intermediate M4-4: according to the synthesis method of compound M1-7, compounds M4-3 and M4-2 were substituted for compounds M1-6 and M1-3, respectively, to obtain intermediate M4-4 with yield of 73%.
3) Synthesis of intermediate M4-5: according to the synthesis method of compound M1-9, compounds M4-4 and M3-6 were substituted for compounds M1-7 and M1-8, respectively, to obtain intermediate M4-5 with yield of 71%.
4) Synthesis of compound M4: according to the synthesis method of compound M1, compound M4-5 was substituted for compound M1-9 to obtain compound M4 with yield of 52%. MS (ASAP): 763.

### Example 5

### Synthesis Route of Compound (M5)

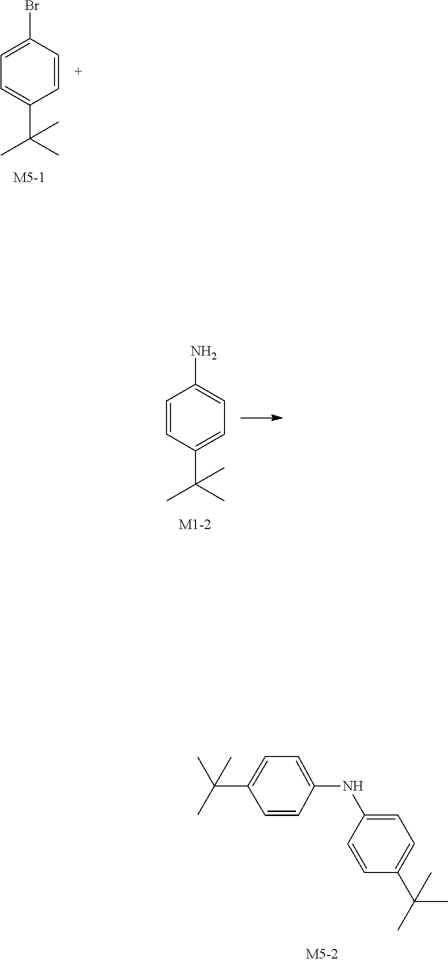 [SMILES: CC(C)(C)c1ccc(Br)cc1 ; CC(C)(C)c1ccc(N)cc1 ; CC(C)(C)c1ccc(Nc2ccc(C(C)(C)C)cc2)cc1]

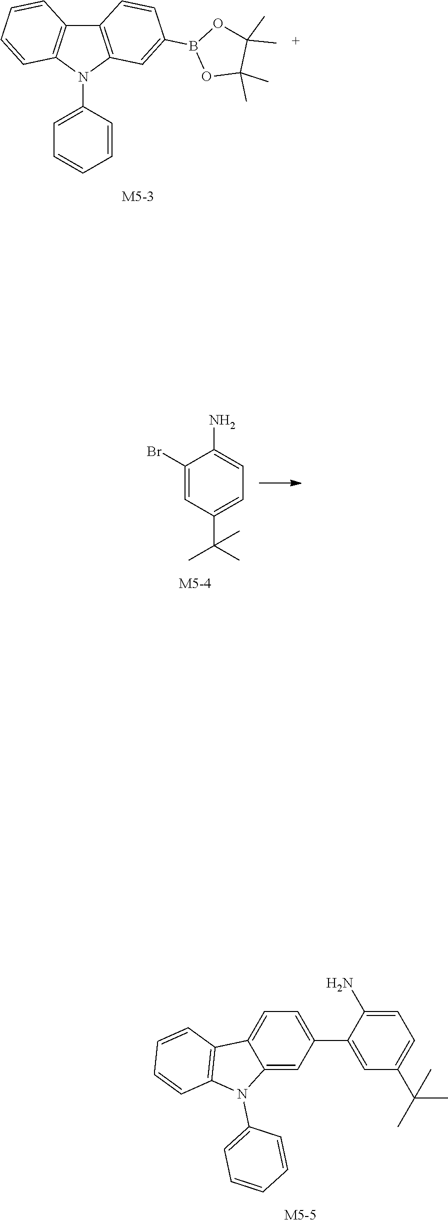 [SMILES: CC1(C)OB(c2ccc3c4ccccc4n(-c4ccccc4)c3c2)OC1(C)C ; CC(C)(C)c1ccc(N)c(Br)c1 ; CC(C)(C)c1ccc(N)c(-c2ccc3c4ccccc4n(-c4ccccc4)c3c2)c1]

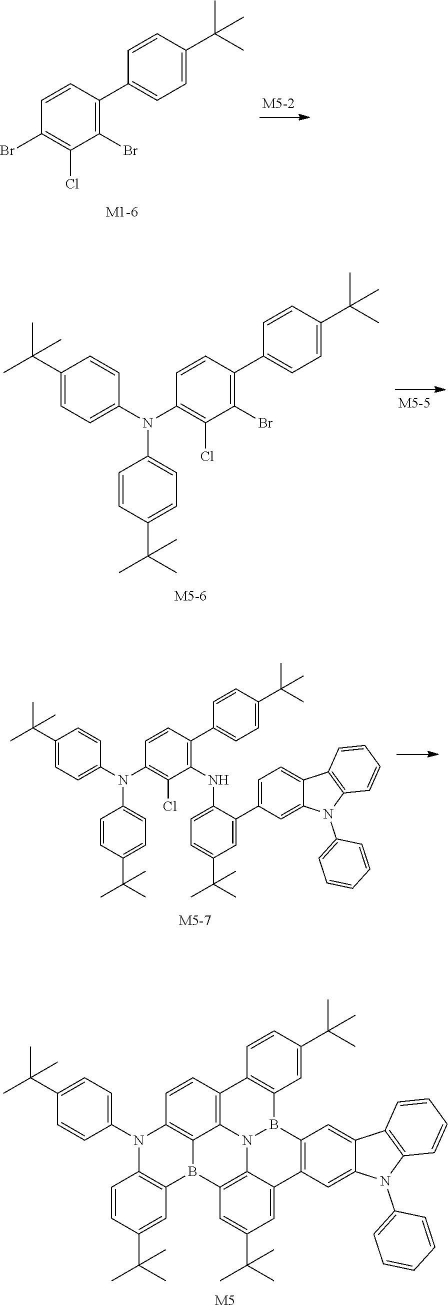

### Synthesis of Compound (M5)

1) Synthesis of intermediate M5-3: according to the synthesis method of compound M1-3, compound M5-1 was substituted for compound M1-1 to obtain intermediate M5-3 with yield of 86%.
2) Synthesis of intermediate M5-5: according to the synthesis method of compound M1-6, compounds M5-4 and M5-3 were substituted for compounds M1-4 and M1-5, respectively, to obtain intermediate M5-5 with yield of 75%.
3) Synthesis of intermediate M5-6: according to the synthesis method of compound M1-7, compound M5-2 was substituted for compound M1-3 to obtain intermediate M5-6 with yield of 70%.
4) Synthesis of intermediate M5-7: according to the synthesis method of compound M1-9, compounds M5-6 and M5-5 were substituted for compounds M1-7 and M1-8, respectively, to obtain intermediate M5-7 with yield of 70%.
5) Synthesis of compound M5: according to the synthesis method of compound M1, compound M5-7 was substituted for compound M1-9 to obtain compound M5 with yield of 50%. MS (ASAP): 894.

### Example 6

### Synthesis Route of Compound (M6)

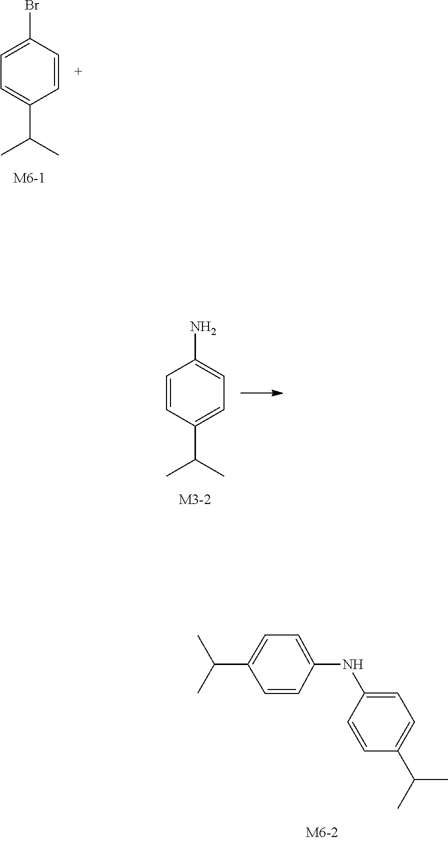

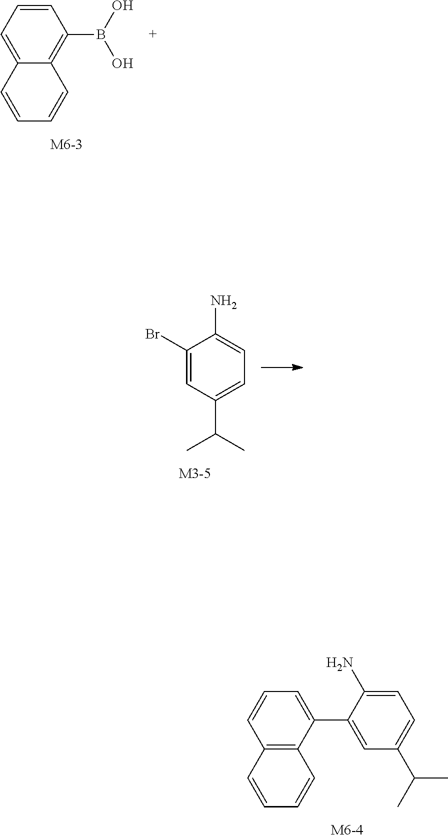 [SMILES: OB(O)c1cccc2ccccc12 ; CC(C)c1ccc(N)c(Br)c1 ; CC(C)c1ccc(N)c(-c2cccc3ccccc23)c1]

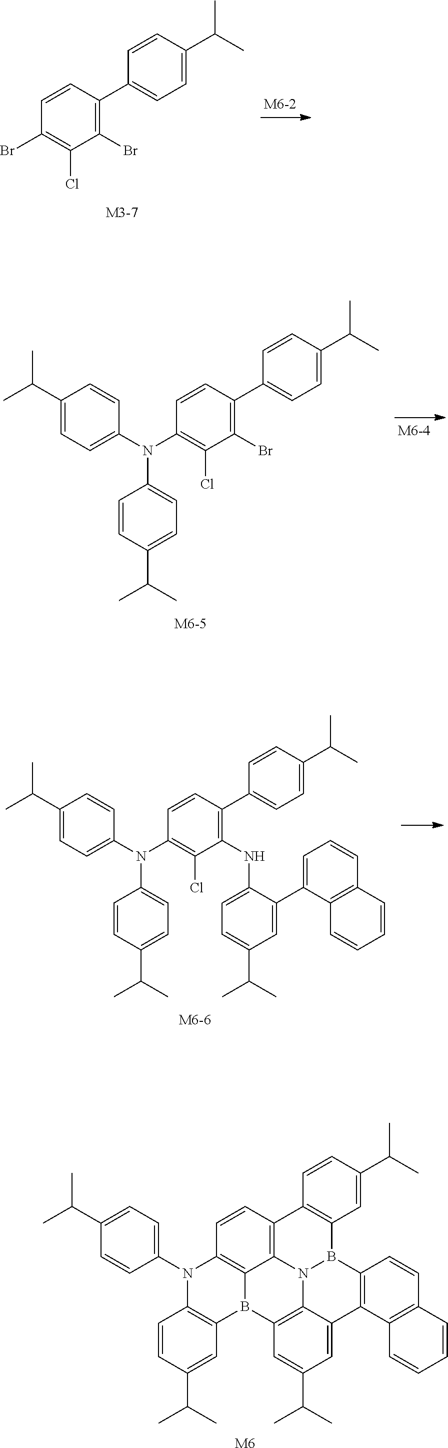

### Synthesis of Compound (M6)

1) Synthesis of intermediate M6-2: according to the synthesis method of compound M1-3, compound M6-1 and compound 3-2 were substituted for compound M1-1 and compound M1-2, respectively, to obtain intermediate M6-2 with yield of 85%.
2) Synthesis of intermediate M6-4: according to the synthesis method of compound M1-6, compounds M3-5 and M6-3 were substituted for compounds M1-4 and M1-5, respectively, to obtain intermediate M6-4 with yield of 77%.
3) Synthesis of intermediate M6-5: according to the synthesis method of compound M1-7, compounds M3-7 and M6-2 were substituted for compounds M1-6 and M1-3, respectively, to obtain intermediate M6-5 with yield of 73%.
4) Synthesis of intermediate M6-6: according to the synthesis method of compound M1-9, compounds M6-5 and M6-4 were substituted for compounds M1-7 and M1-8, respectively, to obtain intermediate M6-6 with yield of 71%.
5) Synthesis of compound M6: according to the synthesis method of compound M1, compound M6-6 was substituted for compound M1-9 to obtain compound M6 with yield of 53%. MS (ASAP): 723.

### Example 7

### Synthesis Route of Compound (M7)

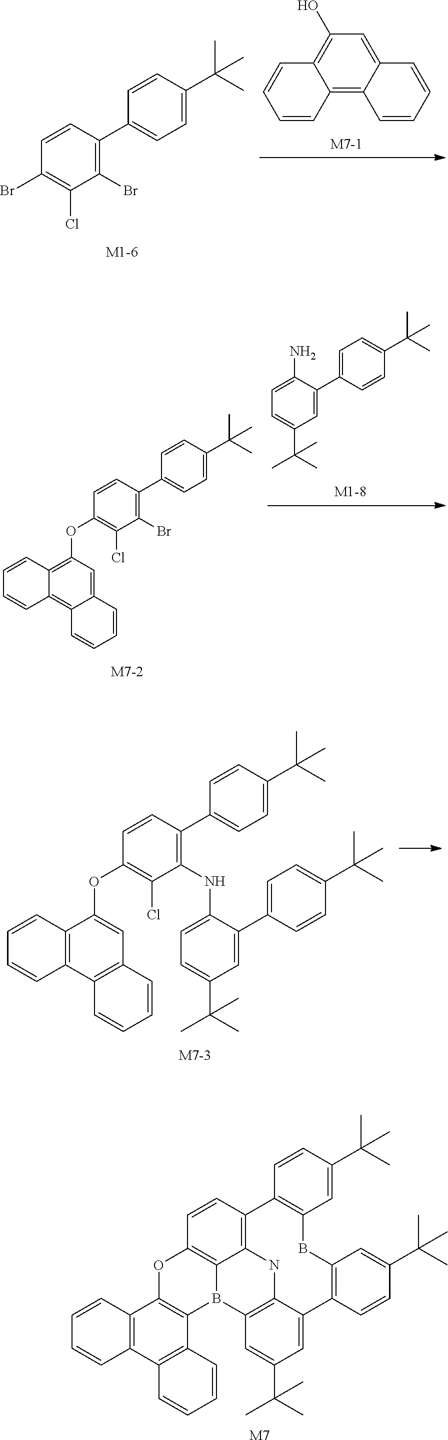

### Synthesis of Compound (M7)

1) Synthesis of intermediate M7-2: in a nitrogen environment, compound M7-1 (19.4 g, 100 mmol), sodium hydride (3.6 g, 150 mmol), and 200 mL of tetrahydrofuran solvent were added to a two-necked flask (500 mL), stirred and reacted for 1 hour. Compound M1-6 (40.3 g, 100 mmol) was added at one time, then the reaction solution was continuously stirred and reacted for 6 hours. The reaction was quenched with water, and most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M7-2 with yield of 70%. The eluent used in the purification was composed of petroleum ether and dichloromethane with a volume ratio of 4:1.
2) Synthesis of intermediate M7-3: according to the synthesis method of compound M1-9, compound M7-2 was substituted for compound M1-7 to obtain intermediate M7-3 with yield of 72%.
3) Synthesis of compound M7: according to the synthesis method of compound M1, compound M7-3 was substituted for compound M1-9 to obtain compound M7 with yield of 54%. MS (ASAP): 698.

### Example 8

### Synthesis Route of Compound (M8)

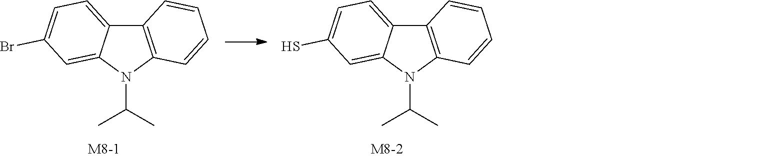 [SMILES: CC(C)n1c2ccccc2c2ccc(Br)cc21 ; CC(C)n1c2ccccc2c2ccc(S)cc21]

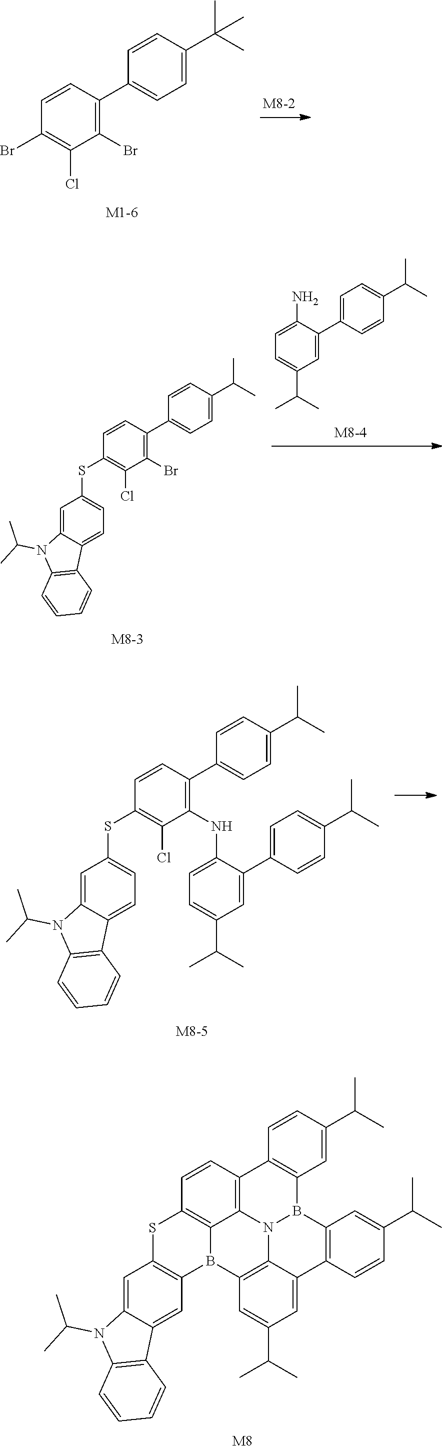

### Synthesis of Compound (M8)

1) Synthesis of intermediate M8-2: in a nitrogen environment, compound M8-1 (28.8 g, 100 mmol) and 150 mL of anhydrous tetrahydrofuran solvent were added to a two-necked flask (500 mL), stirred to dissolve them, then the reaction solution was cooled to -78° C. Subsequently, 100 mmol of n-butyllithium was slowly added to the reaction solution at a constant temperature, and continuously stirred and reacted for 2 hours. Then 100 mmol of sulfur powder was added to the reaction solution at one time. Raise the reaction solution to room temperature naturally, then the reaction solution was continuously stirred for 4 hours. Subsequently, 100 mL of ammonium chloride aqueous solution (2 mmol/mL) was added to the reaction solution, which was continuously stirred for 0.5 hours. After the reaction was completed, most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M8-2 with yield of 70%. The eluent used in the purification was composed of petroleum ether and dichloromethane with a volume ratio of 3:1.
2) Synthesis of intermediate M8-3: according to the synthesis method of compound M7-2, compound M8-2 was substituted for compound M7-1 to obtain intermediate M8-3 with yield of 68%.
3) Synthesis of intermediate M8-5: according to the synthesis method of compound M1-9, compound M8-3 and compound M8-4 were substituted for compound M1-7 and compound M1-8, respectively, to obtain intermediate M8-5 with yield of 70%.
4) Synthesis of compound M8: according to the synthesis method of compound M1, compound M8-5 was substituted for compound M1-9 to obtain compound M8 with yield of 52%. MS (ASAP): 703.

### Example 9

### Synthesis Route of Compound (M9)

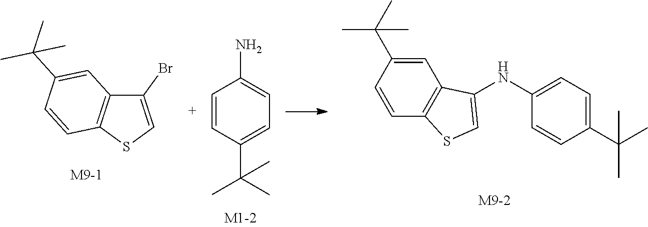 [SMILES: CC(C)(C)c1ccc2scc(Br)c2c1 ; CC(C)(C)c1ccc(N)cc1 ; CC(C)(C)c1ccc(Nc2csc3ccc(C(C)(C)C)cc23)cc1]

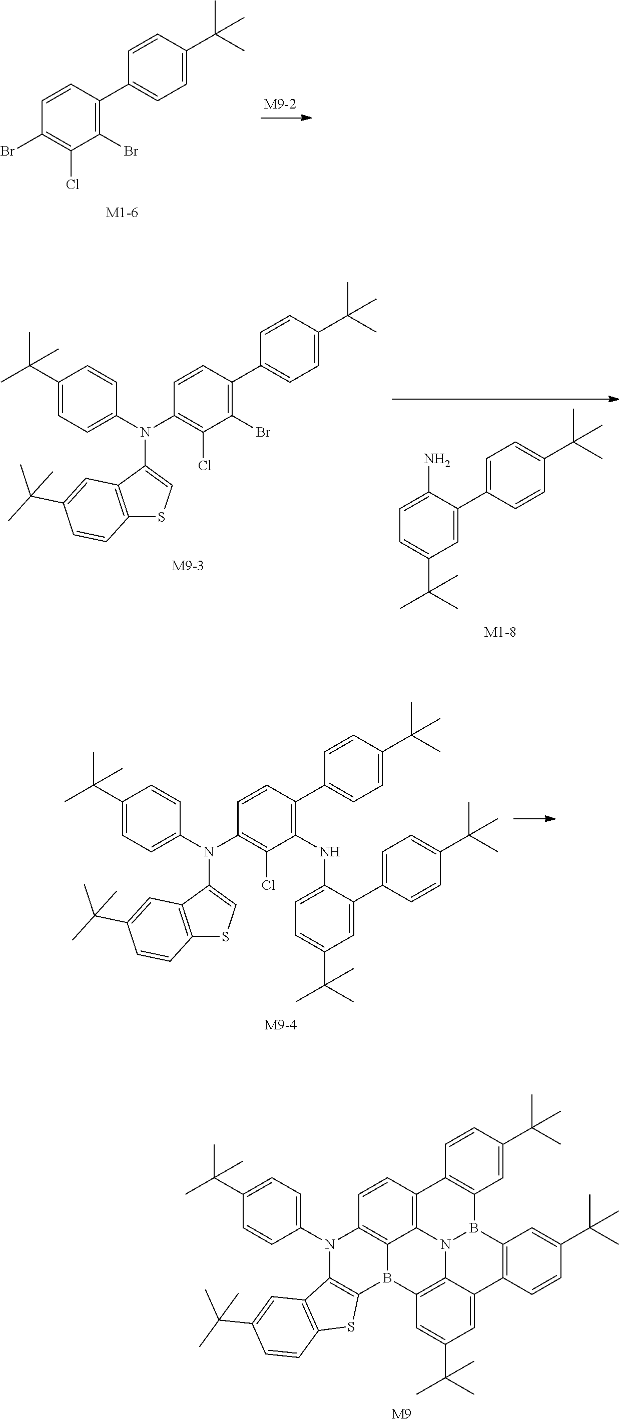

### Synthesis of Compound (M9)

1) Synthesis of intermediate M9-2: according to the synthesis method of compound M1-3, compound M9-1 was substituted for compound M1-1 to obtain intermediate M9-2 with yield of 78%.
2) Synthesis of intermediate M9-3: according to the synthesis method of compound M1-7, compound M9-2 was substituted for compound M1-3 to obtain intermediate M9-3 with yield of 69%.
3) Synthesis of intermediate M9-4: according to the synthesis method of compound M1-9, compound M9-3 was substituted for compound M1-7 to obtain intermediate M9-4 with yield of 65%.
4) Synthesis of compound M9: according to the synthesis method of compound M1, compound M9-4 was substituted for compound M1-9 to obtain compound M9 with yield of 50%. MS (ASAP): 841.

### Example 10

### Synthesis Route of Compound (M10)

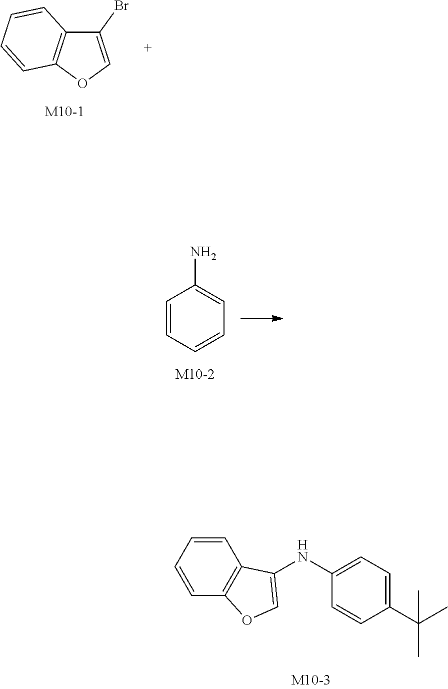 [SMILES: Brc1coc2ccccc12 ; Nc1ccccc1 ; CC(C)(C)c1ccc(Nc2coc3ccccc23)cc1]

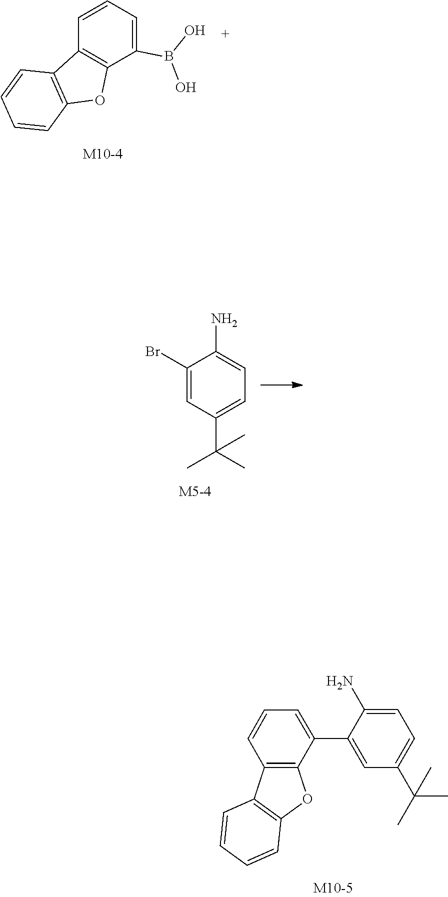 [SMILES: OB(O)c1cccc2c1oc1ccccc12 ; CC(C)(C)c1ccc(N)c(Br)c1 ; CC(C)(C)c1ccc(N)c(-c2cccc3c2oc2ccccc23)c1]

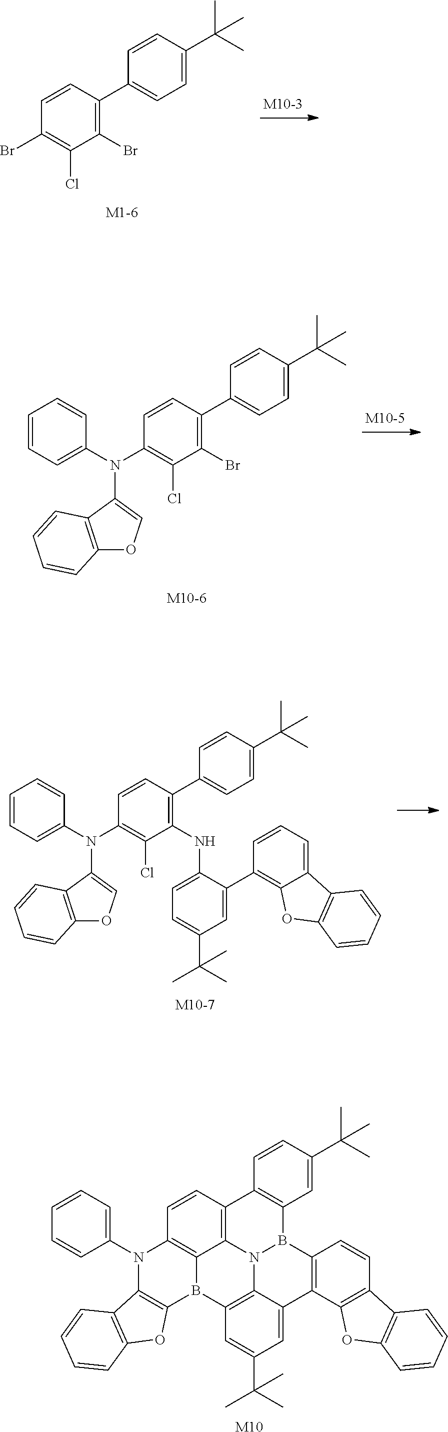

### Synthesis of Compound (M10)

1) Synthesis of intermediate M10-3: according to the synthesis method of compound M1-3, compounds M10-1 and M10-2 were substituted for compounds M1-1 and M1-2, respectively, to obtain intermediate M10-3 with yield of 75%.
2) Synthesis of intermediate M10-5: according to the synthesis method of compound M1-6, compounds M5-4 and M10-4 were substituted for compounds M1-4 and M1-5, respectively, to obtain intermediate M10-5 with yield of 70%.
3) Synthesis of intermediate M10-6: according to the synthesis method of compound M1-7, compound M10-3 was substituted for compound M1-3 to obtain intermediate M10-6 with yield of 70%.
4) Synthesis of intermediate M10-7: according to the synthesis method of compound M1-9, compounds M10-6 and M10-5 were substituted for compounds M1-7 and M1-8, respectively, to obtain intermediate M10-7 with yield of 67%.
5) Synthesis of compound M10: according to the synthesis method of compound M1, compound M10-7 was substituted for compound M1-9 to obtain compound M10 with yield of 54%. MS (ASAP): 747.

### Example 11

### Synthesis Route of Compound (M11)

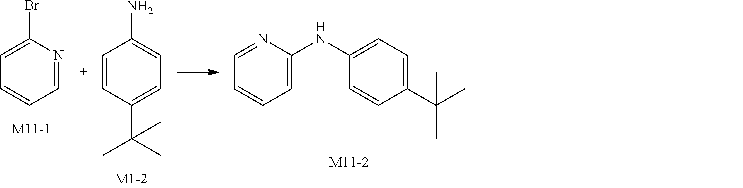

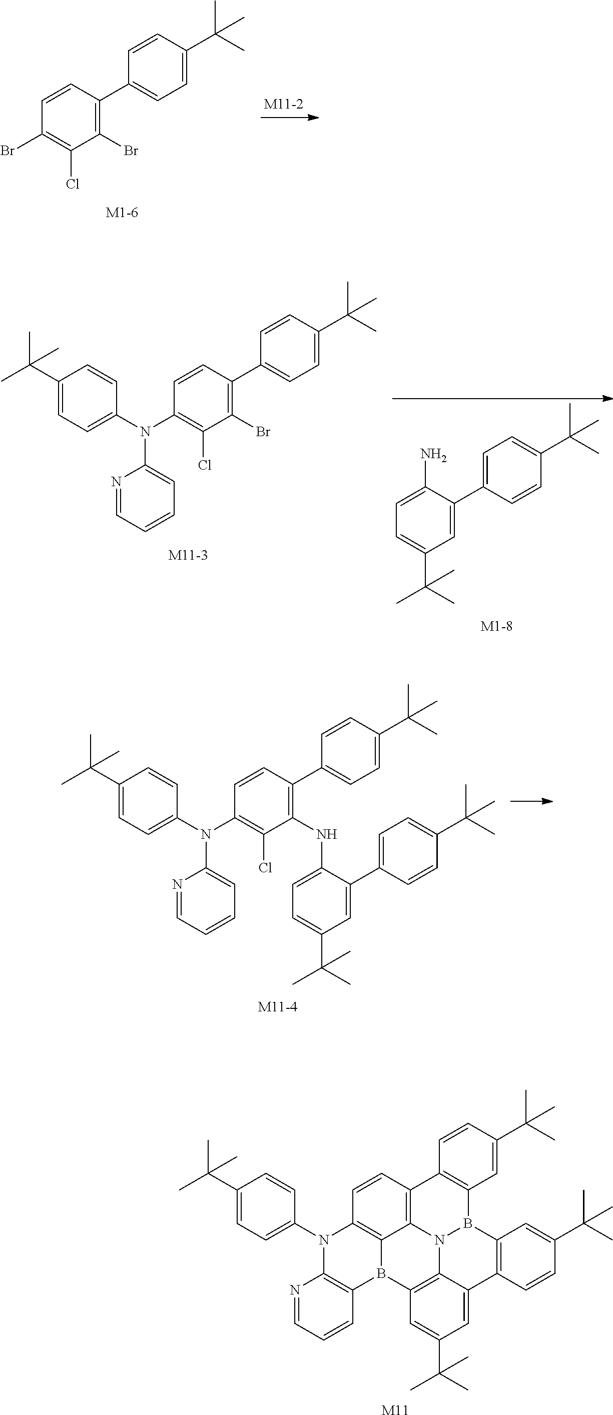

### Synthesis of Compound (M11)

1) Synthesis of intermediate M11-2: according to the synthesis method of compound M1-3, compound M11-1 was substituted for compound M1-1 to obtain intermediate M11-2 with yield of 70%.
2) Synthesis of intermediate M11-3: according to the synthesis method of compound M1-7, compound M11-2 was substituted for compound M1-3 to obtain intermediate M11-3 with yield of 68%.
3) Synthesis of intermediate M11-4: according to the synthesis method of compound M1-9, compound M11-3 was substituted for compound M1-7 to obtain intermediate M11-4 with yield of 65%.
4) Synthesis of compound M11: according to the synthesis method of compound M1, compound M11-4 was substituted for compound M1-9 to obtain compound M11 with yield of 52%. MS (ASAP): 730.

### Example 12

### Synthesis Route of Compound (M12)

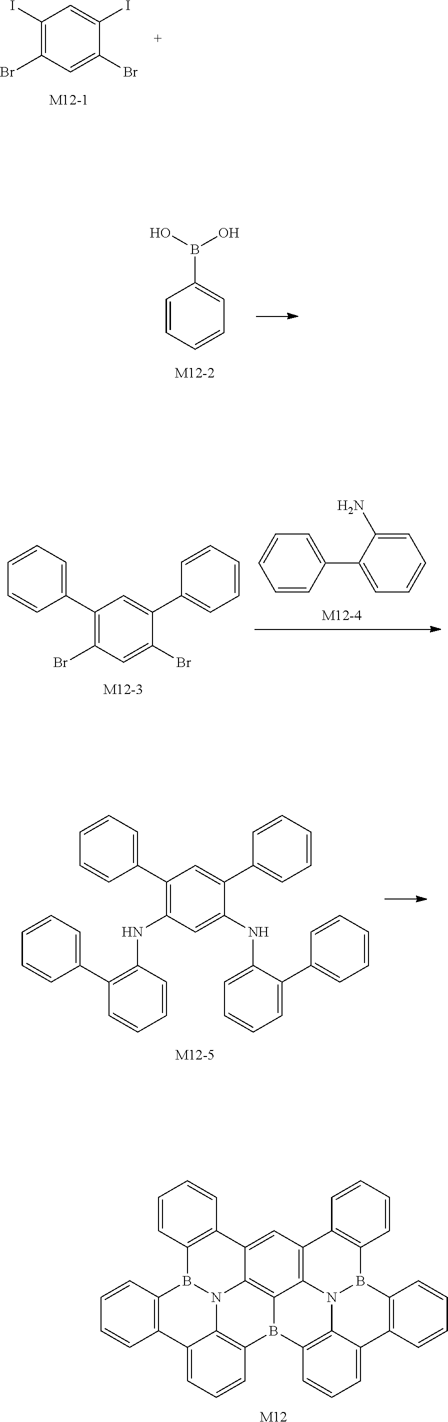

### Synthesis of Compound (M12)

1) Synthesis of intermediate M12-3: in a nitrogen environment, compound M12-1 (48.8 g, 100 mmol), compound M12-2 (24.4 g, 200 mmol), tetrakis(triphenylphosphine)palladium (3.31 g, 3 mmol), 50 mL of aqueous solution of potassium carbonate (27.6 g, 200 mmol), and 200 mL of toluene were added to a three-necked flask (500 mL), heated and stirred to 80° C., and reacted for 12 hours. After the reaction was completed, the reaction solution was cooled to room temperature. The filtrate was treated by suction filtration, then most of the solvent was removed by rotary evaporation. The reaction solution was dissolved in dichloromethane and washed three times with water. Organic liquids were collected, mixed with silica gel, and purified by silica gel column chromatography to obtain the intermediate M12-3 with yield of 67%. The eluent used in the purification was composed of petroleum ether and dichloromethane with a volume ratio of 4.5:1.
2) Synthesis of intermediate M12-5: in a nitrogen environment, compound M12-3 (23.3 g, 60 mmol), compound M12-4 (20.3 g, 120 mmol), Pd₂(dba)₃ (1.1 g, 1.2 mmol), tri-tert-butylphosphine (0.48 g, 2.4 mmol), sodium tert-butoxide (13.7 g, 90 mmol), and 150 mL of anhydrous toluene solvent were added to a two-necked flask (300 mL), heated to 60° C., stirred and reacted for 6 hours, then cooled to room temperature. The reaction was quenched with water, and most of the solvent was removed from the reaction solution by rotary evaporation. The reaction solution was dissolved in dichloromethane and washed three times with water. Organic liquids were collected, mixed with silica gel, and purified by silica gel column chromatography to obtain the intermediate M12-5 with yield of 65%. The eluent used in the purification was composed of petroleum ether and dichloromethane with a volume ratio of 1.5:1.
3) Synthesis of compound M12: in a nitrogen environment, compound M12-5 (11.3 g, 20 mmol) and 100 mL of anhydrous toluene solvent were added to a three-necked flask (300 mL), stirred to dissolve them, then cooled to −78° C., and 65 mmol of tert-butyllithium was slowly added. After the reaction solution was reacted for 2 hours, 70 mmol of boron tribromide was added at one time, then slowly raise the reaction solution to room temperature. The reaction solution was continuously stirred and reacted for 3 hours, then 100 mmol of N, N-diisopropylethylamine was added at one time. Subsequently, the reaction solution was heated to 100° C. and reacted for 4 hours. After the reaction was completed, most of the solvent was removed from the reaction solution by rotary evaporation. The reaction solution was dissolved in dichloromethane and washed three times with water. Organic liquids were collected, mixed with silica gel, and purified by silica gel column chromatography to obtain the compound M12 with yield of 45%. The eluent used in the purification was composed of petroleum ether and dichloromethane with a volume ratio of 3:1. MS (ASAP): 588.

### Example 13

### Synthesis Route of Compound (M13)

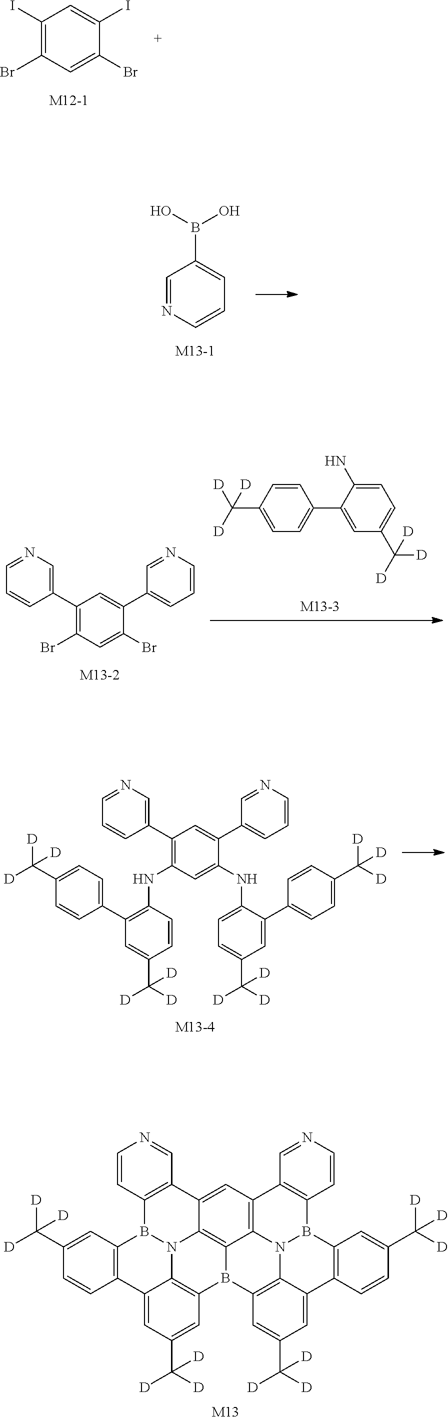

### Synthesis of Compound (M13)

1) Synthesis of intermediate M13-2: according to the synthesis method of compound M12-3, compound M13-1 was substituted for compound M12-2 to obtain intermediate M13-2 with yield of 65%.
2) Synthesis of intermediate M13-4: according to the synthesis method of compound M12-5, compounds M13-2 and M13-3 were substituted for compounds M12-3 and M12-4, respectively, to obtain intermediate M13-4 with yield of 67%.
3) Synthesis of compound M13: according to the synthesis method of compound M12, compound M13-4 was substituted for compound M12-5 to obtain compound M13 with yield of 43%. MS (ASAP): 658.

### Example 14

Synthesis route of Compound (M14) is as follows:

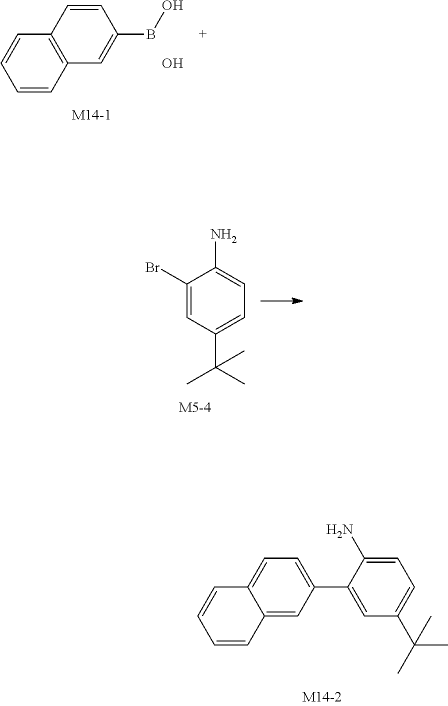

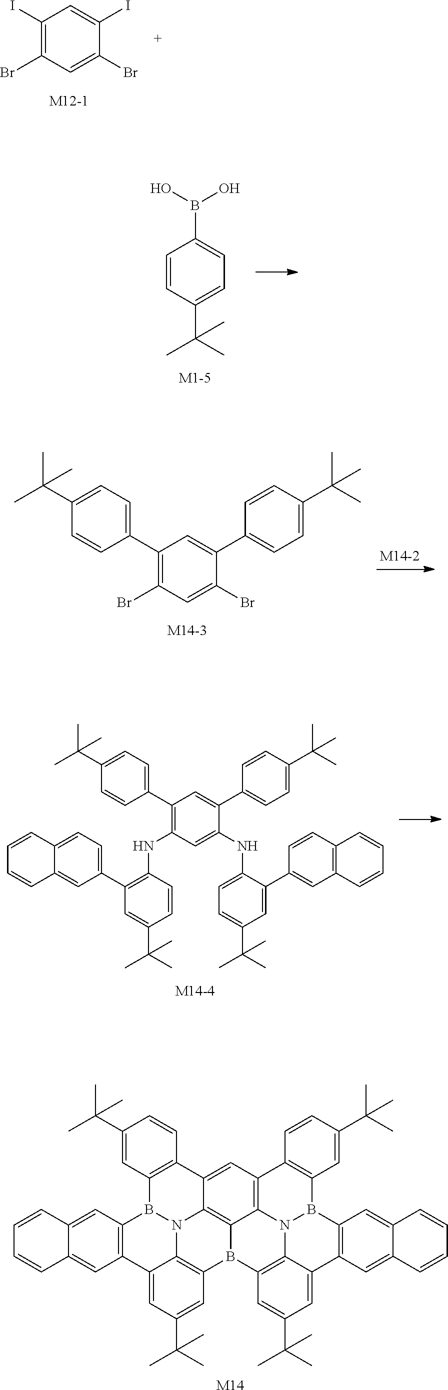

### Synthesis of Compound (M14)

1) Synthesis of intermediate M14-2: according to the synthesis method of compound M1-6, compounds M5-4 and M14-1 were substituted for compounds M1-4 and M1-5, respectively, to obtain intermediate M14-2 with yield of 69%.
2) Synthesis of intermediate M14-3: according to the synthesis method of compound M12-3, compound M1-5 was substituted for compound M12-2 to obtain intermediate M14-3 with yield of 70%.
3) Synthesis of intermediate M14-4: according to the synthesis method of compound M12-5, compounds M14-3 and M14-2 were substituted for compounds M12-3 and M12-4, respectively, to obtain intermediate M14-4 with yield of 63%.
4) Synthesis of compound M14: according to the synthesis method of compound M12, compound M14-4 was substituted for compound M12-5 to obtain compound M14 with yield of 42%. MS (ASAP): 913.

### Example 15

### Synthesis Route of Compound (M15)

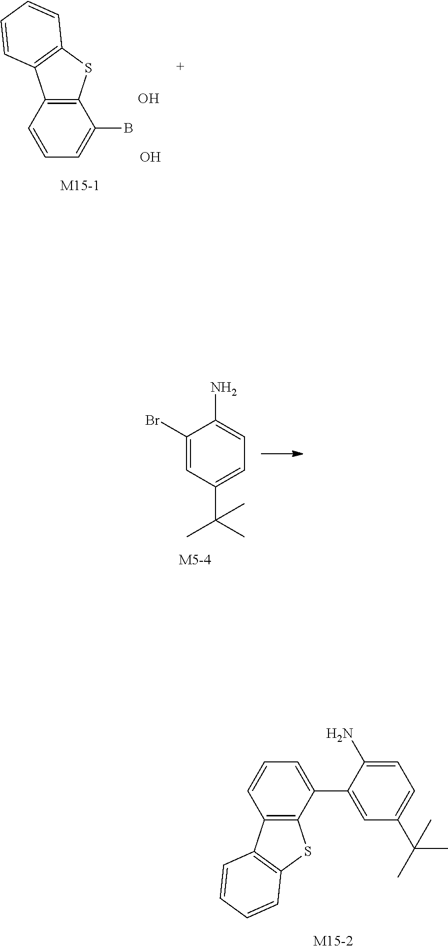

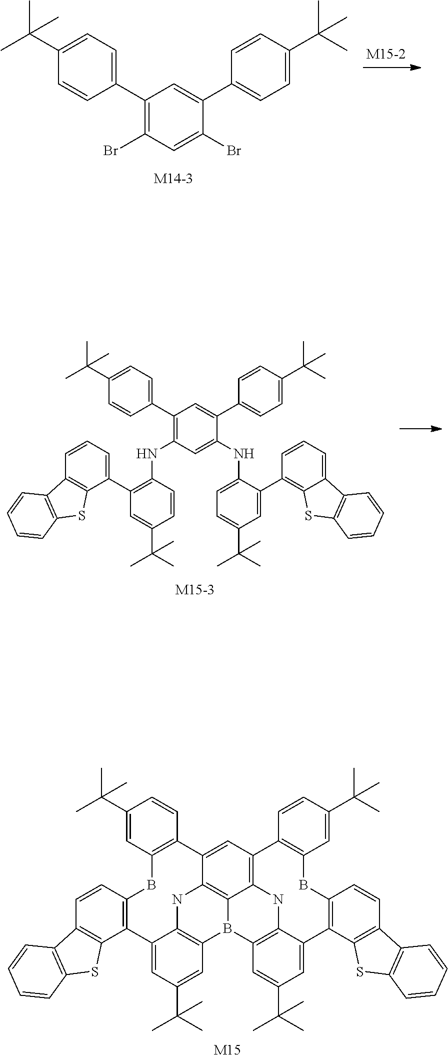

### Synthesis of Compound (M15)

1) Synthesis of intermediate M15-2: according to the synthesis method of compound M1-6, compounds M5-4 and M15-1 were substituted for compounds M1-4 and M1-5, respectively, to obtain intermediate M15-2 with yield of 69%.
2) Synthesis of intermediate M15-3: according to the synthesis method of compound M12-5, compounds M15-3 and M15-2 were substituted for compounds M12-3 and M12-4, respectively, to obtain intermediate M15-3 with yield of 60%.
3) Synthesis of compound M15: according to the synthesis method of compound M12, compound M15-3 was substituted for compound M12-5 to obtain compound M15 with yield of 46%. MS (ASAP): 1025.

### Example 16

### Synthesis Route of Compound (M16)

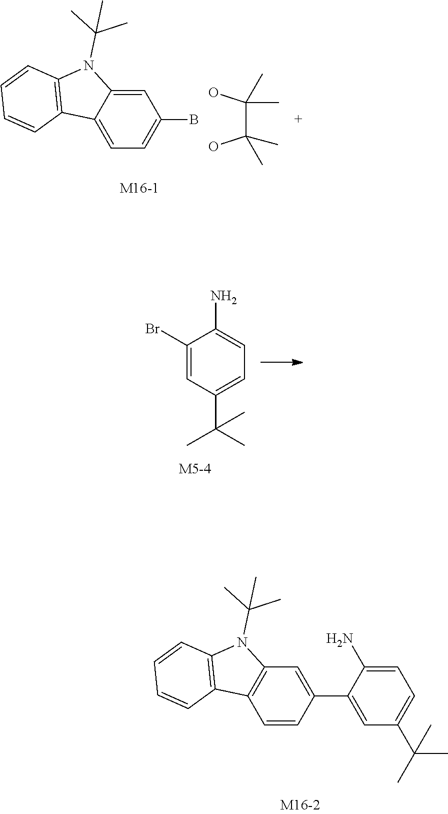

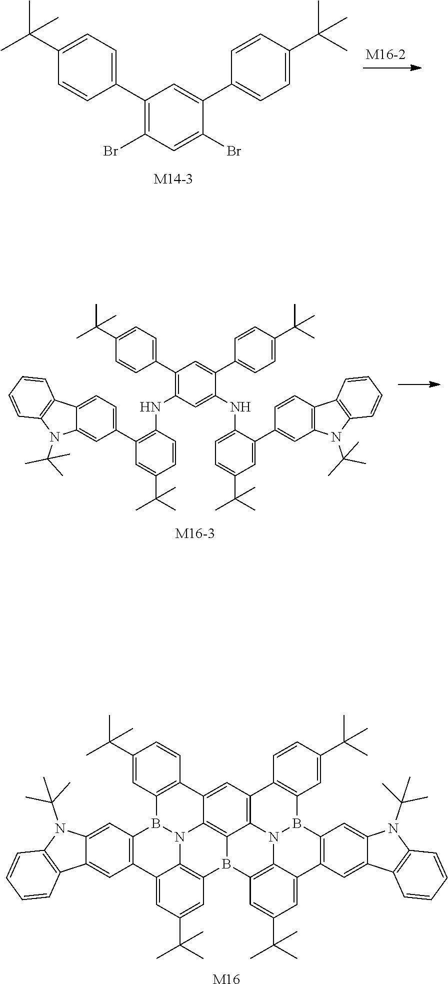

### Synthesis of Compound (M16)

1) Synthesis of intermediate M16-2: according to the synthesis method of compound M1-6, compounds M5-4 and M16-1 were substituted for compounds M1-4 and M1-5, respectively, to obtain intermediate M16-2 with yield of 70%.
2) Synthesis of intermediate M16-3: according to the synthesis method of compound M11-5, compounds M14-3 and M16-2 were substituted for compounds M12-3 and M12-4, respectively, to obtain intermediate M16-3 with yield of 62%.
3) Synthesis of compound M16: according to the synthesis method of compound M12, compound M16-3 was substituted for compound M12-5 to obtain compound M16 with yield of 44%. MS (ASAP): 1103.

### Example 17

### Synthesis Route of Compound (M17)

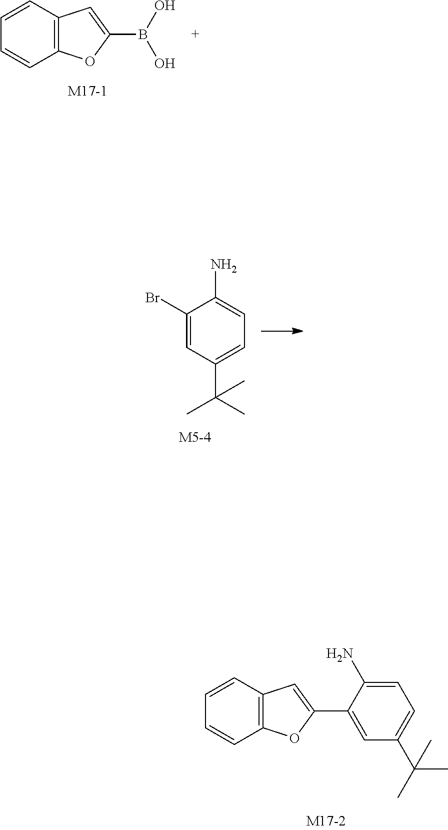 [SMILES: OB(O)c1cc2ccccc2o1 ; CC(C)(C)c1ccc(N)c(Br)c1 ; CC(C)(C)c1ccc(N)c(-c2cc3ccccc3o2)c1]

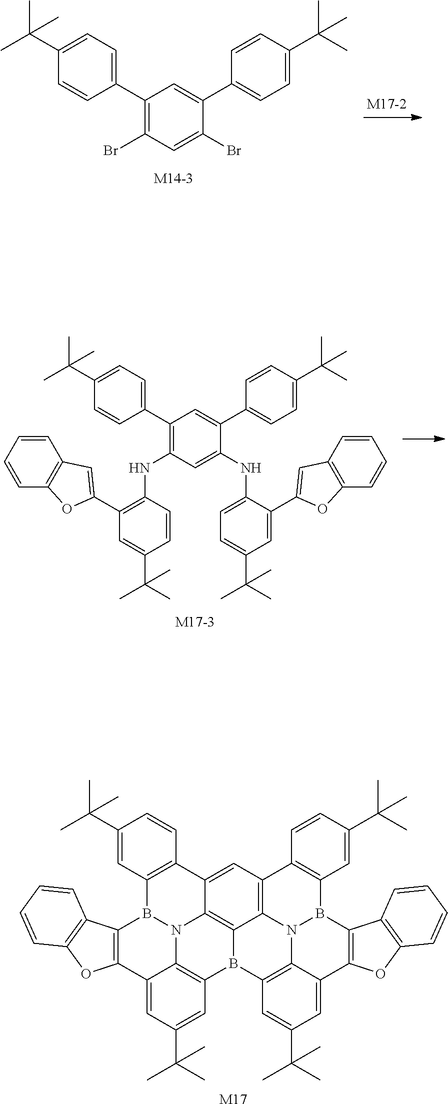

### Synthesis of Compound (M17)

1) Synthesis of intermediate M17-2: according to the synthesis method of compound M1-6, compounds M5-4 and M17-1 were substituted for compounds M1-4 and M1-5, respectively, to obtain intermediate M17-2 with yield of 72%.
2) Synthesis of intermediate M17-3: according to the synthesis method of compound M12-5, compounds M14-3 and M17-2 were substituted for compounds M12-3 and M12-4, respectively, to obtain intermediate M17-3 with yield of 61%.
3) Synthesis of compound M17: according to the synthesis method of compound M12, compound M17-3 was substituted for compound M12-5 to obtain compound M17 with yield of 47%. MS (ASAP): 893.

### Example 18

### Synthesis Route of Compound (M18)

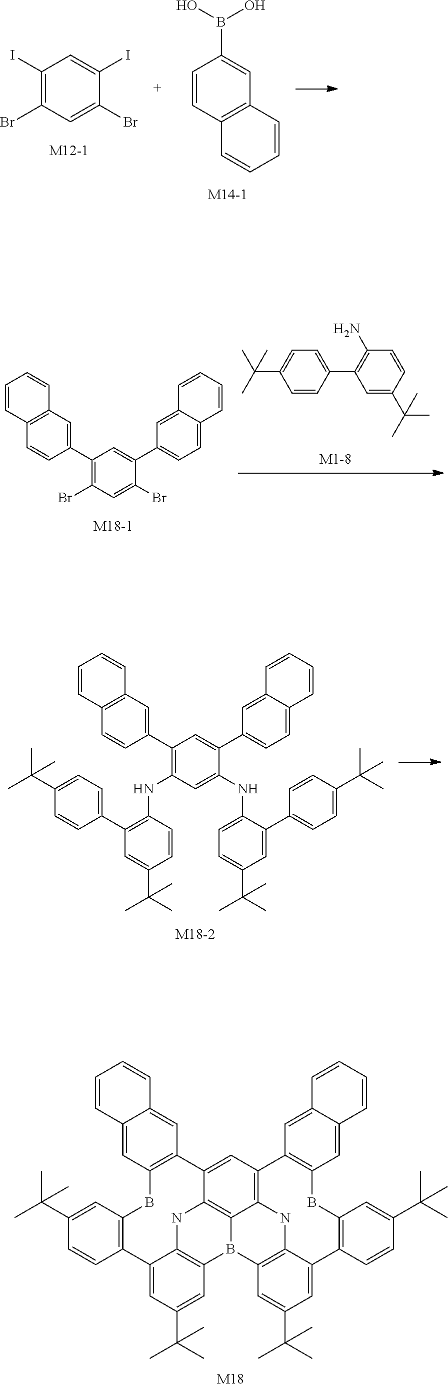

### Synthesis of Compound (M18)

1) Synthesis of intermediate M18-1: according to the synthesis method of compound M12-3, compound M14-1 was substituted for compound M12-2 to obtain intermediate M18-1 with yield of 68%.
2) Synthesis of intermediate M18-2: according to the synthesis method of compound M12-5, compounds M18-1 and M1-8 were substituted for compounds M12-3 and M12-4, respectively, to obtain intermediate M18-2 with yield of 64%.
3) Synthesis of compound M18: according to the synthesis method of compound M12, compound M18-2 was substituted for compound M12-5 to obtain compound M18 with yield of 46%. MS (ASAP): 913.

### Example 19

### Synthesis Route of Compound (M19)

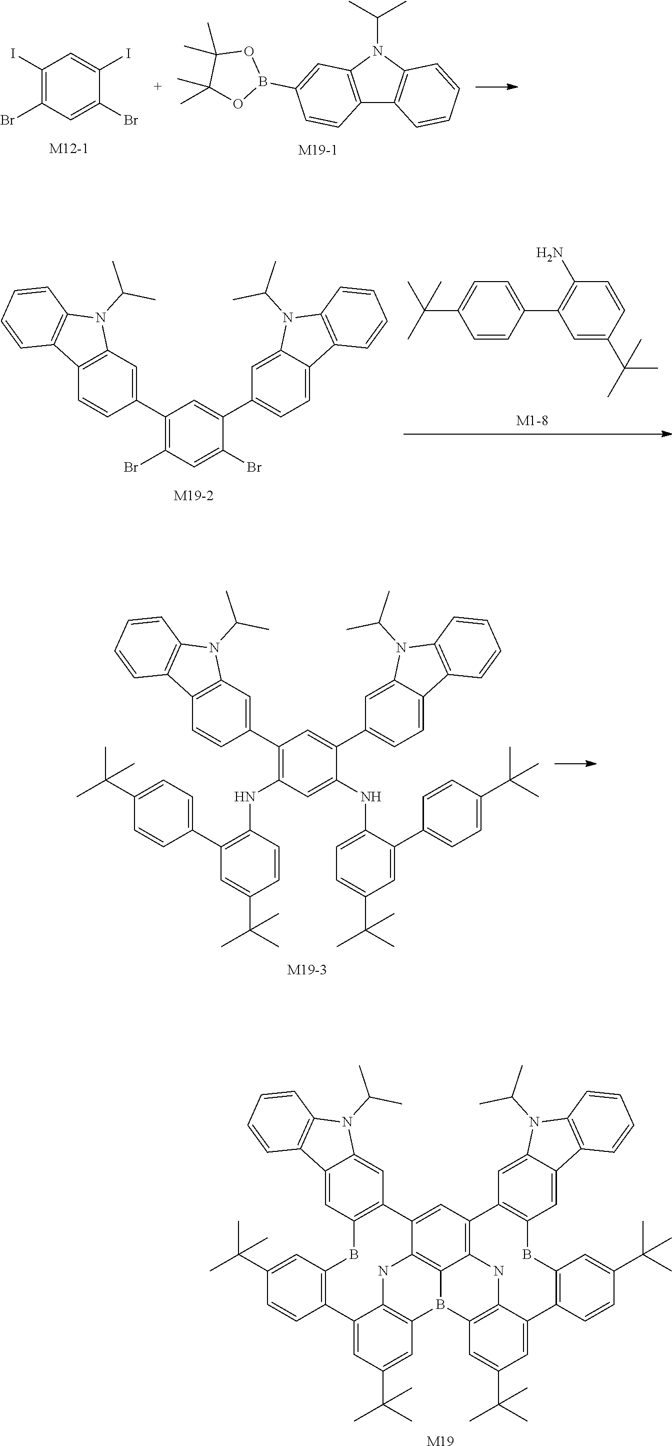

### Synthesis of Compound (M19)

1) Synthesis of intermediate M19-2: according to the synthesis method of compound M12-3, compound M19-1 was substituted for compound M12-2 to obtain intermediate M19-2 with yield of 69%.
2) Synthesis of intermediate M19-3: according to the synthesis method of compound M12-5, compounds M19-2 and M1-8 were substituted for compounds M12-3 and M12-4, respectively, to obtain intermediate M19-3 with yield of 66%.
3) Synthesis of compound M19: according to the synthesis method of compound M12, compound M19-3 was substituted for compound M12-5 to obtain compound M19 with yield of 41%. MS (ASAP): 1075.

### Example 20

### Synthesis Route of Compound (M20)

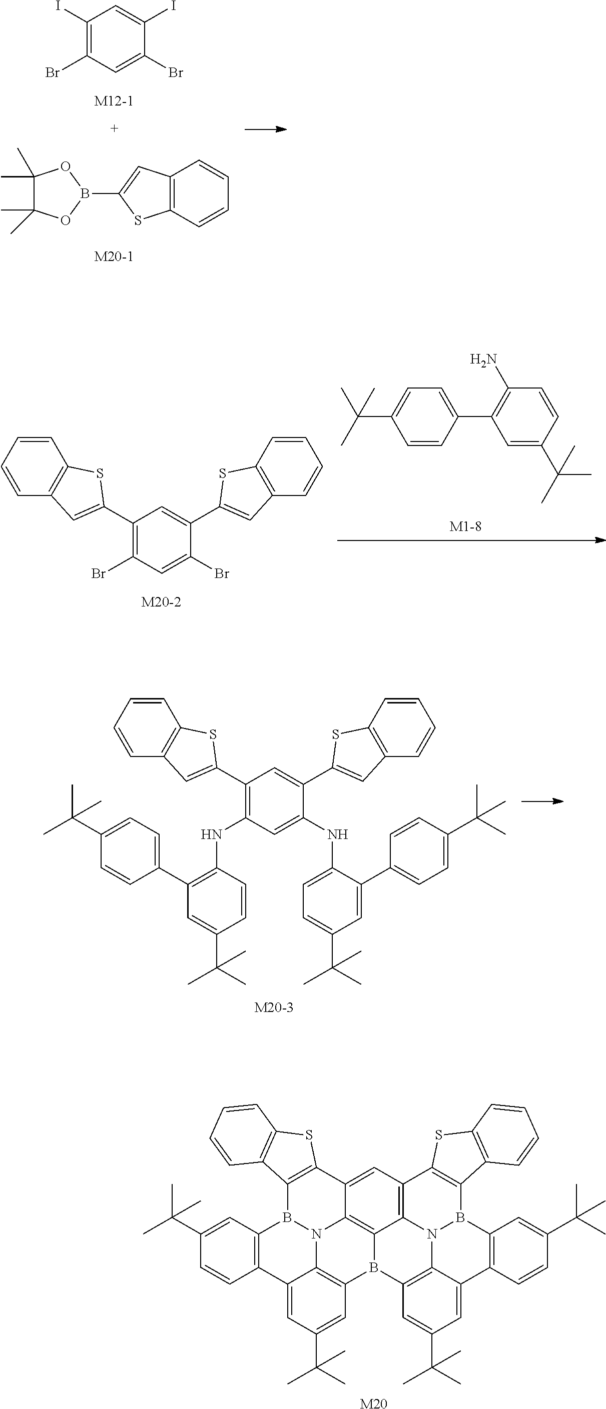

### Synthesis of Compound (M20)

1) Synthesis of intermediate M20-2: according to the synthesis method of compound M12-3, compound M20-1 was substituted for compound M12-2 to obtain intermediate M20-2 with yield of 67%.
2) Synthesis of intermediate M20-3: according to the synthesis method of compound M12-5, compounds M20-2 and M1-8 were substituted for compounds M12-3 and M12-4, respectively, to obtain intermediate M20-3 with yield of 64%.
3) Synthesis of compound M20: according to the synthesis method of compound M12, compound M20-3 was substituted for compound M12-5 to obtain compound M20 with yield of 40%. MS (ASAP): 925.

### Example 21

### Synthesis Route of Compound (M21)

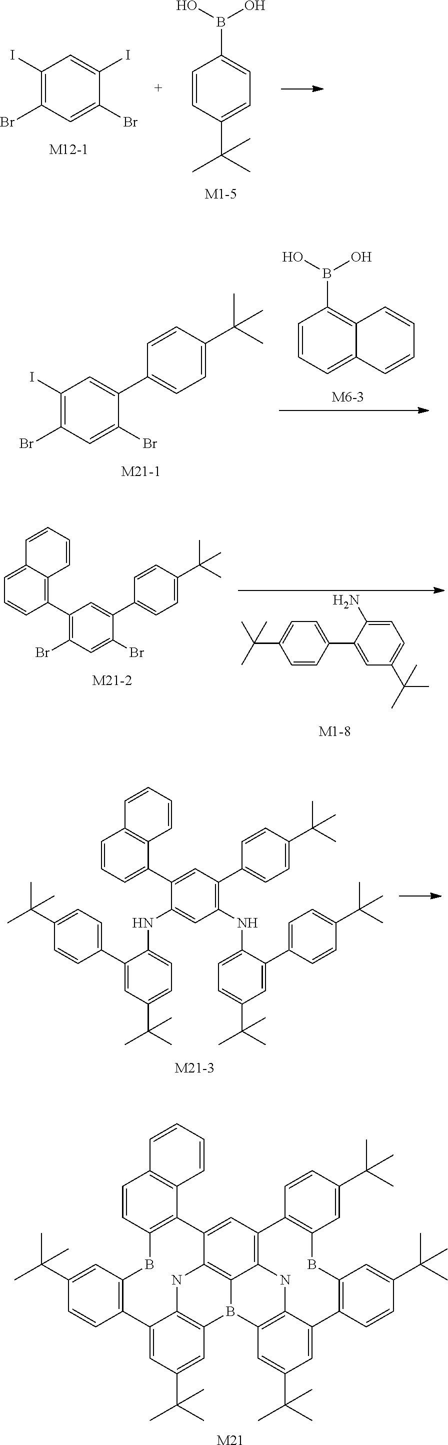

### Synthesis of Compound (M21)

1) Synthesis of intermediate M21-1: according to the synthesis method of compound M1-6, compound M12-1 was substituted for compound M1-4 to obtain intermediate M21-1 with yield of 63%.
2) Synthesis of intermediate M21-2: according to the synthesis method of compound M1-6, compounds M21-1 and M6-3 were substituted for compounds M1-4 and M1-5, respectively, to obtain intermediate M21-2 with yield of 68%.
3) Synthesis of intermediate M21-3: according to the synthesis method of compound M12-5, compounds M21-2 and M1-8 were substituted for compounds M12-3 and M12-4, respectively, to obtain intermediate M21-3 with yield of 65%.
4) Synthesis of compound M21: according to the synthesis method of compound M12, compound M21-3 was substituted for compound M12-5 to obtain compound M21 with yield of 44%. MS (ASAP): 917.

### Example 22

### Synthesis Route of Compound (M22)

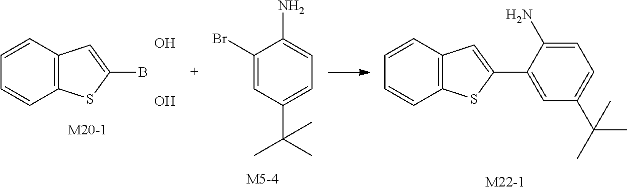

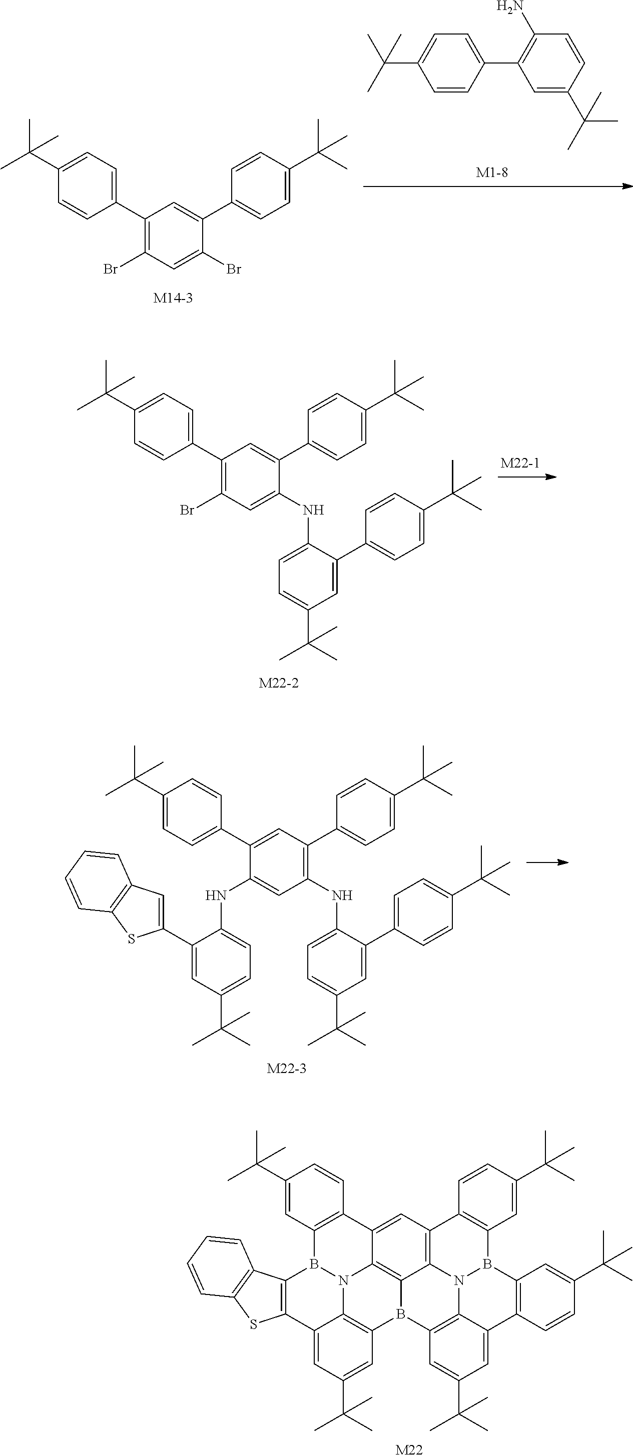

### Synthesis of Compound (M22)

1) Synthesis of intermediate M22-1: according to the synthesis method of compound M1-6, compounds M5-4 and M20-1 were substituted for compounds M1-4 and M1-5, respectively, to obtain intermediate M22-1 with yield of 73%.
2) Synthesis of intermediate M22-2: according to the synthesis method of compound M1-7, compounds M14-3 and M1-8 were substituted for compounds M1-6 and M1-3, respectively, to obtain intermediate M22-2 with yield of 64%.
3) Synthesis of intermediate M22-3: according to the synthesis method of compound M1-7, compounds M22-2 and M22-1 were substituted for compounds M1-6 and M1-3, respectively, to obtain intermediate M22-3 with yield of 68%.
5) Synthesis of compound M22: according to the synthesis method of compound M12, compound M22-3 was substituted for compound M12-5 to obtain compound M22 with yield of 42%. MS (ASAP): 925.
Example 23
   Preparation and Characterization of OLED devices
(1) Materials for each layer of OLED devices:
HIM: a derivative of triarylamine;
HTM: a derivative of triarylamine;
Host: a derivative of anthracene;
Dopant: compound Ml to compound M22, and comparative compound 1 (Ref-1), respectively.

Specific structures of the materials are as follows:

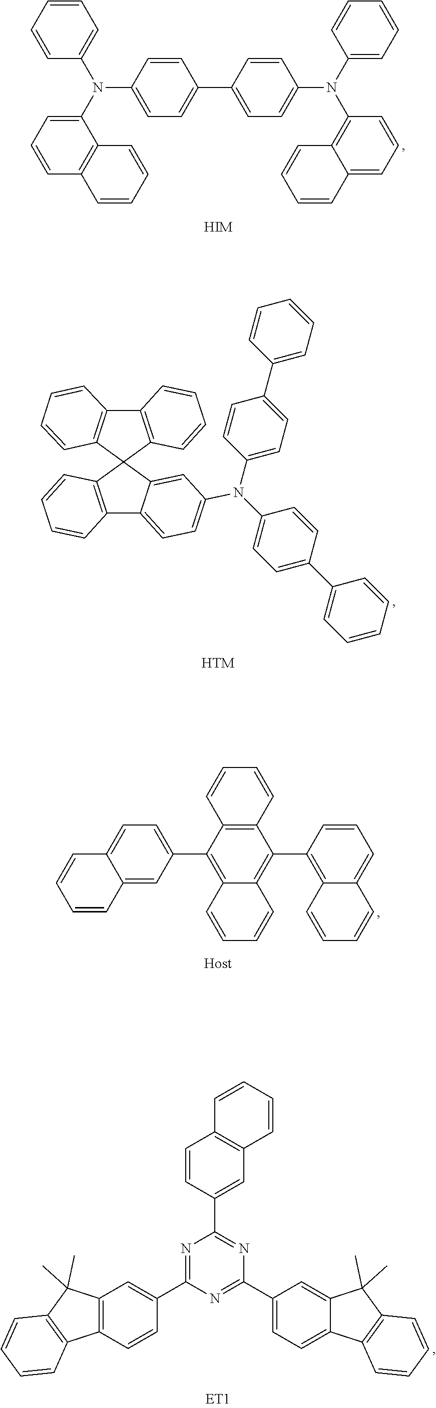

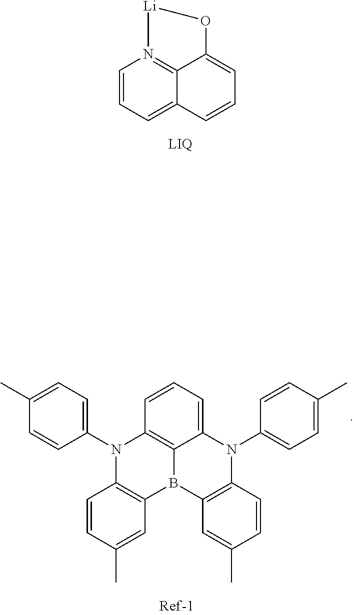

The structure of OLED devices is as follows:
ITO/HIL (40 nm)/HTL (100 nm)/Host and 5% of Dopant (50 nm)/ETL (25 nm)/LiQ (1 nm)/Al (150 nm)/cathode, the preparation steps are as follows:
a. cleaning a conductive glass substrate. When used for the first time, the conductive glass substrate was cleaned using multiple solvents, such as chloroform, ketone, and isopropanol, followed by UV ozone plasma treatment;
b. forming the HIL (40 nm), the HTL (100 nm), and the EML (50 nm) sequentially by the solution processing method;
c, forming the ETL (25 nm) by hot vapor deposition in high vacuum (10-6 millibars);
d. forming the cathode of LiQ/Al (1 nm/150 nm) by hot vapor deposition in high vacuum (10-6 millibars);
e, encapsulation. The devices were encapsulated by UV cured resin in a nitrogen glove box.

Current-voltage (J-V) characteristics of organic light-emitting diodes in blue light device examples M1 to M20 and comparative example 1 were measured using characterization equipment, and important parameters such as efficiency, lifetime (as shown in Table 1), and external quantum efficiency were recorded. In Table 1, all external quantum efficiency and lifetime of the organic light-emitting diodes are relative values relative to the comparative example 1.

TABLE 1

| OLED device | Guest material | EQE | T90@1000 nits |
|---|---|---|---|
| Example 1 | M1 | 1.49 | 1.66 |
| Example 2 | M2 | 1.48 | 1.63 |
| Example 3 | M3 | 1.55 | 1.70 |
| Example 4 | M4 | 1.56 | 1.72 |
| Example 5 | M5 | 1.53 | 1.69 |
| Example 6 | M6 | 1.52 | 1.67 |
| Example 7 | M7 | 1.45 | 1.58 |
| Example 8 | M8 | 1.46 | 1.60 |
| Example 9 | M9 | 1.59 | 1.76 |
| Example 10 | M10 | 1.58 | 1.74 |
| Example 11 | M11 | 1.34 | 1.58 |
| Example 12 | M12 | 1.58 | 1.67 |
| Example 13 | M13 | 1.42 | 1.55 |
| Example 14 | M14 | 1.67 | 1.75 |
| Example 15 | M15 | 1.60 | 1.86 |
| Example 16 | M16 | 1.62 | 1.81 |
| Example 17 | M17 | 1.65 | 1.84 |
| Example 18 | M18 | 1.64 | 1.76 |
| Example 19 | M19 | 1.62 | 1.79 |
| Example 20 | M20 | 1.63 | 1.80 |
| Example 21 | M21 | 1.58 | 1.68 |
| Example 22 | M22 | 1.63 | 1.72 |
| Comparative | Ref-1 | 1 | 1 |
| Example 1 | | | |

It can be seen from Table 1 that, when the compounds of examples 1 to 22 of the disclosure are used to prepare OLED devices, luminous efficiency and lifetime of the OLED devices can be greatly improved.

Various technical features of the above examples can be optionally combined. To make the description concise, the above examples do not illustrate all possible combinations of various technical features. However, as long as there is no contradiction in the combinations of these technical features, they should be considered within the scope of this specification.

The above examples only illustrate several examples of the disclosure, and the description to these examples is specific and detailed, but cannot be understood as a limitation on the scope of the disclosure. It should be pointed out that for ordinary skilled in the art, several modifications and improvements can be made without departing from the concept of this application, all of which fall within the scope of the disclosure.

1. An organic boron-nitrogen compound, wherein the organic boron-nitrogen compound is represented by formula (I) or formula (II): 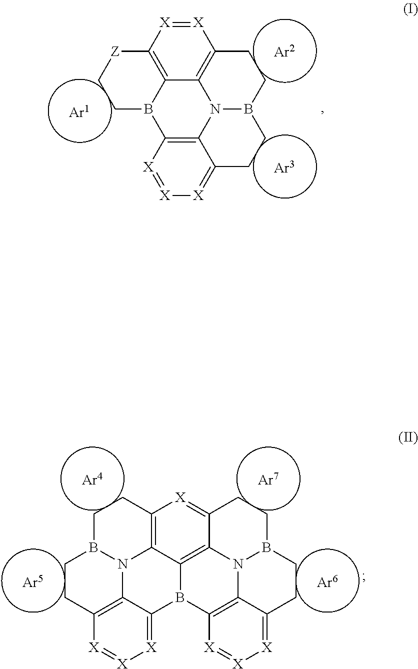
wherein Ar¹ to Ar⁷ are independently selected from a substituted or unsubstituted aromatic group having 6 to 40 ring atoms or a substituted or unsubstituted heteroaromatic group having 6 to 40 ring atoms;
X at each occurrence is independently selected from CRI or N;
Z is selected from NR₂, PR₂, CR₃R₄, SiR₃R₄, O, S, S(═O)₂, or S(═O);
R₁ to R₄ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF₃, —OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₁ groups are connected to form a ring or not form a ring together.

2. The organic boron-nitrogen compound of claim 1, wherein R₁ to R₄ at each occurrence are independently selected from —H, -D, methyl, —CD3, isopropyl, tert-butyl, 2,2-dimethylbutyl, phenyl, pyridinyl, triazinyl, naphthyl, phenanthryl, anthranyl, dibenzofuranyl, dibenzothienyl, carbazolyl, or 9,9-dimethylfluorenyl.

3. The organic boron-nitrogen compound of claim 1, wherein Ar¹ to Ar⁷ are independently selected from a group consisting of formulae (B-1) to (B-9): 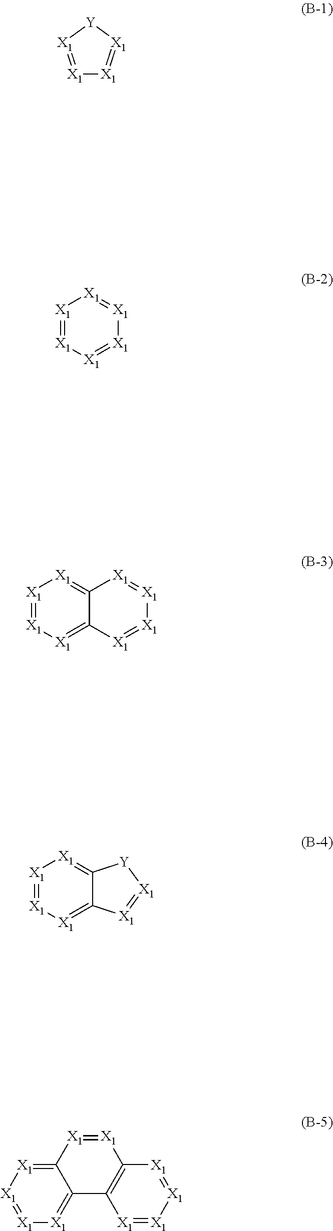 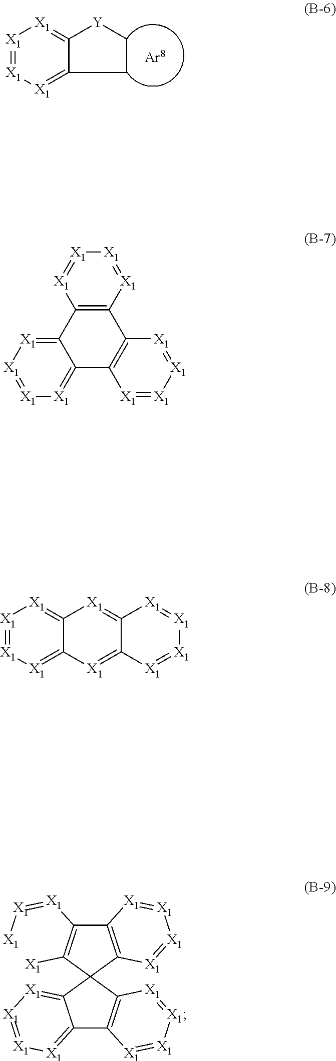
wherein,
X₁ at each occurrence is independently selected from CR₅ or N;
Y at each occurrence is independently selected from NR₆, PR₆, CR₇R₈, SiR₇R₈, O, S, S(═O)₂, or S(═O);
Ar⁸ is selected from a substituted or unsubstituted aromatic group having 6 to 40 ring atoms or a substituted or unsubstituted heteroaromatic group having 6 to 40 ring atoms;
R₅ to R₈ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, —CF₃, —OCF₃, —C₁, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₅ groups are connected to form a ring or not form a ring together.

4. The organic boron-nitrogen compound of claim 3, wherein the formula (B-6) is selected from a group consisting of following formulae:

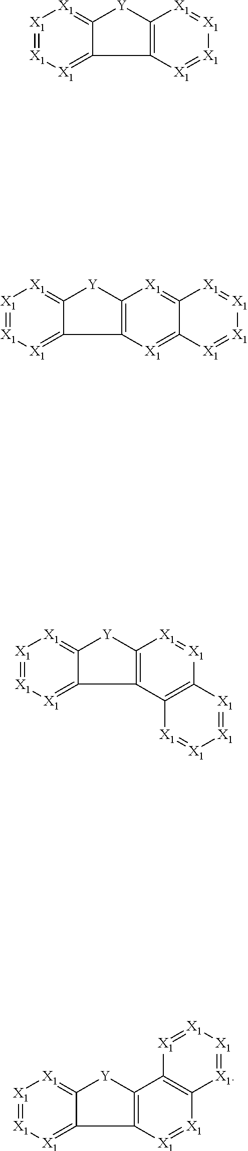

5. The organic boron-nitrogen compound of claim 3, wherein Ar¹ to Ar⁷ are independently selected from a group consisting of formulae (C-1) to (C-22): 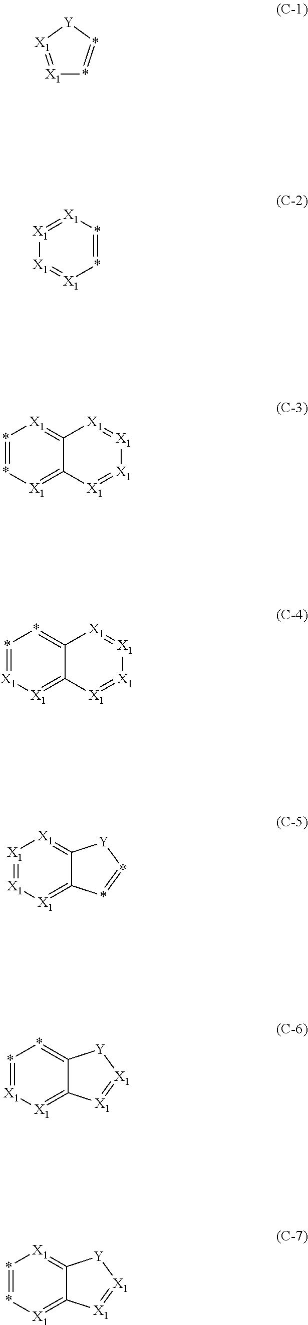 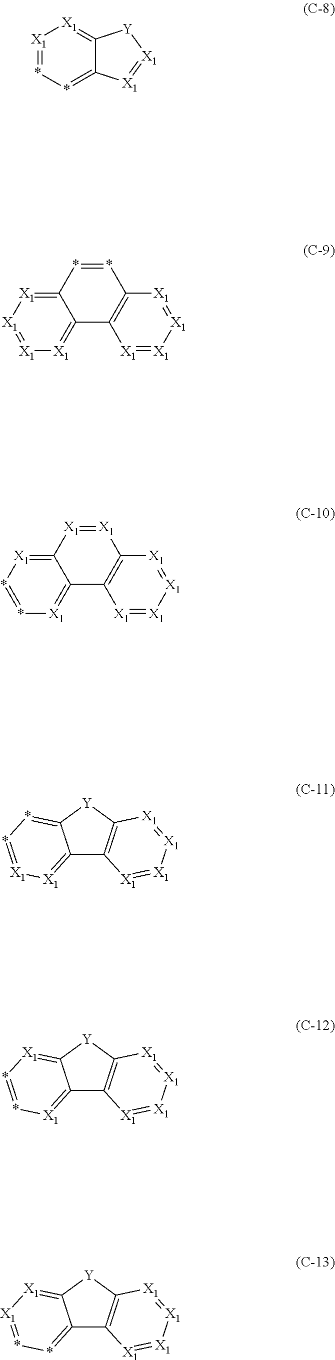 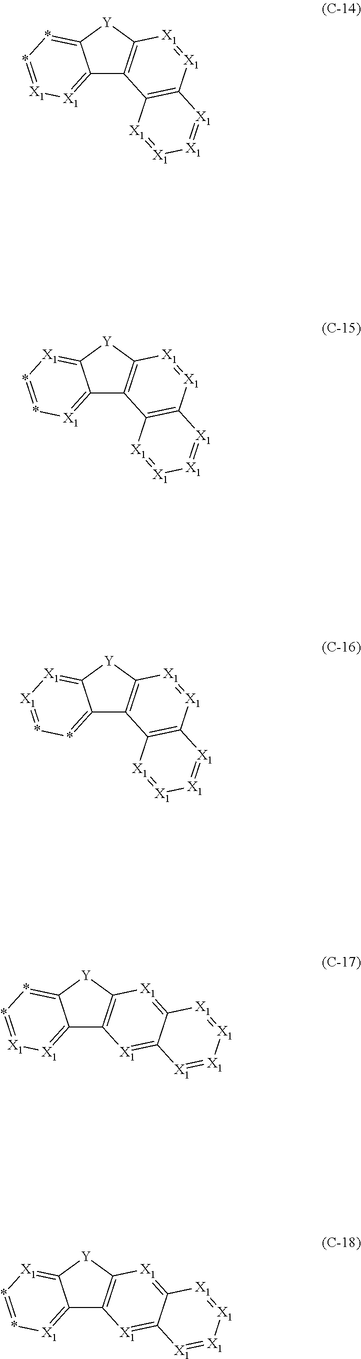 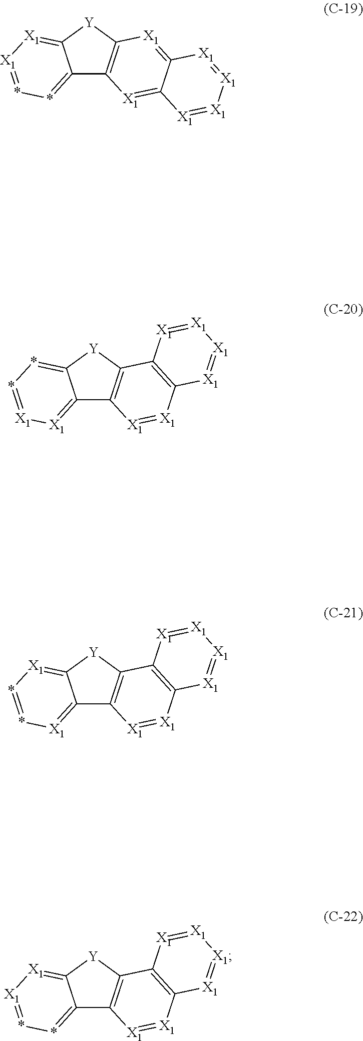
wherein * indicates a fusing site.

6. The organic boron-nitrogen compound of claim 3, wherein X₁ at each occurrence is selected from CR₅; and R₅ at each occurrence is independently from —H, -D, a linear alkyl group having 1 to 10 carbon atoms, a branched alkyl group having 3 to 10 carbon atoms, a cyclic alkyl group having 3 to 10 carbon atoms, a substituted or unsubstituted aromatic group having 5 to 20 ring atoms, a substituted or unsubstituted heteroaromatic group having 5 to 20 ring atoms, or any combination of these groups.

7. The organic boron-nitrogen compound of claim 3, wherein R₅ at each occurrence is independently selected from —H, -D, methyl, —CD₃, isopropyl, tert-butyl, 2,2-dimethylbutyl, phenyl, pyridinyl, triazinyl, naphthyl, phenanthryl, anthranyl, dibenzofuranyl, dibenzothienyl, carbazolyl, or 9,9-dimethylfluorenyl.

8. The organic boron-nitrogen compound of claim 3, wherein Ar¹ is selected from the formula (B-1) or the formula (B-6).

9. The organic boron-nitrogen compound of claim 3, wherein,
Ar⁴ and Ar⁷ are selected from the same group, and/or
Ar⁵ and Ar⁶ are selected from the same group.

10. The organic boron-nitrogen compound of claim 3, wherein Ar⁴ and Ar⁷ are the same group selected from 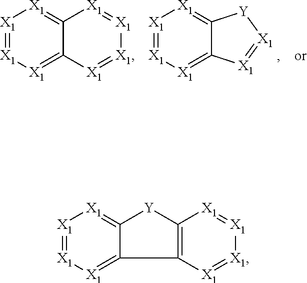
and/or Ar⁵ and Ar⁶ are the same group selected from

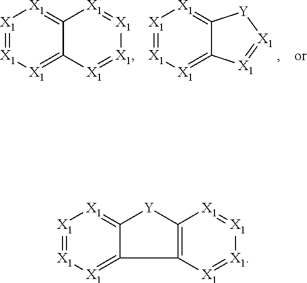

11. The organic boron-nitrogen compound of claim 3, wherein the organic boron-nitrogen compound is represented by any one of formulae (1-1) to (1-15):

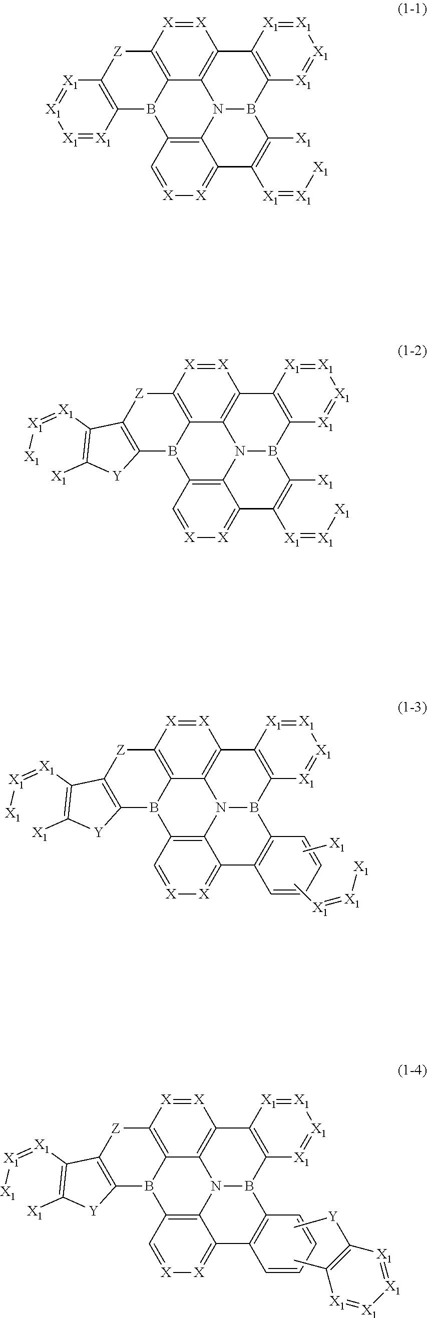

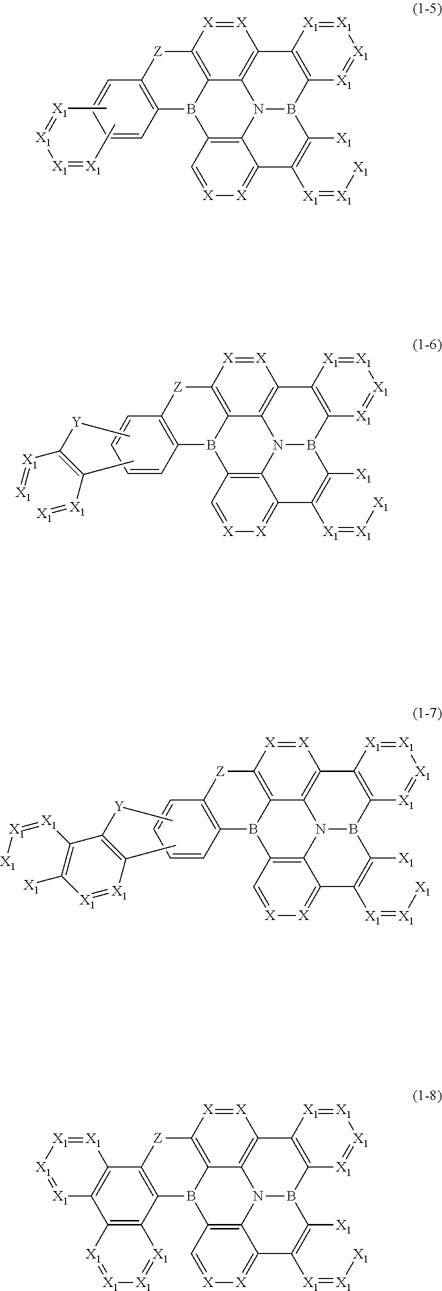

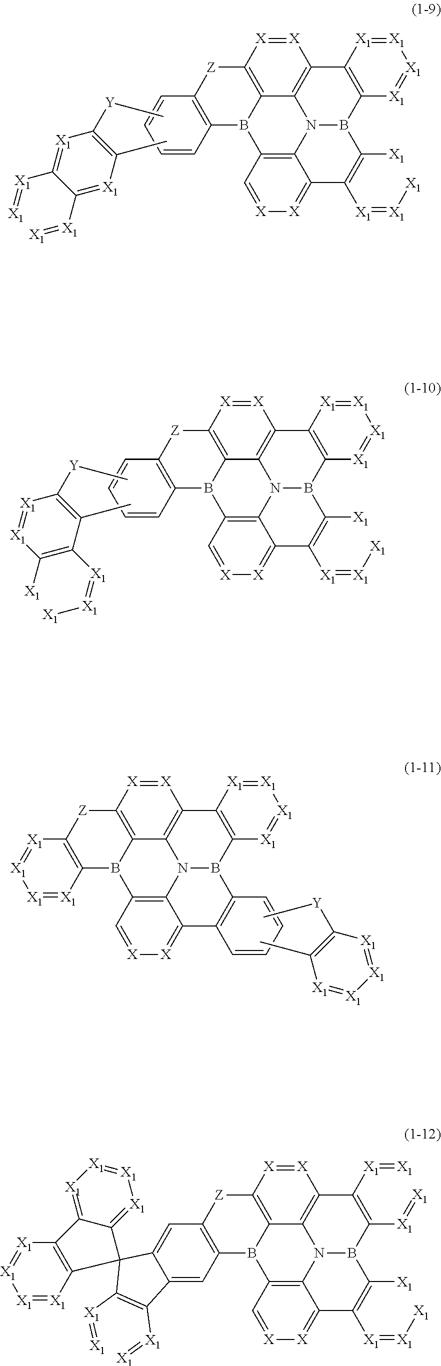

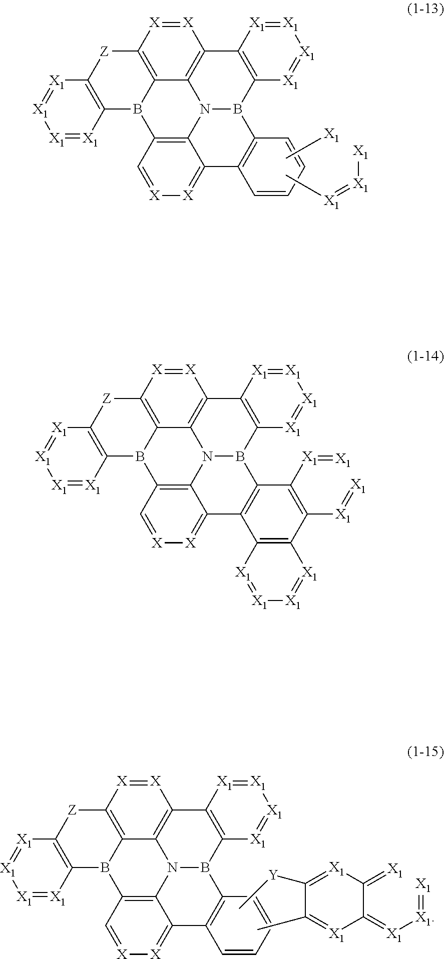

12. The organic boron-nitrogen compound of claim 3, wherein the organic boron-nitrogen compound is represented by any one of formulae (2-1) to (2-12):

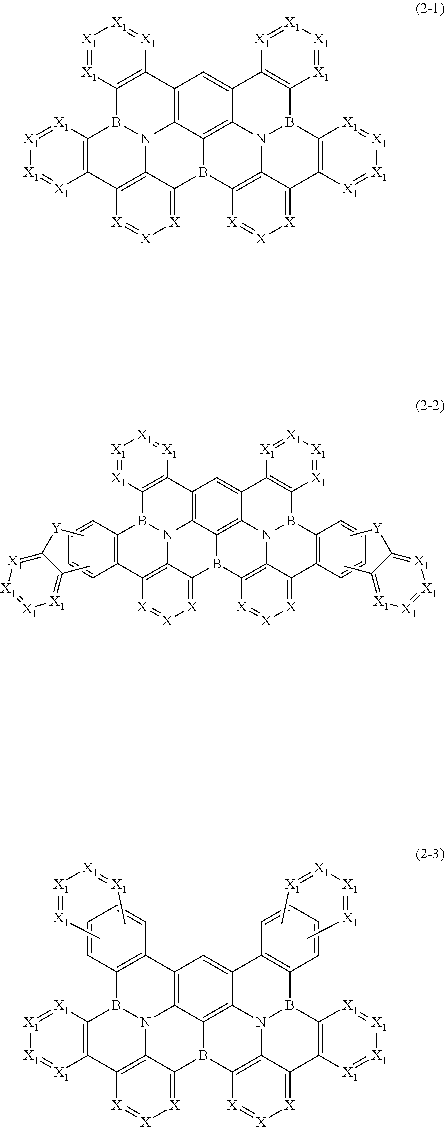

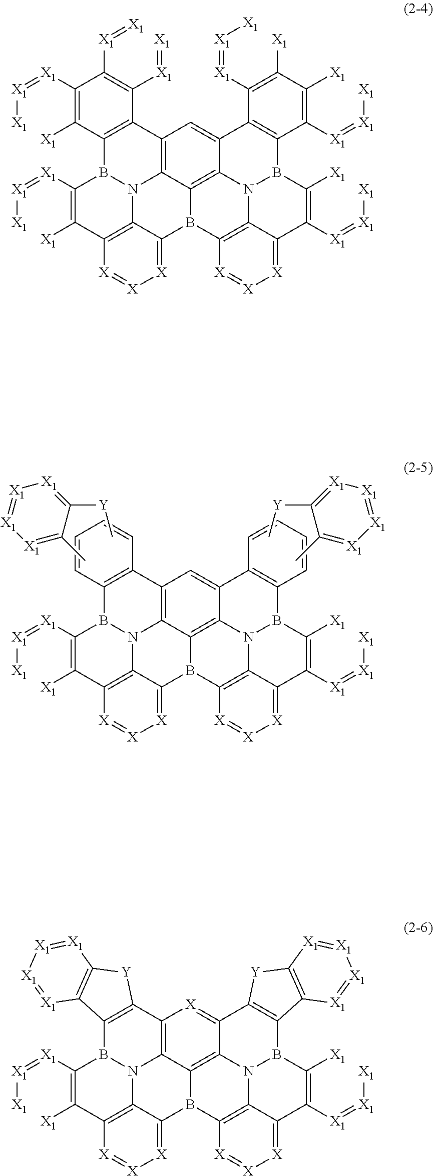

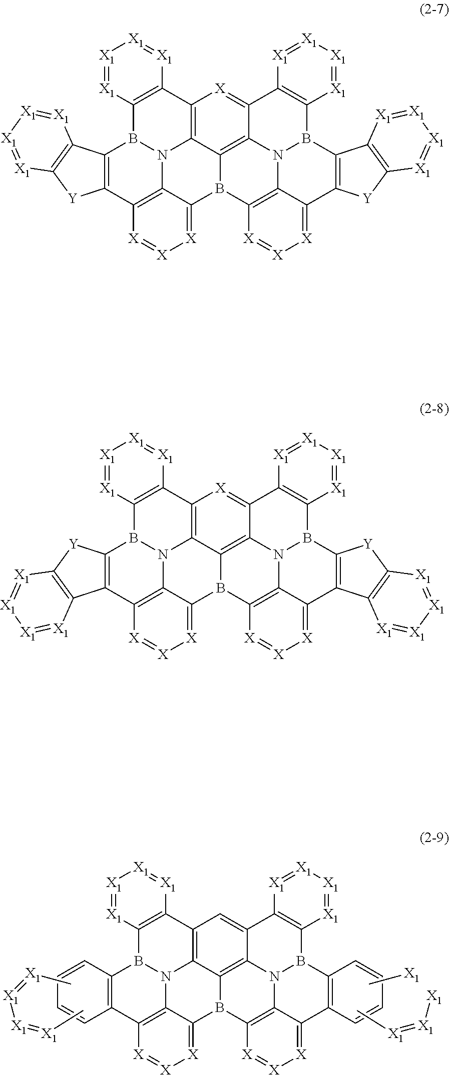

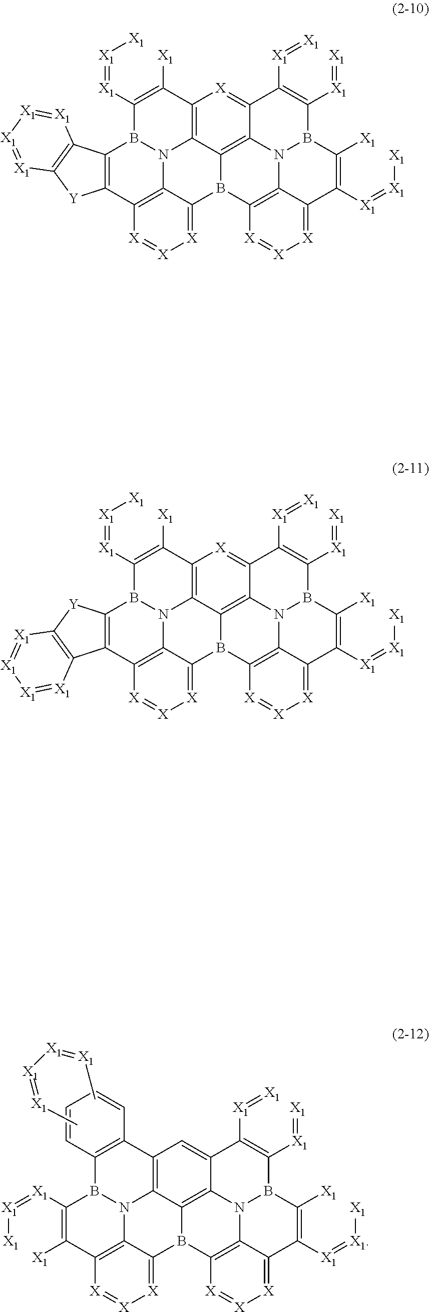

13. The organic boron-nitrogen compound of claim 1, wherein X at each occurrence is selected from CR₁, and R₁ at each occurrence is independently from —H, -D, a linear alkyl group having 1 to 10 carbon atoms, a branched alkyl group having 3 to 10 carbon atoms, a cycloalkyl group having 3 to 10 carbon atoms, a substituted or unsubstituted aromatic group having 5 to 20 ring atoms, a substituted or unsubstituted heteroaromatic group having 5 to 20 ring atoms, or any combination of these groups.

14. The organic boron-nitrogen compound of claim 13, wherein R₁ at each occurrence is independently selected from —H, -D, methyl, —CD₃, isopropyl, tert-butyl, or 2,2-dimethylbutyl.

15. A mixture, wherein the mixture comprises at least one organic boron-nitrogen compound as claimed in claim 1, and at least one organic functional material; and the organic functional material is one or more selected from a hole injection material, a hole transport material, an electron transport material, an electron injection material, an electron blocking material, a hole blocking material, a light-emitting material, a host material, or an organic dye.

16. A composition, wherein the composition comprises an organic boron-nitrogen compound represented by formula (I) or formula (II) and at least one organic solvent: 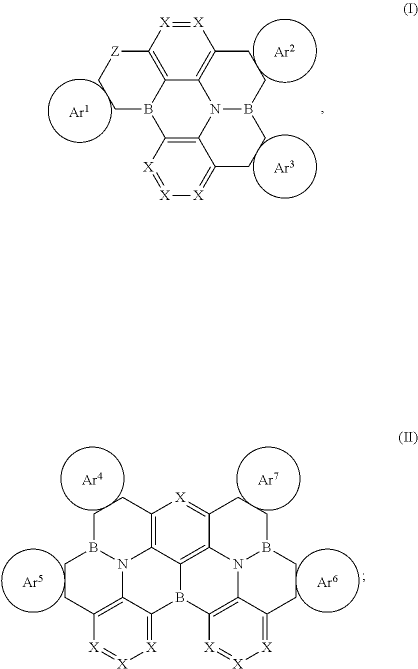
wherein Ar¹ to Ar⁷ are independently selected from a substituted or unsubstituted aromatic group having 6 to 40 ring atoms or a substituted or unsubstituted heteroaromatic group having 6 to 40 ring atoms;
X at each occurrence is independently selected from CRI or N;
Z is selected from NR₂, PR₂, CR₃R₄, SiR₃R₄, O, S, S(═O)₂, or S(═O);
R₁ to R₄ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF₃, —OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₁ groups are connected to form a ring or not form a ring together.

17. An organic electronic device, wherein the organic electronic device comprises a first electrode, a second electrode, and one or more functional layers disposed between the first electrode and the second electrode; and at least one functional layer in the one or more functional layers comprises an organic boron-nitrogen compound represented by formula (I) or formula (II): 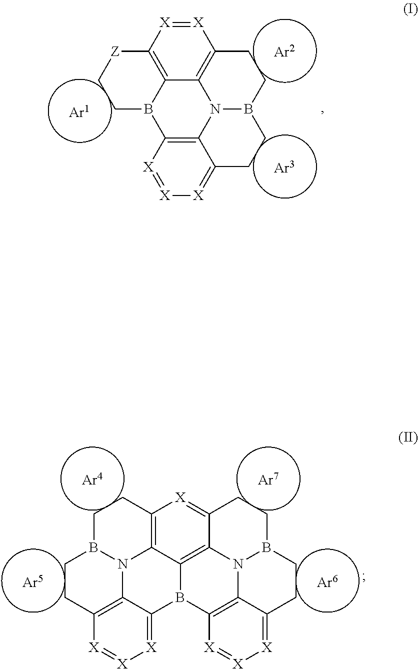
wherein Ar¹ to Ar⁷ are independently selected from a substituted or unsubstituted aromatic group having 6 to 40 ring atoms or a substituted or unsubstituted heteroaromatic group having 6 to 40 ring atoms;
X at each occurrence is independently selected from CR₁ or N;
Z is selected from NR₂, PR₂, CR₃R₄, SiR₃R₄, O, S, S(═O)₂, or S(═O);
R₁ to R₄ at each occurrence are independently selected from —H, -D, a linear alkyl group having 1 to 20 carbon atoms, a linear alkoxy group having 1 to 20 carbon atoms, a linear thioalkoxy group having 1 to 20 carbon atoms, a branched alkyl group having 3 to 20 carbon atoms, a cycloalkyl group having 3 to 20 carbon atoms, a branched alkoxy group having 3 to 20 carbon atoms, a cyclic alkoxy group having 3 to 20 carbon atoms, a branched thioalkoxy group having 3 to 20 carbon atoms, a cyclic thioalkoxy group having 3 to 20 carbon atoms, a silyl group, a ketone group having 1 to 20 carbon atoms, an alkoxycarbonyl group having 2 to 20 carbon atoms, an aryloxycarbonyl group having 7 to 20 carbon atoms, a cyano group, an aminoformyl group, haloformyl, formyl, an isocyano group, an isocyanate group, a thiocyanate group, an isothiocyanate group, a hydroxyl group, a nitro group, an amino group, —CF₃, —OCF₃, —Cl, —Br, —F, a substituted or unsubstituted aromatic group having 5 to 40 ring atoms, a substituted or unsubstituted heteroaromatic group having 5 to 40 ring atoms, a substituted or unsubstituted aryloxy group having 5 to 40 ring atoms, substituted or unsubstituted heteroaryloxy group having 5 to 40 ring atoms, or any combination of these groups; and
two adjacent R₁ groups are connected to form a ring or not form a ring together.

18. The organic boron-nitrogen compound of claim 1, wherein the organic boron-nitrogen compound is represented by formula (I-1) or formula (II-2): 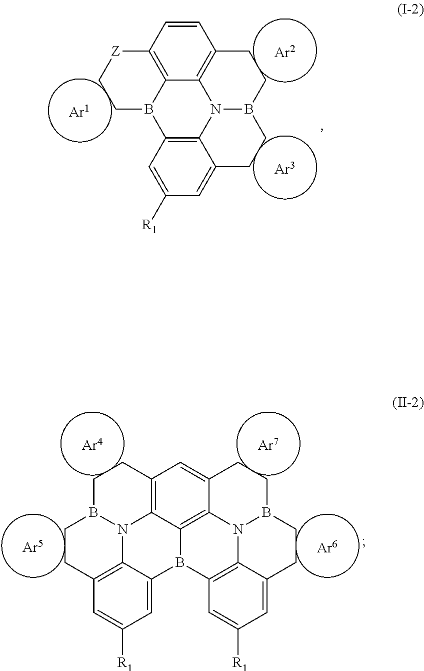
wherein Ar¹ to Ar⁷, Z, and R₁ have the same meaning as defined in claim 1.

19. The organic boron-nitrogen compound of claim 1, wherein R₁ is independently selected from methyl, isopropyl, —CD₃, or the following structure: 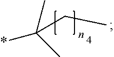
wherein n4 is an integer from 0 to 4.

20. The organic boron-nitrogen compound of claim 1, wherein the formula (II) has a symmetric structure.
